(19) United States
(12) Patent Application Publication
(10) Pub. No.: US 2026/0276874 A1
(43) Pub. Date: Sep. 17, 2026

(54) LIGHT ABSORPTION FILTER, OPTICAL FILTER, MANUFACTURING METHOD THEREOF, DISPLAY ELEMENT INTERMEDIATE, DISPLAY ELEMENT, ORGANIC ELECTROLUMINESCENT DISPLAY DEVICE, INORGANIC ELECTROLUMINESCENT DISPLAY DEVICE, AND LIQUID CRYSTAL DISPLAY DEVICE

(71) Applicant: FUJIFILM Corporation, Tokyo (JP)

(72) Inventors: Nobutaka FUKAGAWA, Minamiashigara-shi (JP); Kunihiro ATSUMI, Minamiashigara-shi (JP)

(73) Assignee: FUJIFILM Corporation, Tokyo (JP)

(21) Appl. No.: 19/668,870

(22) Filed: May 6, 2026

Related U.S. Application Data
(63) Continuation of application No. PCT/JP2024/042416, filed on Nov. 29, 2024.

(30) Foreign Application Priority Data
Dec. 8, 2023 (JP) 2023-207520
Jun. 12, 2024 (JP) 2024-095400

(51) Int. Cl. G02B 5/22; G02F 1/1335; H10H 29/01; H10H 29/855; H10K 59/80

(52) U.S. Cl. CPC G02B 5/223; G02F 1/133512; H10H 29/0363; H10H 29/8552; H10K 59/8792

(57) ABSTRACT

A light absorption filter includes a light absorption disappearing layer and a wavelength-selective absorption layer. The light absorption disappearing layer contains a resin, a dye having a main absorption wavelength in a range of 400 to 700 nm, and a compound that generates radicals upon ultraviolet irradiation. The wavelength-selective absorption layer contains a resin and a dye having a main absorption wavelength in the same range and excludes any radical-generating compound. The configuration enables controlled light absorption and selective modification of absorption characteristics upon ultraviolet irradiation.

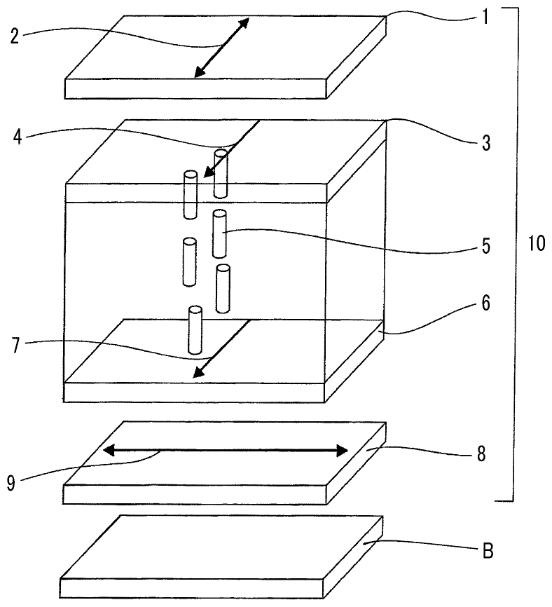

### CROSS-REFERENCE TO RELATED APPLICATIONS

This application is a Continuation of PCT International Application No. PCT/JP2024/042416 filed on Nov. 29, 2024, which claims priority under 35 U.S.C. § 119 (a) to Japanese Patent Application No. 2023-207520 filed in Japan on Dec. 8, 2023 and Japanese Patent Application No. 2024-095400 filed in Japan on Jun. 12, 2024. Each of the above applications is hereby expressly incorporated by reference, in their entirety, into the present application.

### BACKGROUND OF THE INVENTION

### 1. Field of the Invention

The present invention relates to a light absorption filter, an optical filter, a manufacturing method thereof, a display element intermediate, a display element, an organic electroluminescent display device, an inorganic electroluminescent display device, and a liquid crystal display device.

### 2. Description of the Related Art

As image display devices, an organic electroluminescent (OLED) display device, an inorganic electroluminescent display device (inorganic EL display device), a liquid crystal display device, and the like have been used in recent years.

A liquid crystal display device is widely used year by year as a space-saving image display device with low power consumption. Since a liquid crystal panel displaying images is a non-light emitting element which does not emit light itself, the liquid crystal display device includes a backlight unit which is disposed on a rear surface of the liquid crystal panel and supplies light to the liquid crystal panel.

The OLED display device is a device that displays an image using self-luminescence of an OLED display element. Therefore, the OLED display device has advantages such as a high contrast ratio, a high color reproducibility, a wide viewing angle, high-speed responsiveness, and a reduction in thickness and weight can be achieved, as compared with various display devices such as a liquid crystal display device and a plasma display device. In addition to these advantages, in terms of flexibility as well, research and development are being actively carried out as a next-generation display device.

The inorganic EL display device is a device that displays an image using self-luminescence of an inorganic EL display element instead of the OLED display element in the OLED display device as a fluorescent material. As a result of recent research, it is expected that a display device more excellent than the OLED display device in terms of a large screen size, a longer service life, and the like can be realized.

In the development of an image display device, there is known a technology of incorporating a light absorption filter as a configuration.

For example, in a liquid crystal display device, in a case where a white light emitting diode (LED) is used as a light source for a backlight unit, an attempt has been made to provide a light absorption filter in order to block light having unnecessary wavelengths emitted from the white LED. In addition, in the OLED display device, an attempt has been made to provide a light absorption filter from the viewpoint of suppressing external light reflection, and WO2021-066082A discloses a method of preventing external light reflection without decreasing a transmittance of display light by combining a plurality of coloring agents having different maximum absorption wavelengths.

Regarding another form of the light absorption filter that is incorporated in an image display device, research has been also carried out on an optical filter having both a light absorptive portion having a light absorption effect and a portion in which the light absorbability has been disappeared (hereinafter, also simply referred to as a “light absorption disappearing portion”), which is obtained by eliminating the light absorbability of a desired portion. In general, since a metal wire or the like is disposed on a non-display portion (a portion from which display light is not emitted, that is, a non-light emitting portion) of the OLED display device, a reflectivity of the non-display portion is often higher than that of a display portion (a portion from which display light is emitted, that is, alight emitting portion). In a case where the optical filter is incorporated in the image display device and used, by disposing the light absorptive portion on the non-display portion of the OLED display device and disposing the light absorption disappearing portion on the display portion of the OLED display device, it is possible to minimize a decrease in transmittance of display light and improve an antireflection effect.

For example, WO2023-068235A describes a light absorption filter containing a resin, a compound having an acid group, a compound that forms a hydrogen bond with the compound having an acid group and generates a radical upon ultraviolet irradiation, and a dye having a main absorption wavelength band in a wavelength range of 400 to 700 nm. According to the light absorption filter described in WO2023/068235A, it is said that a high decolorization rate is exhibited upon ultraviolet irradiation, and absorption derived from a new coloration structure (hereinafter, also referred to as “secondary absorption”) associated with the decomposition of the dye upon ultraviolet irradiation hardly occurs, whereby a high decolorization property can be obtained. In addition, WO2023-234353A describes a light absorption filter containing a resin, a dye having a main absorption wavelength band in a wavelength range of 400 to 700 nm, and a compound that generates a radical upon ultraviolet irradiation, in which the dye includes at least one of an azo coloring agent represented by any of General Formulae (i) to (iv) or an indoaniline-based coloring agent represented by General Formula (v). According to the light absorption filter described in WO2023-234353A, an excellent decolorization rate is exhibited even upon ultraviolet irradiation at room temperature, and the secondary absorption due to ultraviolet irradiation hardly occurs, and thus high decolorization properties are obtained.

### SUMMARY OF THE INVENTION

However, in the light absorption filter described in WO2021/066082A, there is a problem in that the transmittance of display light is impaired in a case where the absorbance is increased until the reflection of external light can be sufficiently suppressed. In addition, in the methods described in WO2023/068235A and WO2023/234353A, the suppression of the reflection of external light caused by the display portion in the display device is insufficient, and thus improvement is required.

That is, an object of the present invention is to provide a light absorption filter that can obtain an optical filter having a portion having high light absorbency and a portion having low light absorbency at desired positions and reducing a reflectivity to a desired level without impairing a transmittance of display light, and a display element intermediate including the light absorption filter.

In addition, another object of the present invention is to provide an optical filter that is an optical filter using the light absorption filter, in which the optical filter has a portion having high light absorbency and a portion having low light absorbency at desired positions and reduces a reflectivity to a desired level without impairing a transmittance of display light, a manufacturing method of the optical filter, and an organic electroluminescent display device, an inorganic electroluminescent display device, and a liquid crystal display device, each including the optical filter.

In addition, another object of the present invention is to provide a display element obtained by performing mask exposure on the display element intermediate, in which the display element has a portion having high light absorbency and a portion having low light absorbency at desired positions and reduces a reflectivity to a desired level without impairing a transmittance of display light, and an organic electroluminescent display device, an inorganic electroluminescent display device, and a liquid crystal display device, each including the display element.

As a result of intensive studies in consideration of the above-described objects, the present inventors have found that, by adopting a configuration of an optical filter including both a light absorption filter in which light absorbency is lost by ultraviolet irradiation and a light absorption filter in which light absorbency is not changed by ultraviolet irradiation, it is possible to impart both absorption characteristics required for suppressing the reflection of external light in the display portion in the display device and absorption characteristics required for suppressing the reflection of external light in the non-display portion in one optical filter. Further studies have been carried out based on these findings, whereby the present invention has been completed.

That is, the above-described object has been achieved by the following means.

<1>
a light absorption disappearing layer containing a resin, a dye having a main absorption wavelength band in a wavelength range of 400 to 700 nm, and a compound which generates a radical upon ultraviolet irradiation, and
a wavelength-selective absorption layer containing a resin and a dye having a main absorption wavelength band in a wavelength range of 400 to 700 nm, in which the wavelength-selective absorption layer does not contain a compound that generates a radical upon ultraviolet irradiation.
   <2>

The light absorption filter according to <1>, in which the compound that generates a radical upon ultraviolet irradiation, which is contained in the light absorption disappearing layer, includes a combination of a compound A having an acid group and a compound B having a structure capable of forming a hydrogen bond with the acid group contained in the compound A.

<3>

The light absorption filter according to <2>, in which the compound A is chemically bonded to a polymer constituting the resin contained in the light absorption disappearing layer.

<4>

The light absorption filter according to any one of <1> to <3>, in which the dye contained in the light absorption disappearing layer is chemically changed and decolorized by ultraviolet irradiation.

<5>

An optical filter that is obtained by subjecting the light absorption filter according to any one of <1> to <4> to mask exposure by ultraviolet irradiation.

<6>

A display element intermediate including the light absorption filter according to any one of <1> to <4>.

<7>

A display element obtained by performing mask exposure on the display element intermediate according to <6> by ultraviolet irradiation.

<8>

An organic electroluminescent display device, an inorganic electroluminescent display device, or a liquid crystal display device including the optical filter according to <5> or the display element according to <7>.

<9>

The organic electroluminescent display device, the inorganic electroluminescent display device, or the liquid crystal display device according to <8>, in which a layer that inhibits light absorption of the compound that generates a radical upon ultraviolet irradiation is provided on a viewer side with respect to the optical filter according to <5> or the display element according to <7>.

<10>

A manufacturing method for an optical filter, comprising: irradiating the light absorption filter according to any one of <1> to <4> with ultraviolet rays to carry out mask exposure.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same as or different from each other unless otherwise specified. The same applies to the definition of the number of substituents or the like. In a case where a plurality of substituents or the like come close to each other (particularly in a case where a plurality of substituents or the like are adjacent to each other), the substituents or the like may be linked to each other to form a ring unless otherwise specified. In addition, unless otherwise specified, rings, for example, alicyclic rings, aromatic rings, and heterocyclic rings may be further fused to form a fused ring.

In the present invention, unless otherwise specified, in the light absorption filter, each of the components (resin, dye, compound that generates a radical upon ultraviolet irradiation, other components which may be appropriately contained, and the like) constituting the light absorption disappearing layer may be contained in the light absorption disappearing layer of the light absorption filter in an amount of one kind or two or more kinds. In addition, in the present invention, in the light absorption filter, each of the components (resin, dye, other components which may be appropriately contained, and the like) constituting the wavelength-selective absorption layer may be contained in the wavelength-selective absorption layer of the light absorption filter in an amount of one kind or two or more kinds. The same applies to an optical filter produced by using the light absorption filter of the present invention.

The description of the light absorption filter according to the embodiment of the present invention can be preferably applied to the optical filter according to the embodiment of the present invention, unless otherwise specified, except that a layer corresponding to the light absorption disappearing layer in the light absorption filter has a light absorption disappearing portion formed by ultraviolet irradiation.

In the present invention, in a case where an E type double bond and a Z type double bond are present in a molecule, the double bond may be any one thereof or may be a mixture thereof, unless otherwise specified.

In the present invention, the representation of a compound (including a complex) is used to mean not only the compound itself but also a salt thereof, and an ion thereof. In addition, it is meant to include those in which a part of the structure is changed, as long as the effect of the present invention is not impaired. Further, a compound for which substitution or non-substitution is not specified means that the compound may have an arbitrary substituent within a range in which an effect of the present invention is not impaired. The same applies to the definition of a substituent or a linking group.

In addition, in the present invention, the numerical range represented by using “to” means a range including the numerical values before and after “to” as the lower limit value and the upper limit value, respectively.

In the present invention, “composition” includes a mixture in which a component concentration varies within a range in which a desired function is not impaired, in addition to a mixture in which the component concentration is constant (respective components are uniformly dispersed).

In the present invention, the description of “having a main absorption wavelength band at a wavelength XX to YY nm” means that a wavelength at which the maximum absorption is exhibited (that is, the maximum absorption wavelength) is present in a wavelength range of XX to YY nm. Therefore, in a case where the maximum absorption wavelength is present in the above-described wavelength range, the entire absorption band including this wavelength may be in the above-described wavelength range or may also extend up to the outside of the above-described wavelength range. In addition, in a case where there are a plurality of maximum absorption wavelengths, it suffices that a maximum absorption wavelength at which the highest absorbance is exhibited is present in the above-described wavelength range. That is, the maximum absorption wavelength other than the maximum absorption wavelength at which the highest absorbance is exhibited may be present either inside or outside the above-described wavelength range of XX to YY nm.

In the present invention, “(meth)acrylate” represents any one or both of acrylate and methacrylate, “(meth)acrylic acid” represents any one or both of acrylic acid and methacrylic acid and “(meth)acryloyl” represents any one or both of acryloyl and methacryloyl.

The light absorption filter according to the embodiment of the present invention has portions having different light absorbability at desired positions, and it is possible to obtain an optical filter that reduces the reflectivity to a desired level without impairing the transmittance of display light.

In addition, the optical filter according to the embodiment of the present invention has portions having different light absorbability at desired positions, and reduces the reflectivity to a desired level without impairing the transmittance of display light.

In addition, the organic electroluminescent display device, the inorganic electroluminescent display device, and the liquid crystal display device according to the embodiment of the present invention include the optical filter according to the embodiment of the present invention.

In addition, the display element intermediate according to the embodiment of the present invention includes the optical absorption filter according to the embodiment of the present invention, and the organic electroluminescent display device, the inorganic electroluminescent display device, and the liquid crystal display device, which include a display element obtained by performing mask exposure on the display element intermediate, include the optical filter according to the embodiment of the present invention.

The optical filter according to the embodiment of the present invention can be preferably manufactured by the manufacturing method according to the embodiment of the present invention.

### BRIEF DESCRIPTION OF THE DRAWINGS

The FIGURE is a schematic view illustrating an outline of one embodiment of a liquid crystal display device having an optical filter according to the present invention.

### DESCRIPTION OF THE PREFERRED EMBODIMENTS

### [Light Absorption Filter]

The light absorption filter according to the embodiment of the present invention includes a light absorption disappearing layer containing a resin, a dye having a main absorption wavelength band in a wavelength range of 400 to 700 nm, and a compound that generates a radical upon ultraviolet irradiation;
and a wavelength-selective absorption layer containing a resin and a dye having a main absorption wavelength band in a wavelength range of 400 to 700 nm, in which the wavelength-selective absorption layer does not contain a compound that generates a radical upon ultraviolet irradiation.

In the present invention, the main absorption wavelength band of a dye is the main absorption wavelength band of the dye, which is measured in the state of being a light absorption filter. Specifically, in Examples described later, it is measured in a state of being a light absorption filter with a substrate under the conditions described in the section of the absorbance of the light absorption filter.

In the light absorption filter according to the embodiment of the present invention, the “dye” is dispersed (preferably dissolved) in the resin contained in the same layer (light absorption disappearing layer or wavelength-selective absorption layer) to form a filter exhibiting a specific absorption spectrum derived from the dye. The dispersion may be any type of dispersion, such as a random type or a regular type.

In the light absorption disappearing layer constituting the light absorption filter according to the embodiment of the present invention, the compound that generates a radical upon ultraviolet irradiation is dispersed (preferably dissolved) in the resin, so that the radical is generated upon ultraviolet irradiation, the generated radical reacts with the dye, and the dye is chemically changed to fade and decolorize the dye. That is, the light absorption disappearing layer constituting the light absorption filter according to the embodiment of the present invention is a layer having a characteristic that the dye contained in the light absorption disappearing layer is chemically changed and can be decolorized upon ultraviolet irradiation.

In addition, in the light absorption disappearing layer constituting the light absorption filter according to the embodiment of the present invention, in a case where the compound that generates a radical upon ultraviolet irradiation contains a compound A having an acid group and a compound B having a structure capable of forming a hydrogen bond with the acid group contained in the compound A, as described later, the efficiency of generating radical species upon ultraviolet irradiation is improved as compared with a case where a commonly used photoradical generator such as a benzophenone compound is used. As a result, even in a case where the ultraviolet irradiation is carried out under a mild temperature condition such as room temperature, sufficient radical species are generated, the radical species directly or indirectly react with the dye, and then the dye is decomposed, whereby the dye is faded and decolorized.

In addition, in the light absorption disappearing layer constituting the light absorption filter according to the embodiment of the present invention, in a case where the compound A having an acid group is bonded to the polymer constituting the resin contained in the light absorption disappearing layer, the radical is generated in the vicinity of the dye upon ultraviolet irradiation, and the effect of making the radical easily react with the dye is exhibited.

Further, “the compound B having a structure that is capable of forming a hydrogen bond with the acid group contained in the compound A” described above is dispersed (preferably dissolved) in the resin by forming a hydrogen bond with the compound A or forms a hydrogen bond with the compound A in the resin in a case where the compound A containing the acid group is bonded to a polymer that constitutes the resin. In a case of being subjected to ultraviolet irradiation, the compound B generates a radical, and this radical easily reacts with a dye, which makes it possible for a dye to be efficiently faded and decolorized by a mechanism in which the generated radical reacts with a dye in the vicinity.

Hereinafter, the light absorption disappearing layer constituting the light absorption filter according to the embodiment of the present invention will be described in detail.

### <<Light Absorption Disappearing Layer>>

<Dye Having Main Absorption Wavelength Band in Wavelength Range of 400 to 700 nm>

Specific examples of the dye having a main absorption wavelength band in a wavelength range of 400 to 700 nm, which is used in the light absorption disappearing layer constituting the light absorption filter according to the embodiment of the present invention, include each coloring agent (dye) of squaraine (SQ), cyanine (CY), benzylidene, cinnamylidene, azo, and indoaniline.

Among these, from the viewpoint that a secondary coloration structure is less likely to be generated due to the decomposition of the dye, the light absorption disappearing layer preferably contains at least one of an azo coloring agent represented by any of General Formulae (i) to (iv) or an indoaniline coloring agent represented by General Formula (v). The azo coloring agent represented by General Formula (i) described later is a dye having a main absorption wavelength band in a wavelength range of approximately 400 to 500 nm, the azo coloring agent represented by any of General Formulae (ii) to (iv) described later is a dye having a main absorption wavelength band in a wavelength range of approximately 450 to 650 nm, and the indoaniline-based coloring agent represented by General Formula (v) described later is a dye having a main absorption wavelength band in a wavelength range of approximately 580 to 700 nm. In the form in which the light absorption disappearing layer has such a configuration, the light absorption disappearing layer can exhibit excellent decolorization properties upon ultraviolet irradiation.

Each of the azo coloring agent represented by General Formula (i), the azo coloring agent represented by General Formula (ii), the azo coloring agent represented by General Formula (iii), the azo coloring agent represented by General Formula (iv), and the indoaniline coloring agent represented by General Formula (v), which can be contained in the light absorption disappearing layer, may be used alone or in combination of two or more kinds thereof.

The light absorption disappearing layer may contain a squaraine coloring agent represented by General Formula (1) described in the wavelength-selective absorption layer described later.

The light absorption disappearing layer can also contain a dye other than the azo coloring agent represented by any of General Formulae (i) to (iv), the indoaniline coloring agent represented by General Formula (v), and the squaraine coloring agent represented by General Formula (1) described later. By optimizing the blending ratio of the azo coloring agent represented by any of General Formulae (i) to (iv) and the indoaniline coloring agent represented by General Formula (v), it is possible to suppress a change in tint of reflected light as compared with a case where the dye is not contained, in combination with the wavelength-selective absorption layer described later (hereinafter, also referred to as “adjusting the tint of reflected light to be more neutral”).

From the viewpoint of more easily achieving both the suppression of external light reflection and the suppression of brightness reduction, it is preferable that the light absorption disappearing layer contains a dye having absorption in a wavelength range where the absorbance is low with respect to the main absorption wavelength band of each dye contained in the wavelength-selective absorption layer described later.

Specifically, it is preferable that the light absorption disappearing layer contains a dye having a main absorption wavelength band separated by 5 nm or more from any of the main absorption wavelength bands of each dye contained in the wavelength-selective absorption layer described later.

In a form applied to an OLED display device, the “dye” contained in the light absorption disappearing layer preferably includes at least one of the following dyes E to G having a main absorption wavelength band in different wavelength ranges.
Dye E: a dye having a main absorption wavelength band in a wavelength range of 430 to 480 nm
Dye F: a dye having a main absorption wavelength band in a wavelength range of 500 to 570 nm
Dye G: a dye having a main absorption wavelength band in a wavelength range of 600 to 660 nm

The above-described dye E that can be contained in the light absorption disappearing layer may be one kind or two or more kinds. The above-described dyes F and G that can be contained in the light absorption disappearing layer may be each independently one kind or two or more kinds, similarly to the dye E.

The wavelength range in which the dye E has a main absorption wavelength band is preferably 430 to 475 nm, more preferably 430 to 470 nm, and still more preferably 430 to 465 nm.

The wavelength range in which the dye F has a main absorption wavelength band is preferably 505 to 560 nm, more preferably 510 to 555 nm, and still more preferably 515 to 555 nm.

The wavelength range in which the dye G has a main absorption wavelength band is preferably 610 to 655 nm, more preferably 610 to 650 nm, and still more preferably 610 to 640 nm.

The light absorption disappearing layer can also contain a dye other than the dyes E to G.

In particular, from the viewpoint of combination with a wavelength-selective absorption layer described later, the dye E, the dye F, and the dye G are preferably a combination of at least two kinds, and it is more preferable to contain all of three kinds. Among these, it is preferable that the wavelength-selective absorption layer described later contains all of the dyes A to D described later, and the light absorption disappearing layer contains all of the dyes E to G from the viewpoint that suppression of external light reflection and suppression of brightness reduction of the optical filter can be realized at a higher level, and in a case where the obtained optical filter is applied to a display device, the tint of reflected light can be adjusted to be more neutral.

In a relationship with the dye that can be contained in the wavelength-selective absorption layer described later, it is preferable that the main absorption wavelength band of the dye E is separated from the main absorption wavelength band of the dye A described later by 5 to 70 nm (more preferably 5 to 60 nm) and is separated from the main absorption wavelength band of the dye B described later by 5 to 80 nm (more preferably 10 to 80 nm).

In addition, it is preferable that the main absorption wavelength band of the dye F is separated from the main absorption wavelength band of the dye B described later by 5 to 60 nm (more preferably 10 to 50 nm) and is separated from the main absorption wavelength band of the dye C described later by 5 to 60 nm (more preferably 10 to 50 nm).

In addition, it is preferable that the main absorption wavelength band of the dye G is separated from the main absorption wavelength band of the dye C described later by 5 to 60 nm (more preferably 10 to 50 nm) and is separated from the main absorption wavelength band of the dye D described later by 5 to 80 nm (more preferably 10 to 60 nm).

In the present invention, in the coloring agent represented by each general formula, a cation is present in a delocalized manner, and thus a plurality of tautomer structures are present. Therefore, in the present invention, in a case where at least one tautomer structure of a certain coloring agent matches with each general formula, the certain coloring agent shall be a coloring agent represented by the general formula. Therefore, a coloring agent represented by a specific general formula can also be said to be a coloring agent having at least one tautomer structure that can be represented by the specific general formula. In the present invention, a coloring agent represented by a general formula may have any tautomer structure as long as at least one tautomer structure of the coloring agent matches the general formula.

### (1-1) Azo Coloring Agent Represented by General Formula (i)

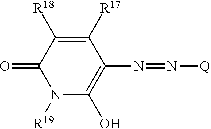

In the formula, R¹⁷ and R¹⁸ each independently represent a hydrogen atom or a monovalent substituent.

R¹⁹ represents a hydrogen atom, an aliphatic group, an aryl group, a heterocyclic group, a carbamoyl group, an alkoxycarbonyl group, an aryloxycarbonyl group, an acyl group, an alkylsulfonyl group, an arylsulfonyl group, or a sulfamoyl group.

Q represents a diazo component residue.

Examples of the monovalent substituent that can be adopted as R¹⁷ and R¹⁸ include a halogen atom, an aliphatic group, an aryl group, a heterocyclic group, a cyano group, a carboxy group, a carbamoyl group, an aliphatic oxycarbonyl group, an aryloxycarbonyl group, an acyl group, a hydroxy group, an aliphatic oxy group, an aryloxy group, an acyloxy group, a carbamoyloxy group, a heterocyclic oxy group, an amino group (—NH₂), an aliphatic amino group, an arylamino group, a heterocyclic amino group, an acylamino group, a carbamoylamino group, a sulfamoylamino group, an aliphatic oxycarbonylamino group, an aryloxycarbonylamino group, an aliphatic sulfonylamino group, an arylsulfonylamino group, a nitro group, an aliphatic thio group, an arylthio group, an aliphatic sulfonyl group, an arylsulfonyl group, a sulfamoyl group, a sulfo group, an imide group, and a heterocyclic thio group. Among these, an aliphatic group, an aryl group, a heterocyclic group, a cyano group, a carbamoyl group, an aliphatic oxycarbonyl group, an aryloxycarbonyl group, an acyl group, an aliphatic oxy group, an aryloxy group, an aliphatic amino group, or an arylamino group is preferable mainly from the viewpoint of imparting solubility.

The substituents that can be adopted as R¹⁷ and R¹⁸ may be further substituted.

The aliphatic group that can be adopted as R¹⁷ to R¹⁹ may further have a monovalent substituent, may be saturated or unsaturated, and may be cyclic. Specific examples thereof include an alkyl group, a substituted alkyl group, an alkenyl group, a substituted alkenyl group, an alkynyl group, a substituted alkynyl group, an aralkyl group, and a substituted aralkyl group. The total number of carbon atoms in the aliphatic group is preferably 1 to 30 and more preferably 1 to 16. Specific examples of the aliphatic group include a methyl group, an ethyl group, a butyl group, an isopropyl group, a t-butyl group, a hydroxyethyl group, a methoxyethyl group, a cyanoethyl group, a trifluoromethyl group, a 3-sulfopropyl group, a 4-sulfobutyl group, a 2-(2-hydroxyethoxy)ethyl group, a 2-(2-(acetyloxy)ethoxy)ethyl group, a cyclohexyl group, a benzyl group, a 2-phenethyl group, a vinyl group, and an allyl group.

It is noted that Examples of the monovalent substituent which may be contained include the monovalent substituents that can be adopted as R¹⁷ and R¹⁸, and the same applies to the following description regarding the monovalent substituent which may be contained. The monovalent substituent which may be contained is, for example, preferably an alkoxy group, an acyloxy group, or a hydroxy group. In addition, this substituent may further have a substituent, and preferred examples thereof include an alkoxy group, an acyloxy group, and a hydroxy group.

The aryl group that can be adopted as R¹⁷ to R¹⁹ may further have a monovalent substituent, and the aryl group is preferably an aryl group having a total number of carbon atoms of 6 to 30, and more preferably an aryl group having a total number of carbon atoms of 6 to 16. Specific examples thereof include a phenyl group, a 4-tolyl group, a 4-methoxyphenyl group, a 2-chlorophenyl group, a 3-(3-sulfopropylamino)phenyl group, a 4-sulfamoylphenyl group, a 4-(ethoxyethylsulfamoyl)phenyl group, and a 3-(dimethylcarbamoyl)phenyl group.

The heterocyclic group that can be adopted as R¹⁷ to R¹⁹ may be a saturated or unsaturated aliphatic ring group or may be an aromatic ring group, and it is preferably an aromatic heterocyclic group. Examples of the ring-constituting atom constituting the heterocyclic group include those containing at least any one of a heteroatom such as a nitrogen atom, a sulfur atom, or an oxygen atom, where the heterocyclic group may further have a monovalent substituent. The heterocyclic group is preferably a heterocyclic group having a total number of carbon atoms of 1 to 30, and more preferably a heterocyclic group having a total number of carbon atoms of 1 to 15. Specific examples thereof include a 2-pyridyl group, a 2-thienyl group, a 2-thiazolyl group, a 2-benzothiazolyl group, a 2-benzoxazolyl group, and a 2-furyl group.

The carbamoyl group that can be adopted as R¹⁷ to R¹⁹ includes, in addition to an unsubstituted carbamoyl group (—CONH₂), a carbamoyl group substituted with an aliphatic group, an aryl group, or the like.

The carbamoyl group that can be adopted as R¹⁷ to R¹⁹ may further have a monovalent substituent, and the carbamoyl group is preferably a carbamoyl group having a total number of carbon atoms of 1 to 30, and more preferably a carbamoyl group having 1 to 16 carbon atoms. Specific examples thereof include a methylcarbamoyl group, a dimethylcarbamoyl group, a phenylcarbamoyl group, and an N-methyl-N-phenylcarbamoyl group.

To the aliphatic group in the aliphatic oxycarbonyl group that can be adopted as R¹⁷ and R¹⁸, the description of the aliphatic group that can be adopted as R¹⁷ to R¹⁹ can be applied.

The aliphatic oxycarbonyl group that can be adopted as R¹⁷ and R¹⁸ may further have a monovalent substituent, may be saturated or unsaturated, or may be cyclic, and the aliphatic oxycarbonyl group is preferably an aliphatic oxycarbonyl group having a total number of carbon atoms of 2 to 30, and more preferably an aliphatic oxycarbonyl group having a total number of carbon atoms of 2 to 16. Specific examples thereof include a methoxycarbonyl group, an ethoxycarbonyl group, and a 2-methoxyethoxycarbonyl group.

The alkoxycarbonyl group that can be adopted as R¹⁹ may further have a monovalent substituent, may be saturated or unsaturated, or may be cyclic, and the alkoxycarbonyl group is preferably an alkoxycarbonyl group having a total number of carbon atoms of 2 to 30 and more preferably an alkoxycarbonyl group having a total number of carbon atoms of 2 to 16. Specific examples thereof include a methoxycarbonyl group, an ethoxycarbonyl group, and a 2-methoxyethoxycarbonyl group.

The aryloxycarbonyl group that can be adopted as R¹⁷ to R¹⁹ may further have a monovalent substituent, and it is preferably an aryloxycarbonyl group having a total number of carbon atoms of 7 to 30 and more preferably an aryloxycarbonyl group having the number of carbon atoms of 7 to 16. Specific examples thereof include a phenoxycarbonyl group, a 4-methylphenoxycarbonyl group, and a 3-chlorophenoxycarbonyl group.

The acyl group that can be adopted as R¹⁷ to R¹⁹ includes an aliphatic carbonyl group, an arylcarbonyl group, and a heterocyclic carbonyl group, where an aspect in which the total number of carbon atoms is 1 to 30 is preferable, and an aspect in which the total number of carbon atoms is 1 to 16 is more preferable. Specific examples thereof include an acetyl group, a methoxyacetyl group, a thienoyl group, and a benzoyl group.

To the aliphatic group in the aliphatic sulfonyl group that can be adopted as R¹⁷ and R¹⁸, the description of the aliphatic group that can be adopted as R¹⁷ to R¹⁹ can be applied.

The aliphatic sulfonyl group that can be adopted as R¹⁷ and R¹⁸ may further have a monovalent substituent, may be saturated or unsaturated, or may be cyclic, where an aspect in which the total number of carbon atoms is 1 to 30 is preferable, and an aspect in which the total number of carbon atoms is 1 to 16 is more preferable. Specific examples thereof include a methanesulfonyl group, a methoxymethanesulfonyl group, and an ethoxyethanesulfonyl group.

The alkylsulfonyl group that can be adopted as R¹⁹ may further have a monovalent substituent, may be saturated or unsaturated, or may be cyclic, where an aspect in which the total number of carbon atoms is 1 to 30 is preferable, and an aspect in which the total number of carbon atoms is 1 to 16 is more preferable. Specific examples thereof include a methanesulfonyl group, a methoxymethanesulfonyl group, and an ethoxyethanesulfonyl group.

The arylsulfonyl group that can be adopted as R¹⁷ to R¹⁹ may further have a monovalent substituent, where an aspect in which the total number of carbon atoms is 6 to 30 is preferable, and an aspect in which the total number of carbon atoms is 6 to 18 is more preferable. Specific examples thereof include a benzenesulfonyl group and a toluenesulfonyl group.

The sulfamoyl group that can be adopted as R¹⁷ to R¹⁹ includes a sulfamoyl group substituted with an aliphatic group, an aryl group, or the like, in addition to an unsubstituted sulfamoyl group (—SO₂NH₂).

The sulfamoyl group that can be adopted as R¹⁷ to R¹⁹ may further have a monovalent substituent, where an aspect in which the total number of carbon atoms is 0 to 30 is preferable, and an aspect in which the total number of carbon atoms is 0 to 16 is more preferable. Specific examples thereof include an unsubstituted sulfamoyl group, a dimethylsulfamoyl group, and a di-(2-hydroxyethyl)sulfamoyl group.

The imide group that can be adopted as R¹⁷ and R¹⁸ may further have a monovalent substituent, and it is preferably an imide group of a 5- or 6-membered ring. In addition, an aspect in which the total number of carbon atoms in the imide group is 4 to 30 is preferable, and an aspect in which the total number of carbon atoms in the imide group is 4 to 20 is more preferable. Specific examples thereof include a succinimide group and a phthalimide group.

To the aliphatic group in the aliphatic oxy group, the aliphatic amino group, the aliphatic oxycarbonylamino group, the aliphatic sulfonylamino group, and the aliphatic thio group, which can be adopted as R¹⁷ and R¹⁸, the description of the aliphatic group that can be adopted as R¹⁷ to R¹⁹ can be applied.

To the aryl group in the aryloxy group, the arylamino group, the aryloxycarbonylamino group, the arylsulfonylamino group, and the arylthio group, which can be adopted as R¹⁷ and R¹⁸, the description of the aryl group that can be adopted as R¹⁷ to R¹⁹ can be applied.

To the acyl group in the acyloxy group and the acylamino group, which can be adopted as R¹⁷ and R¹⁸, the description of the acyl group, which can be adopted as R¹⁷ to R¹⁹, can be applied.

To the carbamoyl group in the carbamoyloxy group and the carbamoylamino group, which can be adopted as R¹⁷ and R¹⁸, the description of the carbamoyl group, which can be adopted as R¹⁷ to R¹⁹, can be applied.

To the heterocyclic group in the heterocyclic oxy group, the heterocyclic amino group, and the heterocyclic thio group, which can be adopted as R¹⁷ and R¹⁸, the description of the heterocyclic group, which can be adopted as R¹⁷ to R¹⁹, can be applied.

To the sulfamoyl group in the sulfamoylamino group that can be adopted as R¹⁷ and R¹⁸, the description of the sulfamoyl group, which can be adopted as R¹⁷ to R¹⁹, can be applied.

The diazo component residue represented by Q means a residue of a diazo component “Q-NH₂”. In particular, from the viewpoint of more neutrally adjusting the tint of the target reflected light, Q is preferably an aryl group or an aromatic heterocyclic group.

The aromatic hydrocarbon ring constituting the aryl group that can be adopted as Q may be a monocyclic ring or a fused ring, and it is preferably a monocyclic ring. It is preferably an aryl group having a total number of carbon atoms of 6 to 30, and more preferably an aryl group having a total number of carbon atoms of 6 to 16. Specifically, a phenyl group is preferable. The aryl group that can be adopted as Q may have a substituent, and preferred examples of the substituent that may be contained include a sulfamoyl group (preferably an alkylsulfamoyl group or a dialkylsulfamoyl group), a sulfonyl group (preferably an alkylsulfonyl group), and a cyano group.

The aromatic heterocyclic group that can be adopted as Q is an aromatic ring group containing, as a ring-constituting atom constituting a heterocyclic group, at least any one among heteroatoms such as a nitrogen atom, a sulfur atom, and an oxygen atom, where the aromatic heterocyclic group is preferably composed of a 5- or 6-membered ring. The number of carbon atoms in the aromatic heterocyclic group is preferably 1 to 25 and more preferably 1 to 15. The aromatic heterocyclic ring constituting the aromatic heterocyclic group may be a monocyclic ring or a fused ring, and it is preferably a monocyclic ring.

Specific examples of the aromatic heterocyclic group include a pyrazole group, a 1,2,4-triazole group, an isothiazole group, a benzisothiazole group, a thiazole group, a benzothiazole group, an oxazole group, and a 1,2,4-thiadiazole group.

As an example of the azo coloring agent represented by General Formula (i), the description of specific examples of the azo coloring agent represented by General Formula (i) described in paragraph 0042 of WO2023/234353A can be applied as it is. However, the present invention is not limited thereto.

### (1-2) Azo Coloring Agent Represented by General Formula (ii)

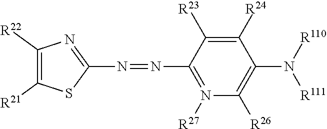

In the formula, R²¹ to R²⁴, R²⁶, and R²⁷ represent a hydrogen atom, a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, or a heterocyclic group.

R¹⁰⁸ to R¹²¹ represent a hydrogen atom, an acyclic hydrocarbon group, a monocyclic hydrocarbon group, a fused polycyclic hydrocarbon group, or a heterocyclic group, and n represents a positive integer.

It is noted that the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, and a heterocyclic group.

The acyclic hydrocarbon group that can be adopted as R²¹ to R²⁴, R²⁶, R²⁷, and R¹⁰⁸ to R¹²¹ means an acyclic alkyl group in which one hydrogen atom is removed from an acyclic alkane. However, the acyclic alkyl group may have a ring structure as a substituent. The number of carbon atoms in the acyclic alkyl group is preferably 1 to 30, more preferably 1 to 20, still more preferably 1 to 12, particularly preferably 1 to 8, and among these, it is preferably 1 to 6.

The monocyclic hydrocarbon group that can be adopted as R²¹ to R²⁴, R²⁶, R²⁷, and R¹⁰⁸ to R¹²¹ means a monocyclic cycloalkyl group, a monocyclic cycloalkenyl group, a monocyclic cycloalkynyl group, or a monocyclic aryl group, which is a group in which one hydrogen atom is removed from a monocyclic aliphatic hydrocarbon ring (which may be any of a monocyclic cycloalkane, a monocyclic cycloalkene, or a monocyclic cycloalkyne) or a monocyclic aromatic hydrocarbon ring.

The number of carbon atoms in the monocyclic cycloalkyl group, the monocyclic cycloalkenyl group, and the monocyclic cycloalkynyl group is not particularly limited as long as it is allowed in terms of the structure; however, it is more preferably 3 to 30, more preferably 3 to 20, and still more preferably 3 to 16. The number of carbon atoms in the monocyclic aryl group is more preferably 6 to 30, still more preferably 6 to 20, and particularly preferably 6 to 16.

The fused polycyclic hydrocarbon group that can be adopted as R²¹ to R²⁴, R²⁶, R²⁷, and R¹⁰⁸ to R¹²¹ means a fused polycyclic cycloalkyl group, a fused polycyclic cycloalkenyl group, a fused polycyclic cycloalkynyl group, or a fused polycyclic aryl group, which is a group in which one hydrogen atom is removed from a fused polycyclic aliphatic hydrocarbon ring (which may be any of a fused polycyclic cycloalkane, a fused polycyclic cycloalkene, or a fused polycyclic cycloalkyne) or a fused polycyclic aromatic hydrocarbon ring.

The number of carbon atoms in the fused polycyclic cycloalkyl group, the fused polycyclic cycloalkenyl group, and the fused polycyclic cycloalkynyl group is not particularly limited as long as it is allowed in terms of the structure; however, it is more preferably 8 to 30 and more preferably 8 to 20. The number of carbon atoms in the fused polycyclic aryl group is more preferably 10 to 30 and more preferably 10 to 20.

To the heterocyclic group that can be adopted as R²¹ to R²⁴, R²⁶, R²⁷, and R¹⁰⁸ to R¹²¹, the description of the heterocyclic group that can be adopted as R¹⁷ to R¹⁹ in General Formula (i) can be applied.
n is preferably an integer of 1 to 12, more preferably an integer of 1 to 6, and still more preferably an integer of 1 to 3.

Regarding the specific group of each of the substituents in General Formula (ii), unless otherwise specified, the descriptions regarding R¹ to R⁴, R⁶, R⁷, and R⁸ to R²¹ for the compound represented by General Formula [1] described in JP1993-257180A (JP-H5-257180A) can be applied as they are to R²¹ to R²⁴, R²⁶, R²⁷, and R¹⁰⁸ to R¹²¹, respectively.

R²¹ is preferably a cyano group, a nitro group, —OR¹⁰⁸, an acyclic hydrocarbon group (preferably an acyclic alkyl group or an acyclic alkenyl group), or a heterocyclic group, more preferably a cyano group or a nitro group, or an acyclic alkyl group (preferably an alkyl group substituted with a fluorine atom) substituted with a halogen atom, and still more preferably a cyano group.

R²² is preferably a hydrogen atom, a cyano group, an acyclic hydrocarbon group (preferably an acyclic alkyl group), or a monocyclic hydrocarbon group, more preferably a hydrogen atom, an alkyl group, or an aryl group, and still more preferably an alkyl group or an aryl group.

It is noted that at least one of R²¹ or R²² is preferably a cyano group or a nitro group, or an acyclic alkyl group substituted with a halogen atom, a cyano group, or a nitro group.

R²³ is preferably a hydrogen atom, —OR¹⁰⁸, —SR¹⁰⁹, —NR¹¹⁰R¹¹¹, —C(═O)NR¹¹⁴R¹¹⁵, —NHC(═O)R¹¹⁶, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, or an acyclic hydrocarbon group (preferably an acyclic alkyl group), more preferably a hydrogen atom, —OR¹⁰⁸, —SR¹⁰⁹, —NR¹¹⁰R¹¹¹, —NHC(═O)R¹¹⁶, or an acyclic alkyl group, and still more preferably —NHC(═O)R¹¹⁶. Here, R¹⁰⁸ to R¹¹¹, R¹¹⁶, and R¹¹⁸ to R¹²¹ are preferably an acyclic alkyl group.

R²⁴ and R²⁷ are preferably a hydrogen atom.

R²⁶ is preferably a hydrogen atom, —OR¹⁰⁸, —SR¹⁰⁹, —NR¹¹⁰R¹¹¹, —NHC(═O)R¹¹⁶, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, or an acyclic hydrocarbon group (preferably an acyclic alkyl group), more preferably a hydrogen atom, —OR¹⁰⁸, or —SR¹⁰⁹, and still more preferably a hydrogen atom. Here, R¹⁰⁸ to R¹¹¹, R¹¹⁶, and R¹¹⁸ to R¹²¹ are preferably an acyclic alkyl group.

In —NR¹¹⁰R¹¹¹ that is located at the ortho position with respect to R²⁴ and R²⁶, R¹¹⁰ is preferably an acyclic alkyl group, and R¹¹¹ is preferably an acyclic alkyl group, more preferably an unsubstituted acyclic alkyl group or an acyclic alkyl group having —OR¹⁰⁸, a monocyclic hydrocarbon group, or a fused polycyclic hydrocarbon group as a substituent. Here, R¹⁰⁸ is preferably a hydrogen atom or an acyclic alkyl group.

Specific examples of the coloring agent represented by General Formula (ii) include, in addition to the compounds that are used in Examples described later, the compounds described in paragraphs 0023 to 0034 of JP1993-257180A (JP-H5-257180A), and the compounds described in paragraphs 0050 and 0052, the compound D-18 described in paragraph 0055, and the compound described in paragraph 0056 of JP2013-129712A. However, the present invention is not limited thereto.

(1-3) Azo Coloring Agent Represented by General Formula (iii)

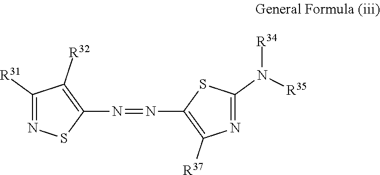

In the formula, R³¹ represents a hydrogen atom, an alkyl group, an alkoxy group, a cyano group, a carbonyl group (an alkyloxycarbonyl group or an aryloxycarbonyl group is preferable), an aromatic group, or a heterocyclic group.

R³² represents a hydrogen atom, an alkyl group, an alkoxy group, a cyano group, a nitro group, a carbonyl group (an alkyloxycarbonyl group or an aryloxycarbonyl group is preferable), an aromatic group, or a heterocyclic group.

R³⁴ and R³⁵ each independently represent a hydrogen atom, an alkyl group, or an aromatic group.

R³⁷ represents a hydrogen atom, an alkyl group, an alkoxy group, a cyano group, a carbonyl group (an alkyloxycarbonyl group or an aryloxycarbonyl group is preferable), an acylamino group, or an aromatic group.

R³⁴ and R³⁵ may be bonded to each other to form a ring.

Regarding the definition and the preferred range of each of the substituents in General Formula (iii), unless otherwise specified, the descriptions regarding R¹ and R² regarding General Formula (1) described in JP2013-129712A can be applied as they are to R³¹ and R³², respectively, and the description regarding R⁴, R⁵, and R⁷ regarding General Formula (3) described in JP2013-129712A can be applied as it is to R³⁴, R³⁵, and R³⁷, respectively.

It is noted that, in the present invention, R³⁷ can adopt the following acylamino group in addition to the hydrogen atom, the alkyl group, the alkoxy group, the cyano group, the carbonyl group, and the aromatic group, which can be adopted by R⁷ regarding General Formula (3) described in JP2013-129712A.

The number of carbon atoms in the acylamino group that can be adopted as R³⁷ is preferably 1 to 12 and more preferably 1 to 6.

In the present invention, the number of carbon atoms in the alkyl group that can be adopted as R³¹, R³², and R³⁷ is more preferably 1 to 20, still more preferably 1 to 12, and particularly preferably 1 to 6.

The number of carbon atoms in the alkoxy group that can be adopted as R³¹, R³², and R³⁷ is more preferably 1 to 20, still more preferably 1 to 12, and particularly preferably 1 to 6.

The number of carbon atoms in the alkyloxycarbonyl group that can be adopted as R³¹, R³², and R³⁷ is preferably 2 to 30, more preferably 2 to 20, still more preferably 2 to 12, and particularly preferably 2 to 7.

The number of carbon atoms in the alkyl group that can be adopted as R³⁴ and R³⁵ is preferably 1 to 30, more preferably 1 to 20, and still more preferably 1 to 12.

R³¹ is preferably an alkyl group or an aryl group, and more preferably an alkyl group.

R³² is preferably an alkyl group or a cyano group, and more preferably a cyano group.

R³⁴ and R³⁵ are preferably a hydrogen atom or an alkyl group, and more preferably an alkyl group.

R³⁷ is preferably a hydrogen atom, an alkyl group, an acylamino group, or an aromatic group, more preferably a hydrogen atom or an alkyl group, and still more preferably an alkyl group.

As specific examples of the coloring agent represented by General Formula (iii), for example, the description of specific examples of the azo coloring agent represented by General Formula (iii) described in paragraphs 0056 to 0058 of WO2023/234353A can be applied as it is. However, the present invention is not limited thereto.

### (1-4) Azo Coloring Agent Represented by General Formula (iv)

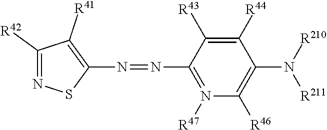

In the formula, R⁴¹ to R⁴⁴, R⁴⁶, and R⁴⁷ represent a hydrogen atom, a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)R²¹⁸, —O(CH₂CH₂S)ₙR²¹⁹, —S(CH₂CH₂O)ₙR²²⁰, —S(CH₂CH₂S)ₙR²²¹, an acyclic hydrocarbon group, a monocyclic hydrocarbon group, a fused polycyclic hydrocarbon group, or a heterocyclic group.

R²⁰⁸ to R²²¹ represent a hydrogen atom, an acyclic hydrocarbon group, a monocyclic hydrocarbon group, a fused polycyclic hydrocarbon group, or a heterocyclic group, and n is a positive integer.

The acyclic hydrocarbon group, the monocyclic hydrocarbon group, the fused polycyclic hydrocarbon group, and the heterocyclic group may have, as a substituent, one or two or more of a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, and —S(CH₂CH₂S)ₙR²²¹.

Unless otherwise specified, the description of R²¹ to R²⁴, R²⁶, R²⁷, R¹⁰⁸ to R¹²¹, and n in General Formula (ii) described above can be applied as it is to R⁴¹ to R⁴⁴, R⁴⁶, R⁴⁷, R²⁰⁸ to R²²¹, and n in General Formula (iv).

R⁴³ is preferably a hydrogen atom, —OR²⁰⁸, —SR²⁰⁹, —NR²¹⁰R²¹¹, —NHC(═O)R²¹⁶, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, or an acyclic hydrocarbon group (preferably an acyclic alkyl group), more preferably a hydrogen atom, —OR²⁰⁸, —SR²⁰⁹, —NR²¹⁰R²¹¹, —NHC(═O)R²¹⁶, or an acyclic alkyl group, and still more preferably —NHC(═O)R²¹⁶ or an acyclic alkyl group. Here, R²⁰⁸ to R²¹¹, R²¹⁶, and R²¹⁸ to R²²¹ are preferably an acyclic alkyl group.

In —NR²¹⁰R²¹¹ that is located at the ortho position with respect to R⁴⁴ and R⁴⁶, R²¹⁰ is preferably an acyclic alkyl group, and R²¹¹ is preferably an acyclic alkyl group and more preferably an unsubstituted acyclic alkyl group (including an acyclic alkyl group substituted with an acyclic alkyl group) or an acyclic alkyl group having —OR²⁰⁸, a monocyclic hydrocarbon group, or a fused polycyclic hydrocarbon group as a substituent. Here, R²⁰⁸ is preferably a hydrogen atom or an acyclic alkyl group.

It is noted that R⁴⁴ and/or R⁴⁶ in General Formula (iv) may be bonded to R²¹⁰ and/or R²¹¹ in —NR²¹⁰R²¹¹ located at the ortho position with respect to R⁴⁴ and R⁴⁶ on the benzene ring, thereby forming a ring. The ring which may be formed is preferably a 5- or 6-membered ring and may be saturated or unsaturated, and it is preferably a saturated 6-membered ring. The ring which may be formed may further have a substituent, and for example, it preferably has an alkyl group.

Among these, regarding a form in which a ring is formed, it is preferable that R⁴⁶ and R²¹¹ in —NR²¹⁰R²¹¹ that is located at the ortho position with respect to R⁴⁴ and R⁴⁶ on the benzene ring are bonded to each other to form a saturated 6-membered ring.

Specific examples of the coloring agent represented by General Formula (iv) include, in addition to the compounds that are used in Examples described later, the compounds described in paragraph 0053 of JP2013-129712A. However, the present invention is not limited thereto.

### (1-5) Indaniline Coloring Agent Represented by General Formula (v)

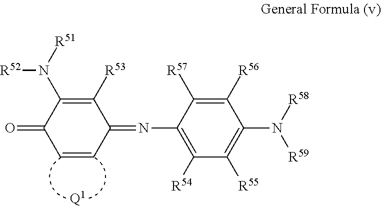

In the formula, Q¹ represents an atomic group that contains at least one nitrogen atom and is necessary for forming a 5- to 7-membered nitrogen-containing heterocyclic ring together with carbon atoms to be bonded.

R⁵¹ represents an acyl group, an alkoxycarbonyl group, an aryloxycarbonyl group, an aminocarbonyl group, or a sulfonyl group, R⁵² represents a hydrogen atom or an alkyl group, R⁵³ to R⁵⁷ represent a hydrogen atom, an alkyl group, an alkoxy group, an acylamino group, an alkylsulfonylamino group, or a halogen atom, and R⁵⁸ and R⁵⁹ represent a hydrogen atom, an alkyl group, or an aryl group.

R⁵¹ and R⁵³, R¹⁴ and R⁵⁵, and/or R⁵⁵ and R⁵⁹, or R¹⁸ and R⁵⁹ may be bonded to each other to form a ring. That is, it means that R⁵¹ and R⁵³ may be bonded to each other to form a ring, R⁵⁴ and R⁵⁵ and/or R⁵⁵ and R⁵⁹ may be bonded to each other to form a ring, or R¹⁸ and R⁵⁹ may be bonded to each other to form a ring.

Regarding the definition and the preferred range of each of the substituents in General Formula (v), unless otherwise specified, the descriptions regarding R¹ to R⁶, R⁸, R⁹, and Q¹ in General Formula (I) described in JP1990-92686A (JP-H2-92686A) can be applied as they are to R⁵¹ to R⁵⁶, R⁵⁸, R⁵⁹, and Q¹, respectively.

It is noted that in the present invention, R⁵³ to R⁵⁶ can adopt the following acylamino group and alkylsulfonylamino group, in addition to the hydrogen atom, the alkyl group, the alkoxy group, and the halogen atom, which can be adopted by R³ to R⁶ regarding General Formula (I) described in JP1990-92686A (JP-H2-92686A).

The number of carbon atoms in the acylamino group that can be adopted as R⁵³ to R⁵⁷ is preferably 1 to 12 and more preferably 1 to 6.

The number of carbon atoms in the alkylsulfonylamino group that can be adopted as R⁵³ to R⁵⁷ is preferably 1 to 12 and more preferably 1 to 6.

To the alkyl group, the alkoxy group, and the halogen atom, which can be adopted as R⁵⁷, the descriptions of the alkyl group, the alkoxy group, and the halogen atom, which can be adopted as R⁵³ to R⁵⁶, can be applied as they are.

Q¹ is preferably represented by —NR¹⁶C(═O)-Q²-. Q² represents an atomic group required for forming a 5- to 7-membered nitrogen-containing heterocyclic ring together with a carbon atom to which —NR¹⁶C(═O)-Q²- is bonded and —NR¹⁶C(═O)—, and examples thereof include a divalent amino group, an ether bond, a thioether bond, an alkylene bond, an ethylene bond, an imino bond, a sulfonyl bond, a carbonyl bond, an arylene bond or a divalent heterocyclic group, and a group obtained by combining a plurality of these. R¹⁶ represents a hydrogen atom, an alkyl group, an aryl group, or a heterocyclic group, where a hydrogen atom is preferable. To each of the definition and the preferred range of each substituent of R¹⁶, the description regarding R¹⁶ regarding General Formula (I) described in JP1990-92686A (JP-H2-92686A) can be applied as it is.

R⁵¹ is preferably an acyl group having 2 to 7 carbon atoms or an alkoxycarbonyl group having 2 to 7 carbon atoms.

R⁵² is preferably a hydrogen atom, and R⁵³ to R⁵⁶ are preferably a hydrogen atom.

R⁵⁷ is preferably an alkoxy group, an acylamino group, or an alkylsulfonylamino group, and more preferably an alkoxy group or an acylamino group.

R⁵⁸ and R⁵⁹ are preferably an alkyl group having 1 to 6 carbon atoms.

Among the above, the indoaniline-based coloring agent represented by General Formula (v) is preferably represented by General Formula (v-a).

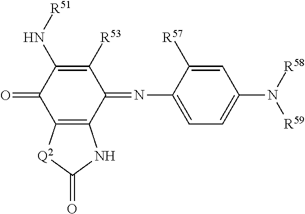

In the formula, R⁵¹, R⁵³, R⁵⁷ to R⁵⁹, and Q² have the same meanings as R⁵¹, R⁵³, R⁵⁷ to R⁵⁹, and Q² in General Formula (v).

Q² is preferably —CR¹¹R¹²CR¹³R¹⁴—, —CR¹¹R¹²—, or —NR¹¹—, and more preferably —CR¹¹R¹²CR¹³R¹⁴—.

R¹¹ to R¹⁴ represent a hydrogen atom or an alkyl group having 1 to 4 carbon atoms, and it is preferable that R¹¹ and R¹² are a hydrogen atom and R¹³ and R¹⁴ are an alkyl group having 1 to 4 carbon atoms.

It is noted that —CR¹¹R¹²CR¹³R¹⁴— is preferably bonded to >C═O on the side of the carbon atom to which R¹¹ and R¹² are bonded.

Specific examples of the coloring agent represented by General Formula (v) include, in addition to the compounds that are used in Examples described later, the compounds of Nos. 1 to 51 on pages 5 and 6 of JP1990-92686A (JP-H2-92686A). However, the present invention is not limited thereto.

The total content of the above-described dye in the light absorption disappearing layer is preferably 0.10% by mass or more, more preferably 0.15% by mass or more, still more preferably 0.20% by mass or more, particularly preferably 0.25% by mass or more, and especially preferably 0.30% by mass or more. In a case where the total content of the above-described dye in the light absorption disappearing layer is equal to or more than the above-described preferred lower limit value, good light absorbability such as an antireflection effect can be obtained.

In addition, the total content of the above-described dye in the light absorption disappearing layer is usually 50% by mass or less, preferably 40% by mass or less, more preferably 30% by mass or less, still more preferably 15% by mass or less, and particularly preferably 10% by mass or less.

That is, the total content of the above-described dye in the light absorption disappearing layer is preferably 0.10% to 50% by mass, more preferably 0.15% to 40% by mass, still more preferably 0.20% to 30% by mass, particularly preferably 0.25% to 15% by mass, and especially preferably 0.30% to 10% by mass.

The content of the azo coloring agent represented by General Formula (i) in the light absorption disappearing layer is preferably 0.01% to 30% by mass and more preferably 0.1% to 10% by mass. The content of each coloring agent of the azo coloring agent represented by General Formula (ii), the azo coloring agent represented by General Formula (iii), the azo coloring agent represented by General Formula (iv), and the indoaniline coloring agent represented by General Formula (v) in the light absorption disappearing layer is also preferably 0.01% to 30% by mass and more preferably 0.1% to 10% by mass, respectively, in the same manner as the content of the azo coloring agent represented by General Formula (i). In the light absorption disappearing layer, all of the above-described dyes may be composed of at least one of the azo coloring agent represented by any of General Formulae (i) to (iv) or the indoaniline coloring agent represented by General Formula (v).

<Compound that Generates Radical Upon Ultraviolet Irradiation>

The light absorption disappearing layer contains a compound that generates a radical upon ultraviolet irradiation (also simply referred to as a “radical generator” in the present invention).

The radical generator is not particularly limited as long as it is a compound that generates a radical upon ultraviolet irradiation, where the compound has a function of decolorizing the above-described dye. As the radical generator, it is possible to use, for example, a photoradical generator which may be used in combination with a compound B, will be described later.

The radical generator is preferably a combination of two or more compounds, and a combination in which two or more compounds in the light absorption disappearing layer interact with each other to form a complex or the like, resulting in the generation of a radical upon ultraviolet irradiation. Regarding the type of the compound to be combined, two or more types of compounds exhibiting functions different from each other need only to be used in a mechanism by which a radical is generated upon ultraviolet irradiation, and the type of the compound to be combined is preferably two types. Preferred examples of such a combination include a combination of a compound A having an acid group and a compound B having a structure that is capable of forming a hydrogen bond with an acid group contained in the compound A.

In a case where the light absorption disappearing layer contains the compound A having an acid group and the compound B having a structure capable of forming a hydrogen bond with the acid group contained in the compound A, the efficiency of generating a radical species upon ultraviolet irradiation is improved as compared with a case where the above-described photoradical generator is used. As a result, even in a case where the ultraviolet irradiation is carried out under a mild temperature condition such as room temperature, sufficient radical species are generated, the radical species directly or indirectly react with the dye, and then the dye is decomposed, whereby the dye is faded and decolorized. In particular, the azo coloring agent represented by any of General Formulae (i) to (iv) described above, the indoaniline coloring agent represented by General Formula (v) described above, and the squaraine coloring agent represented by General Formula (1) described later are decolorized without causing almost secondary absorption associated with the decomposition of the dye.

Hereinafter, the compound A having an acid group and the compound B having a structure that is capable of forming a hydrogen bond with the acid group contained in the compound A will be described in detail.

### (1) Compound a Having Acid Group

In the light absorption disappearing layer, it is preferable that the compound A having an acid group (in the present invention, also simply referred to as “compound A”) is contained as the radical generator together with the compound B having a structure capable of forming a hydrogen bond with the acid group contained in the compound A described later.

The acid group contained in the compound A is preferably a proton dissociable group having a pKa of 12 or less. Specific examples of the acid group include a carboxy group, a sulfonamide group, a phosphonate group (—P(═O)(OH)₂), a phosphate group (—OP(═O)(OH)₂), a sulfo group, a phenolic hydroxyl group, and a sulfonyl imide group, where a carboxy group is preferable. It is noted that pKa means a negative common logarithm (−log Ka) of the acid dissociation constant (Ka) in water at 25° C., and it can be calculated in the same manner, except that in a calculation of the pKa of the compound B described later, a mixed solvent of water/methanol=50/50 (in terms of volume ratio) is changed to water.

The compound A may be a low-molecular-weight compound or a high-molecular-weight compound (hereinafter, also referred to as a “polymer”), where a polymer is preferable.

The fact that the compound A is a polymer means that the compound A is chemically bonded to the polymer constituting the resin contained in the light absorption disappearing layer.

In a case where the compound A is a low-molecular-weight compound, the molecular weight of the compound A is less than 5,000, and it is preferably 2,000 or less, more preferably 1,000 or less, still more preferably 500 or less, and particularly preferably 400 or less. The lower limit value thereof is not particularly limited. However, it is practically 100 or more, and it is preferably 200 or more. That is, it is practically 100 or more and less than 5,000, preferably 200 to 2,000, more preferably 200 to 1,000, still more preferably 200 to 500, and particularly preferably 200 to 400.

In a case where the compound A is a polymer, the lower limit value of the weight-average molecular weight of the compound A is 5,000 or more, and it is preferably 10,000 or more and more preferably 15,000 or more from the viewpoint of physical properties of the optical filter. The upper limit value thereof is not particularly limited; however, it is preferably 500,000 or less, more preferably 200,000 or less, and still more preferably 150,000 or less from the viewpoint of solubility in a solvent. That is, 5,000 to 500,000 is practical and preferable, 10,000 to 200,000 is more preferable, and 15,000 to 150,000 is still more preferable.

In addition, a part or all of the acid groups contained in the compound A may be anionized or may not be anionized in the light absorption disappearing layer constituting the light absorption filter, and in the present invention, both the anionized acid group and the non-anionized acid group are referred to as an acid group. That is, the compound A may be anionized or may not be anionized in the light absorption disappearing layer constituting the light absorption filter.

From the viewpoint of excellent film-forming properties of the light absorption disappearing layer, the compound A is preferably a compound having a carboxy group.

The above-described compound having a carboxy group is more preferably a monomer containing a carboxy group (hereinafter, also referred to as a “carboxy group-containing monomer”) or a polymer containing a carboxy group (hereinafter, also referred to as a “carboxy group-containing polymer”), and it is more preferably a carboxy group-containing polymer from the viewpoint of the film-forming properties of the light absorption disappearing layer.

It is noted that a part or all of the carboxy groups (—COOH) contained in the carboxy group-containing monomer and the carboxy group-containing polymer may or may not be anionized in the light absorption filter, and both an anionized carboxy group (—COO⁻) and a non-anionized carboxy group are also referred to as a carboxy group.

That is, the carboxy group-containing polymer may be anionized or may not be anionized in the light absorption disappearing layer constituting the light absorption filter, and both the anionized carboxy group-containing polymer and the non-anionized carboxy group-containing polymer are referred to as a carboxy group-containing polymer.

The content of the compound A in the above-described light absorption disappearing layer is preferably 1% by mass or more, more preferably 25% by mass or more, still more preferably 30% by mass or more, particularly preferably 45% by mass or more, and especially preferably 50% by mass or more. The upper limit value of the content of the compound A is preferably less than 100% by mass, more preferably 99% by mass or less, and still more preferably 97% by mass or less. That is, it is preferably 1% by mass or more and less than 100% by mass, more preferably 25% to 99% by mass, still more preferably 30% to 97% by mass, particularly preferably 45% to 97% by mass, and especially preferably 50% to 97% by mass.

Among these, in a case where the compound A is a polymer, the content of the compound A in the above-described light absorption disappearing layer is preferably 50% by mass or more and less than 100% by mass, more preferably 60% by mass or more and less than 100% by mass, and still more preferably 70% by mass or more and less than 100% by mass. The upper limit value thereof is also preferably 99% by mass or less, more preferably 97% by mass or less, still more preferably 95% by mass or less, and particularly preferably 90% by mass or less.

One type of the compound A may be used alone, or two or more types thereof may be used in combination.

### (Carboxy Group-Containing Monomer)

Examples of the carboxy group-containing monomer include a polymerizable compound which contains a carboxy group and contains one or more (for example, 1 to 15) ethylenically unsaturated groups.

Examples of the ethylenically unsaturated group include a (meth)acryloyl group, a vinyl group, and a styryl group, and a (meth)acryloyl group is preferable.

It is noted that in a case where the ethylenically unsaturated group is a (meth)acryloyl group, a carbonyl bond in the (meth)acryloyl group and a carbonyl bond in the carboxy group may share one carbonyl bond.

From the viewpoint of more excellent film-forming properties, the carboxy group-containing monomer is preferably a bi- or higher functional monomer containing a carboxy group. The bi- or higher functional monomer means a polymerizable compound having 2 or more (for example, 2 to 15) ethylenically unsaturated groups in one molecule.

It suffices that the number of carboxy groups contained in the carboxy group-containing monomer is 1 or more, and the number thereof is, for example, preferably 1 to 8, more preferably 1 to 4, and still more preferably 1 or 2.

The carboxy group-containing monomer may further have, as an acid group, an acid group other than the carboxy group. Examples of the acid group other than the carboxy group include a phenolic hydroxyl group, a phosphate group, and a sulfonic acid group.

The bi- or higher functional monomer containing a carboxy group is not particularly limited and can be appropriately selected from known compounds.

Examples of the bi- or higher functional monomer containing a carboxy group include, as product names, ARONIX M-520 and ARONIX M-510 (both manufactured by Toagosei Co., Ltd.).

In addition, examples of the tri- or higher functional monomer containing a carboxy group include a tri- or tetra-functional polymerizable compound having a carboxy group (a compound obtained by introducing a carboxy group into a pentaerythritol triacrylate and pentaerythritol tetraacrylate [PETA] skeleton (acid value=80 to 120 mgKOH/g)) and a penta- or hexa-functional polymerizable compound having a carboxy group (a compound obtained by introducing a carboxy group into a dipentaerythritol pentaacrylate and dipentaerythritol hexaacrylate [DPHA] skeleton (acid value=25 to 70 mgKOH/g)). In a case where the above-described tri- or higher functional monomer containing a carboxy group is used, from the viewpoint of more excellent film-forming properties, it is also preferable to use the bi- or higher functional monomer containing a carboxy group in combination.

Examples of the bi- or higher functional monomer containing a carboxy group and the bi- or higher functional monomer containing an acid group also include the polymerizable compounds having an acid group, which are described in paragraphs 0025 to 0030 of JP2004-239942A. The contents of this patent publication are incorporated in the present specification by reference.

### (Carboxy Group-Containing Polymer)

The carboxy group-containing polymer may further have, as an acid group, an acid group other than the carboxy group. Examples of the acid group other than the carboxy group include a phenolic hydroxyl group, a phosphate group, and a sulfonic acid group.

In a case where the carboxy group-containing polymer is a copolymer, the structure of the polymer may be a random polymer or a regular polymer such as a block.

### <<Constitutional Unit Having Carboxy Group>>

The carboxy group-containing polymer preferably has a constitutional unit having a carboxy group.

Examples of the constitutional unit having a carboxy group include a constitutional unit derived from (meth)acrylic acid, crotonic acid, itaconic acid, maleic acid, or fumaric acid. Among the above, a constitutional unit derived from (meth)acrylic acid is preferable from the viewpoint of high decolorizing properties of the dye.

In the carboxy group-containing polymer, the content of the constitutional unit having a carboxy group is preferably 1% to 100% by mole, more preferably 3% to 65% by mole, still more preferably 5% to 60% by mole, particularly preferably 10% to 60% by mole, and among these, it is preferably 20% to 55% by mole in a case where the total of all the constitutional units of the carboxy group-containing polymer is set to 100% by mole.

One kind of the constitutional unit having a carboxy group may be used alone, or two or more kinds thereof may be used in combination.

### <<Constitutional Unit Having Aromatic Ring>>

It is also preferable that the carboxy group-containing polymer has a constitutional unit having an aromatic ring (preferably, an aromatic hydrocarbon ring), in addition to the above-described constitutional unit. Examples thereof include a constitutional unit derived from a (meth)acrylate having an aromatic ring (specifically, benzyl (meth)acrylate, phenethyl (meth)acrylate, phenoxyethyl (meth)acrylate, or the like).

In the carboxy group-containing polymer, the content of the constitutional unit having an aromatic ring is preferably 0% to 97% by mole, more preferably 0% to 95% by mole, and still more preferably 0% to 90% by mole in a case where the total of all the constitutional units of the carboxy group-containing polymer is set to 100% by mole.

One kind of the constitutional unit having an aromatic ring may be used alone, or two or more kinds thereof may be used in combination.

### <<Constitutional Unit Having Alicyclic Structure>>

It is also preferable that the carboxy group-containing polymer has a constitutional unit having an alicyclic structure in addition to the above-described constitutional unit.

Examples of the alicyclic structure include, for example, a tricyclo[5.2.1.0^{2,6}]decane ring structure (also referred to as tetrahydrodicyclopentadiene; the monovalent group is dicyclopentanyl), a tricyclo[5.2.1.0^{2,6}]decane-3-ene ring structure (also referred to as 5,6-dihydrodicyclopentadiene; the monovalent group is dicyclopentenyl), an isobornane ring structure (the monovalent group is isobornyl), an adamantane ring structure (the monovalent group is adamantyl), and a cyclohexane ring structure (the monovalent group is cyclohexyl).

Examples of the constitutional unit having an alicyclic structure include a constitutional unit derived from a (meth)acrylate having an alicyclic structure (specifically, dicyclopentanyl (meth)acrylate, dicyclopentenyl (meth)acrylate, isobornyl (meth)acrylate, adamantyl (meth)acrylate, methyladamantyl (meth)acrylate, cyclohexyl (meth)acrylate, or the like).

In the carboxy group-containing polymer, a content of the constitutional unit having an alicyclic structure is preferably 0% to 97% by mole, more preferably 0% to 95% by mole, and still more preferably 0% to 90% by mole in a case where the total of all constitutional units of the carboxy group-containing polymer is set to 100% by mole.

One kind of the constitutional unit having an alicyclic structure may be used alone, or two or more kinds thereof may be used in combination.

### <<Other Constitutional Units>>

The carboxy group-containing polymer may have other constitutional units in addition to the above-described constitutional units.

Examples of the other constitutional unit include a constitutional unit derived from methyl (meth)acrylate.

In the carboxy group-containing polymer, the content of the other constitutional unit is preferably 0% to 70% by mole, more preferably 0% to 50% by mole, and still more preferably 0% to 20% by mole in a case where the total of all the constitutional units of the carboxy group-containing polymer is set to 100% by mole.

One kind of the other constitutional units may be used alone, or two or more kinds thereof may be used in combination.

### (2) Compound B

It is preferable that the light absorption disappearing layer contains, as the radical generator, the above-described compound A and a compound B (also simply referred to as “compound B” in the present invention) having a structure capable of forming a hydrogen bond with the above-described acid group in the compound A.

The compound B is preferably a compound having such a structure that absorbs ultraviolet rays to be in an excited state, thereby having an increased basicity. In a case where the basicity of the compound B is increased in the excited state, it is possible to form a complex in which the acid group contained in the compound A interacts more strongly with the compound B, and it is possible to increase the efficiency of generating radicals.

A structure contained in the compound B, the structure that is capable of forming a hydrogen bond with the acid group contained in the compound A, may be a whole structure of the compound B or may be a partial structure that constitutes a part of the compound B.

The compound B may be a high-molecular-weight compound (which means a compound having a molecular weight of 5,000 or more) or a low-molecular-weight compound (which means a compound having a molecular weight of less than 5,000), and it is preferably a low-molecular-weight compound.

The molecular weight of the compound B as a low-molecular-weight compound is less than 5,000, and it is preferably less than 1,000, more preferably 500 or less, and still more preferably 350 or less. The lower limit value thereof is not particularly limited; however, it is preferably 65 or more and more preferably 75 or more. The preferred range of the molecular weight of the compound B, which is a low-molecular-weight compound, is, for example, 65 or more and less than 5,000, preferably 65 or more and less than 1,000, more preferably 65 to 500, and still more preferably 75 to 350.

From the viewpoint that the molar absorption coefficient with respect to ultraviolet rays is large, the compound B is preferably an aromatic compound.

Here, the aromatic compound is a compound having one or more aromatic rings.

Only one aromatic ring may be present in the compound B, or a plurality of aromatic rings may be present therein. In a case where a plurality of aromatic rings is present, the aromatic rings may be present, for example, in the side chain or the like of the polymer that constitutes the resin.

The aromatic ring may be any of an aromatic hydrocarbon ring or an aromatic heterocyclic ring. In a case of being an aromatic heterocyclic ring (also referred to as a heteroaromatic ring), it is a compound having one or more (for example, 1 to 4) heteroatoms (at least one among nitrogen atoms, oxygen atoms, sulfur atoms, and the like) as a ring member atom (ring-constituting atom) and preferably has one or more (for example, 1 to 4) nitrogen atoms as a ring member atom.

It is noted that since the unsubstituted aromatic hydrocarbon does not have a structure that is capable of forming a hydrogen bond with the acid group contained in the compound A, the unsubstituted aromatic hydrocarbon does not have a function of generating a radical upon ultraviolet irradiation and does not correspond to the compound B. In addition, since an unsubstituted aromatic hydrocarbon ring in a form in which the unsubstituted aromatic hydrocarbon ring is bonded to the side chain of the polymer that constitutes the resin does not have a structure that is capable of forming a hydrogen bond with the acid group contained in the compound A, the unsubstituted aromatic hydrocarbon ring does not have a function of generating a radical upon ultraviolet irradiation and does not correspond to the compound B.

The number of ring member atoms in the above-described aromatic ring is preferably 5 to 15.

Examples of the above-described aromatic ring include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a phenanthridine ring, a phenanthroline ring, and a phenazine ring.

The above-described aromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, and a nitro group. In addition, in a case where the above-described aromatic ring has two or more substituents, a plurality of substituents may be bonded to each other to form a non-aromatic ring.

It is noted that in a case where a plurality of aromatic rings (for example, 2 to 5 aromatic rings) forms a series of aromatic ring structures bonded with a structure selected from a single bond, a carbonyl bond, and a multiple bond (for example, a vinylene group which may have a substituent, —C≡C—, —N≡N—, and the like), the entire series of aromatic ring structures is regarded as one specific structure.

A series of aromatic ring structures in which the plurality of aromatic rings are bonded through a structure selected from a single bond, a carbonyl bond, or a multiple bond do not correspond to the above-described unsubstituted aromatic hydrocarbon ring, and do not correspond to the unsubstituted aromatic hydrocarbon ring in a form in which the unsubstituted aromatic hydrocarbon ring is bonded to a side chain of the polymer constituting the resin.

In addition, it is preferable that one or more of the aromatic rings constituting the series of aromatic ring structures are the above-described heteroaromatic rings.

Specific examples of the compound B include monocyclic aromatic compound such as a pyridine compound (pyridine or a pyridine derivative), a pyrazine compound (pyrazine or a pyrazine derivative), a pyrimidine compound (pyrimidine or a pyrimidine derivative), and a triazine compound (triazine or a triazine derivative); compounds in which two rings are fused to form an aromatic ring, such as a quinoline compound (quinoline or a quinoline derivative), an isoquinoline compound (isoquinoline or an isoquinoline derivative), a quinoxaline compound (quinoxaline or a quinoxaline derivative), and a quinazoline compound (quinazoline or a quinazoline derivative); and compounds in which three or more rings are fused to form an aromatic ring, such as an acridine compound (acridine or an acridine derivative), a phenanthridine compound (phenanthridine or a phenanthridine derivative), a phenanthroline compound (phenanthroline or a phenanthroline derivative), and a phenazine compound (phenazine or a phenazine derivative). In the specific examples of the compound B, the compound is used to have a meaning including not only the compound itself but a compound having a substituent (referred to as a “derivative”), including an unsubstituted compound in which a part of the structure has been changed, within a range where the effect of the present invention is not impaired.

It is presumed that this compound B forms a complex with the compound A and generates two molecules of radicals by the following mechanism upon ultraviolet irradiation.
1) The compound B in an excited state is generated by absorbing ultraviolet rays.
2) Positive holes move from the compound B in the excited state to the compound A in the ground state (the electrons of the compound A move to an orbital with lower energy in the two semi occupied molecular orbitals of the compound B in the excited state).
3) The movement of a proton from the compound A to the compound B generates a radical in which a hydrogen radical is loaded on the compound B and a radical in which a hydrogen radical is eliminated from the compound A.

In a case where the compound A is a compound having a carboxy group, the following reaction further occurs, and a radical is generated by a photodecarboxylation reaction.
4) Carbon dioxide is eliminated from the radical in which the hydrogen radical has been eliminated from the compound A.

Among the above, the compound B is preferably one or more among quinoline compounds (quinoline and a quinoline derivative) and isoquinoline compounds (isoquinoline and an isoquinoline derivative).

The substituent which may be contained in these compound is preferably an alkyl group, an aryl group, a halogen atom, an acyl group, an alkoxycarbonyl group, an arylcarbonyl group, a carbamoyl group, a hydroxy group, a cyano group, or a nitro group.

In a case where the compound B is a polymer, the compound B may be a polymer in which the above-described specific structure is bonded to a polymer main chain through a single bond or a linking group.

The compound B which is a polymer is obtained, for example, by polymerizing a monomer having a heteroaromatic ring (specifically, a (meth)acrylate monomer having a vinyl group and/or a heteroaromatic ring). As necessary, copolymerization with another monomer may be carried out.

Specific examples of the compound B include quinoline, 2-methylquinoline, 4-methylquinoline, 2,4-dimethylquinoline, 2-methyl-4-phenylquinoline, isoquinoline, 1-methylisoquinoline, 3-methylisoquinoline, and 1-phenylisoquinoline.

From the viewpoint of achieving both the decolorizing properties of the ultraviolet irradiated portion and the durability of the dye in the ultraviolet non-irradiated portion, the content of the compound B is preferably 0.1% to 50% by mass, more preferably 2.0% to 40% by mass, still more preferably 4% to 35% by mass, and particularly preferably 8% to 30% by mass, with respect to the total mass of the light absorption disappearing layer.

In addition, from the viewpoint of achieving both the decolorizing properties of the ultraviolet irradiated portion and the durability of the dye in the ultraviolet non-irradiated portion, pKaH (pKa of a conjugate acid) which is a measure of the basicity of the compound B is preferably 2.0 to 7.0, more preferably 3.0 to 6.0, and still more preferably 4.3 to 5.5.

In the present invention, pKa means a negative common logarithm (−log Ka) of an acid dissociation constant (Ka) in a mixed solvent of water/methanol=50/50 (volume ratio) at 25° C. The pKa can be calculated by adding dropwise a 0.01 mol/L sodium hydroxide aqueous solution to a mixed solution of water/methanol=50/50 (volume ratio) of a sample for measurement (conjugate acid of the compound B) and reading the amount of the sodium hydroxide aqueous solution added dropwise to the half-equivalent point.

One kind of the compound B may be used alone, or two or more kinds thereof may be used in combination.

### <Resin>

The resin contained in the light absorption disappearing layer is not particularly limited as long as the resin can disperse (preferably dissolve) the above-described dye, can exhibit a decolorizing action of the dye by a radical generated from a compound (preferably, a radical generator including the compound B that is hydrogen-bonded to the acid group contained in the compound A) which generates a radical upon ultraviolet irradiation, and has desired light transmittance (preferably, a light transmittance of 80% or more in a visible region in a wavelength range of 400 to 800 nm).

As a polymer that constitutes the above-described resin, various polymers can be used. However, from the viewpoint that the molecular weight of the resin is not easily reduced upon ultraviolet irradiation, a polymer having an aromatic ring or an alicyclic structure in the side chain is preferable, and a (meth)acrylic polymer containing a constitutional unit having an aromatic ring or an alicyclic structure is more preferable. Among the above, from the viewpoint of further improving the decolorization rate and further improving the heat resistance and the light resistance as well, a (meth)acrylic polymer containing a constitutional unit having an alicyclic structure is still more preferable.

Here, the (meth)acrylic polymer refers to a polymer containing at least one of a constitutional unit derived from (meth)acrylic acid or a constitutional unit derived from (meth)acrylic acid ester. In a case where the polymer includes a constitutional unit derived from (meth)acrylic acid, the constitutional unit derived from (meth)acrylic acid is a constitutional unit having a carboxy group as the acid group in the above-described compound A, and the polymer including a constitutional unit derived from (meth)acrylic acid corresponds to the above-described polymer in which the above-described compound Ais chemically bonded to the polymer constituting the resin.

In addition, in the present invention, the “main chain” represents a relatively longest bonding chain in a molecule of a high-molecular-weight compound, and the “side chain” represents an atomic group branched from the main chain.

Examples of the monomer from which a constitutional unit having an aromatic ring is derived include benzyl acrylate, benzyl methacrylate, naphthyl acrylate, naphthyl methacrylate, naphthyl methyl acrylate, and naphthyl methyl methacrylate. In a case where the polymer does not contain a constitutional unit derived from (meth)acrylic acid, the content of the constitutional unit having an aromatic ring is preferably 5% to 100% by mass, more preferably 10% to 100% by mass, and still more preferably 20% to 100% by mass, with respect to the total mass of the polymer.

Examples of the monomer from which a constitutional unit having an alicyclic structure is derived include dicyclopentanyl (meth)acrylate, cyclohexyl (meth)acrylate, isobornyl (meth)acrylate, and adamantyl (meth)acrylate.

In a case where the polymer contains a constitutional unit having an alicyclic structure, the content of the constitutional unit having an alicyclic structure is preferably 1% to 90% by mass, more preferably 5% to 90% by mass, and still more preferably 5% to 80% by mass, with respect to the total mass of the polymer.

In addition, in the above-described light absorption disappearing layer, the polymer constituting the resin may include a constitutional unit in which the compound A having an acid group is bonded. As the constitutional unit in which the compound A having an acid group is bonded, the above-described description regarding the constitutional unit having a carboxy group in the above-described compound A can be applied, and a constitutional unit derived from (meth)acrylic acid is preferable. The content of the constitutional unit in which the compound A having an acid group is bonded (preferably, a constitutional unit derived from (meth)acrylic acid) is preferably 1% to 70% by mass and more preferably 1% to 60% by mass with respect to the total mass of the polymer. More preferably, the description of the content of the constitutional unit having the carboxy group of the carboxy group-containing polymer regarding the compound A is applied.

In a case where the polymer that constitutes the resin contains a constitutional unit bonded to the compound A having an acid group, the descriptions regarding the content of the constitutional unit having the carboxy group of the carboxy group-containing polymer as the compound A and the content of the constitutional unit having an aromatic ring and the content of the constitutional unit having an alicyclic structure are applied to the content of the constitutional unit bonded to the compound A having an acid group, the content of the constitutional unit having an aromatic ring, and the content of the constitutional unit having an alicyclic structure.

From the viewpoint of adjusting the glass transition temperature and the like, the polymer that constitutes the resin may contain a constitutional unit that has an alkyl group having 1 to 14 carbon atoms. Examples of the constitutional unit having an alkyl group having 1 to 14 carbon atoms include a constitutional unit derived from an alkyl (meth)acrylate, such as methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethylbutyl (meth)acrylate, n-octyl (meth)acrylate, isooctyl (meth)acrylate, isononyl (meth)acrylate, lauryl (meth)acrylate, or tetradecyl (meth)acrylate. In the present invention, one kind of the constitutional unit having an alkyl group having 1 to 14 carbon atoms may be used alone, or two or more kinds thereof may be used in combination. The content of the constitutional unit having an alkyl group having 1 to 14 carbon atoms is preferably such that an amount of 0% by mass to 95% by mass is contained with respect to the total mass of the polymer that constitutes the resin.

The weight-average molecular weight (Mw) of the polymer that constitutes the resin is preferably 10,000 or more, more preferably 10,000 to 200,000, and still more preferably 15,000 to 150,000.

Next, the wavelength-selective absorption layer constituting the light absorption filter according to the embodiment of the present invention will be described in detail.

### <<Wavelength Selective Absorption Layer>>

The wavelength-selective absorption layer constituting the light absorption filter according to the embodiment of the present invention contains a resin and a dye having a main absorption wavelength band in a wavelength range of 400 to 700 nm, and does not contain a compound that generates a radical upon ultraviolet irradiation.

In the wavelength-selective absorption layer, the “dye” is dispersed (preferably dissolved) in the resin to make the wavelength-selective absorption layer a layer exhibiting a specific absorption spectrum derived from the dye.

### <Dye>

The “dye” contained in the wavelength-selective absorption layer preferably includes at least one of the following dyes A to D having a main absorption wavelength band in different wavelength ranges.
Dye A: a dye having a main absorption wavelength band in a wavelength range of 390 to 435 nm
Dye B: a dye having a main absorption wavelength band in a wavelength range of 480 to 520 nm
Dye C: a dye having a main absorption wavelength band in a wavelength range of 560 to 610 nm
Dye D: a dye having a main absorption wavelength band in a wavelength range of 640 to 780 nm

The dye A that can be contained in the wavelength-selective absorption layer may be one kind or two or more kinds. The above-described dyes B to D that can be contained in the wavelength-selective absorption layer may be each independently one kind or two or more kinds, similarly to the dye A.

The wavelength-selective absorption layer can also contain a dye other than the dyes A to D.

The form of the wavelength-selective absorption layer may be any form as long as the dye in the wavelength-selective absorption layer exhibits an absorption spectrum and the combination with the above-described light absorption disappearing layer can achieve both the suppression of external light reflection and the suppression of brightness reduction in the obtained optical filter, and it is preferable that the form of the wavelength-selective absorption layer further has a tint that is not easily affected by the original color of the display image. Examples of one aspect of the wavelength-selective absorption layer include an aspect in which a dye (preferably, at least one of the dyes A to D) is dispersed (preferably, dissolved) in a resin. The dispersion may be any type of dispersion, such as a random type or a regular type.

The dyes A to D have main absorption wavelength bands in 390 to 435 nm, 480 to 520 nm, 560 to 610 nm, and 640 to 780 nm, which are wavelength ranges that do not substantially overlap with B (Blue, 460 nm), G (Green, 520 nm), and R (Red, 620 nm) used as a light-emitting light source of the OLED display device, in the wavelength-selective absorption layer. Therefore, by containing at least one of the dyes A to D, the wavelength-selective absorption layer can suppress the reflection of external light on the display portion of the display device without impairing the color reproduction range of the light emitted from the OLED.

Even in a case where the optical filter according to the embodiment of the present invention, which is obtained using the light absorption filter according to the embodiment of the present invention, is applied to an inorganic EL display device or a liquid crystal display device, similarly to the OLED display device, by containing a dye having a main absorption wavelength band in a wavelength range that does not substantially overlap with the light-emitting light source of each display device in the wavelength-selective absorption layer, it is possible to suppress the reflection of external light on the display portion of the display device without impairing the color reproduction range of the light emitted from each display device.

In particular, from the viewpoint of extracting the original tint of the image of the OLED display device, the dye A, the dye B, the dye C, and the dye D contained in the wavelength-selective absorption layer are preferably a combination of at least two kinds, more preferably a combination of at least three kinds, and still more preferably all four kinds, in a case where the wavelength-selective absorption layer exhibits an absorption spectrum having a negative correlation with the emission spectrum of the light-emitting light source.

In a case where two or more kinds of the dyes A to D are contained in the wavelength-selective absorption layer as described above, there is also a problem in that the light resistance may be lowered due to the mixing of the dyes due to chain transfer or the like of radicals generated during the decomposition of the dyes. Even in such a problem, the wavelength-selective absorption layer in the light absorption filter according to the embodiment of the present invention and the optical filter obtained by subjecting the light absorption filter according to the embodiment of the present invention to mask exposure can exhibit excellent light resistance exceeding the decrease in light resistance due to the mixing of the dyes by providing a specific gas barrier layer described later.

Among these, from the viewpoint of further extracting the original tint of the image of the OLED display device, it is preferable that the wavelength-selective absorption layer contains all of the four kinds of dyes A to D described above and satisfies Relational Expressions (I) to (VI). The optical filter according to the embodiment of the present invention, which is obtained from the light absorption filter according to the embodiment of the present invention including the wavelength-selective absorption layer having such a configuration and the light absorption disappearing layer described above, can maintain the original tint of the image of the OLED display device at a more excellent level in addition to satisfying the suppression of the reflection of external light and the suppression of the decrease in brightness.

$$Ab ( 450 ) / Ab ( 430 ) < 1. \qquad Relational Expression ( I )$$

$$Ab ( 450 ) / Ab ( 500 ) < 1. \qquad Relational Expression ( II )$$

$$Ab ( 540 ) / Ab ( 500 ) < 1. \qquad Relational Expression ( III )$$

$$Ab ( 540 ) / Ab ( 600 ) < 1. \qquad Relational Expression ( IV )$$

$$Ab ( 630 ) / Ab ( 600 ) \leq 0.5 \qquad Relational Expression ( V )$$

$$Ab ( 630 ) / Ab ( 700 ) < 1. \qquad Relational Expression ( VI )$$

In the ranges defined by Relational Expressions (I) to (VI), the preferred ranges are as follows.

The upper limit value of Ab(450)/Ab(430) in Relational Expression (I) is preferably 0.90 or less, more preferably 0.85 or less, still more preferably 0.80 or less, and particularly preferably 0.60 or less. The lower limit value thereof is not particularly limited, but is practically 0.05 or more, preferably 0.10 or more, and more preferably 0.20 or more.

The upper limit value of Ab(450)/Ab(500) in Relational Expression (II) is preferably 0.90 or less, more preferably 0.80 or less, still more preferably 0.75 or less, and particularly preferably 0.65 or less, among which, preferably 0.60 or less and most preferably 0.50 or less.

The lower limit value thereof is not particularly limited, but is practically 0.05 or more, preferably 0.10 or more, and more preferably 0.20 or more.

The upper limit value of Ab(540)/Ab(500) in Relational Expression (III) is preferably 0.90 or less, more preferably 0.80 or less, still more preferably 0.75 or less, and particularly preferably 0.70 or less, among which, preferably 0.50 or less and most preferably 0.20 or less. The lower limit value thereof is not particularly limited, but is practically 0.01 or more, preferably 0.02 or more, and more preferably 0.05 or more.

The upper limit value of Ab(540)/Ab(600) in Relational Expression (IV) is preferably 0.90 or less, more preferably 0.85 or less, still more preferably 0.80 or less, and particularly preferably 0.70 or less, among which, preferably 0.50 or less and most preferably 0.25 or less. The lower limit value thereof is not particularly limited, but is practically 0.01 or more, preferably 0.02 or more, and more preferably 0.05 or more.

The upper limit value of Ab(630)/Ab(600) in Relational Expression (V) is preferably 0.40 or less, more preferably 0.30 or less, still more preferably 0.20 or less, and particularly preferably 0.15 or less. The lower limit value thereof is not particularly limited, but is practically 0.01 or more, preferably 0.02 or more, and more preferably 0.05 or more.

The upper limit value of Ab(630)/Ab(700) in Relational Expression (VI) is preferably 0.95 or less, more preferably 0.90 or less, still more preferably 0.80 or less, and particularly preferably 0.75 or less. The lower limit value thereof is not particularly limited, but is practically 0.01 or more, preferably 0.03 or more, more preferably 0.10 or more, still more preferably 0.40 or more, and particularly preferably 0.50 or more.

In a case where Relational Expressions (I) to (VI) satisfy the above-described preferable ranges, a change in tint due to the provision of the optical filter according to the embodiment of the present invention can be reduced, and the original tint of the image of the OLED display device can be further brought out. Therefore, it is preferable that the absorption waveforms of the dyes A to D in the main absorption wavelength band are sharp.

For example, in a case where the dye B is a squaraine coloring agent represented by General Formula (1) described later, the above-described wavelength-selective absorption layer can satisfy Relational Expressions (II) and (III) within the above-described preferable ranges, and the original tint of the image of the OLED display device can be maintained at a more excellent level. This is considered to be because the absorbance of the green photoreceptor of the human cone at a wavelength near the absorption maximum (534 nm) is low.

In addition, in a case where the dye C is a squaraine coloring agent represented by General Formula (1) described later, the above-described wavelength-selective absorption layer can satisfy Relational Expressions (I) to (IV) within the above-described preferable ranges, and the original tint of the image of the OLED display device can be maintained at a more excellent level. This is also considered to be because the absorbance of the green photoreceptor of the human cone at a wavelength near the absorption maximum (534 nm) is low, as described above.

In particular, it is important to satisfy Relational Expression (V) from the viewpoint of not affecting the original tint of the image of the OLED display device. It is considered that, according to Relational Expression (V), a change in a* can be suppressed, and as a result, the above-described tint can be maintained at an excellent level.

### (Dye A)

The dye A is not particularly limited as long as it has a main absorption wavelength band in a wavelength range of 390 to 435 nm in the light absorption filter according to the embodiment of the present invention, and various dyes can be used.

A wavelength range of the dye A having a main absorption wavelength band is preferably 395 to 435 nm, more preferably 400 to 435 nm, and still more preferably 405 to 435 nm.

As the dye A, a coloring agent represented by General Formula (A1) is preferable in that an absorption waveform in the main absorption wavelength band is sharp.

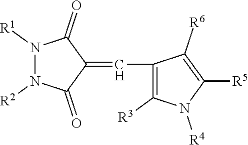

In Formula (A1), R¹ and R² each independently represent an alkyl group or an aryl group, R³ to R⁶ each independently represent a hydrogen atom or a substituent, and R⁵ and R⁶ may be bonded to each other to form a 6-membered ring.

With regard to definition and a preferred range of each substituent in General Formula (A1), each of descriptions related to each substituent of coloring agents represented by General Formula (A1) described in paragraphs 0022 to 0056 of WO2022/138925A can be applied unless otherwise specified. For example, as described in paragraph 0056 of WO2022/138925A, from the viewpoint of light resistance, it is preferable that R¹ in R¹ and R² in General Formula (A1) is an alkyl group, and it is more preferable that R¹ is an alkyl group and R² is an alkyl group or an aryl group. In addition, from the same viewpoint, it is still more preferable that both R¹ and R² are each independently an alkyl group, and it is particularly preferable that both R¹ and R² are an alkyl group having 1 to 8 carbon atoms.

Further, in terms of heat resistance and light resistance, it is also preferable that both R¹ and R² in General Formula (A1) are an aryl group.

In a case where R¹ and R² each independently represent an aryl group, it is preferable that R³, R⁵, and R⁶ are each independently a hydrogen atom, an alkyl group, or an aryl group and that at least one of R³ or R⁶ is preferably a hydrogen atom. Among the above, from the viewpoint of heat resistance and light resistance, a case where R³ represents a hydrogen atom, and R⁵ and R⁶ each independently represent an alkyl group or an aryl group is more preferable. A case where R³ represents a hydrogen atom and R⁵ and R⁶ each independently represent an alkyl group is still more preferable. A case where R³ represents a hydrogen atom, R⁵ and R⁶ each independently represent an alkyl group, and R⁵ and R⁶ are bonded to each other to form a ring and fused with a pyrrole ring to form an indole ring together with the pyrrole ring is particularly preferable. That is, the coloring agent represented by General Formula (A1) is particularly preferably a coloring agent represented by General Formula (A2).

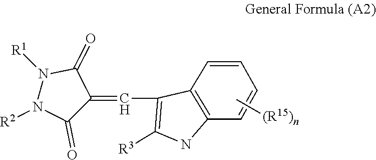

In Formula (A2), R¹ to R⁴ each have the same meanings as R¹ to R⁴ in General Formula (A1), and preferable embodiments are also the same.

In Formula (A2), R¹⁵ represents a substituent. Examples of the substituent that can be employed as R¹⁵ can include substituents included in a substituent group A described in the description of the coloring agent represented by General Formula (A1) described in the WO2022/138925A. R¹⁵ is preferably an alkyl group, an aryl group, a halogen atom, an acyl group, or an alkoxycarbonyl group.

The alkyl group and the aryl group that can be employed as R¹⁵ respectively have the same meanings as the alkyl group and the aryl group that can be employed as R³, R⁵, and R⁶, respectively, and the same applies to each of the preferred aspects thereof.

Examples of the halogen atom that can be employed as R¹⁵ include a chlorine atom, a bromine atom, and an iodine atom.

Examples of the acyl group that can be adopted as R¹⁵ include an acetyl group, a propionyl group, and a butyroyl group.

For the amino group that can be employed as R¹⁵, the description regarding the amino group that can be contained in the substituted aryl group as R⁴ can be applied. Further, a nitrogen-containing heterocyclic group having a 5-membered to 7-membered ring in which an alkyl group on the nitrogen atom of the amino group is bonded to form a ring is also preferable.

As the alkoxycarbonyl group that can be employed as R⁵, an alkoxycarbonyl group having 2 to 5 carbon atoms is preferable, and examples thereof include methoxycarbonyl, ethoxycarbonyl, normal propoxycarbonyl, and isopropoxycarbonyl.

n is an integer of 0 to 4. n is not particularly limited, but for example, 0 or 1 is preferable.

Specific examples of the coloring agent represented by General Formula (A1) include the compounds described in 0063 to 0065 of WO2022/138925A and the following compound (E-42). However, the present invention is not limited thereto.

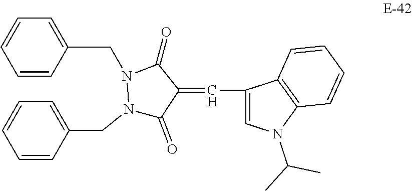

As the dye A, in addition to the coloring agent represented by General Formula (A1), the compounds described in paragraphs 0012 to 0067 of JP1993-53241A (JP-H5-53241A) and the compounds described in paragraphs 0011 to 0076 of JP2707371B can also be preferably used.

### (Dye B and Dye C)

The dye B is not particularly limited as long as it has a main absorption wavelength band in a wavelength range of 480 to 520 nm in the light absorption filter according to the embodiment of the present invention, and various dyes can be used.

In addition, the dye C is not particularly limited as long as it has a main absorption wavelength band in a wavelength range of 560 to 610 nm in the light absorption filter according to the embodiment of the present invention, and various dyes can be used.

A wavelength range of the dye B having a main absorption wavelength band is preferably 485 to 520 nm, more preferably 490 to 520 nm, and still more preferably 490 to 515 nm.

A wavelength range of the dye C having a main absorption wavelength band is preferably 580 to 615 nm, more preferably 580 to 610 nm, and still more preferably 580 to 610 nm.

Specific examples of the dye B include coloring agents (dyes) of pyrrole methine (PM), rhodamine (RH), boron dipyrromethene (BODIPY), and squaraine (SQ).

Specific examples of the dye C include coloring agents (dyes) of tetraazaporphyrin (TAP), squaraine, and cyanine (CY).

Among these, as the dye B and the dye C, squaraine-based coloring agents are preferable, and squaraine-based coloring agents represented by General Formula (1) are more preferable in that an absorption waveform in the main absorption wavelength band is sharp. By using the coloring agent having a sharp absorption waveform as described above as the dye B and the dye C, Relational Expressions (I) and (II) can be satisfied at a preferable level, and the original tint of the image of the OLED display device can be maintained at a more excellent level.

That is, from the viewpoint of suppressing the change in tint, in the wavelength-selective absorption layer, it is preferable that at least one of the dye B or the dye C is a squaraine coloring agent (preferably, a squaraine coloring agent represented by General Formula (1)), and it is more preferable that both the dye B and the dye C are squaraine coloring agents (preferably, squaraine coloring agents represented by General Formula (1)).

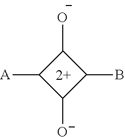

In Formula (1), A and B each independently represent an aryl group which may have a substituent, a heterocyclic group which may have a substituent, or —CH=G. G represents a heterocyclic group which may have a substituent.

Regarding the definition and the preferable range of each substituent in General Formula (1), unless otherwise specified, the description regarding each substituent of the coloring agent represented by General Formula (1) described in paragraphs 0073 to 0095, 0099, and 0100 of WO2021/221122A can be applied as it is.

Examples of a preferred embodiment of the coloring agent represented by General Formula (1) include a coloring agent represented by General Formula (2).

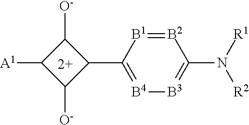

In Formula (2), A¹ is the same as Ain Formula (1). Among these, a heterocyclic group which is a nitrogen-containing five-membered ring is preferable.

In General Formula (2), R¹ and R² each independently represent a hydrogen atom or a substituent. R¹ and R² may be the same as or different from each other, and may be bonded together to form a ring.

The substituent that can be adopted as R¹ and R² is not particularly limited, and examples thereof include an alkyl group (a methyl group, an ethyl group, a propyl group, an isopropyl group, a butyl group, a t-butyl group, an isobutyl group, a pentyl group, a hexyl group, an octyl group, a dodecyl group, a trifluoromethyl group, or the like), a cycloalkyl group (a cyclopentyl group, a cyclohexyl group, or the like), an alkenyl group (a vinyl group, an allyl group, or the like), an alkynyl group (an ethynyl group, a propargyl group, or the like), an aryl group (a phenyl group, a naphthyl group, or the like), a heteroaryl group (a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, a phthalazyl group, or the like), a heterocyclic group (also referred to as a heterocyclic group, for example, a pyrrolidyl group, an imidazolidyl group, a morpholyl group, an oxazolidyl group, or the like), an alkoxy group (a methoxy group, an ethoxy group, a propyloxy group, or the like), a cycloalkoxy group (a cyclopentyloxy group, a cyclohexyloxy group, or the like), an aryloxy group (a phenoxy group, a naphthyloxy group, or the like), a heteroaryloxy group (an aromatic heterocyclic oxy group), an alkylthio group (a methylthio group, an ethylthio group, a propylthio group, or the like), a cycloalkylthio group (a cyclopentylthio group, a cyclohexylthio group, or the like), an arylthio group (a phenylthio group, a naphthylthio group, or the like), a heteroarylthio group (an aromatic heterocyclic thio group), an alkoxycarbonyl group (a methyloxycarbonyl group, an ethyloxycarbonyl group, a butyloxycarbonyl group, an octyloxycarbonyl group, or the like), an aryloxycarbonyl group (a phenyloxycarbonyl group, a naphthyloxycarbonyl group, or the like), a phosphoryl group (dimethoxyphosphonyl or diphenylphosphoryl), a sulfamoyl group (an aminosulfonyl group, a methylaminosulfonyl group, a dimethylaminosulfonyl group, a butylaminosulfonyl group, a cyclohexylaminosulfonyl group, an octylaminosulfonyl group, a phenylaminosulfonyl group, a 2-pyridylaminosulfonyl group, or the like), an acyl group (an acetyl group, an ethylcarbonyl group, a propylcarbonyl group, a cyclohexylcarbonyl group, an octylcarbonyl group, a 2-ethylhexylcarbonyl group, a phenylcarbonyl group, a naphthylcarbonyl group, a pyridylcarbonyl group, or the like), an acyloxy group (an acetyloxy group, an ethylcarbonyloxy group, a butylcarbonyloxy group, an octylcarbonyloxy group, a phenylcarbonyloxy group, or the like), an amide group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, or the like), a sulfonylamide group (a methylsulfonylamino group, an octylsulfonylamino group, a 2-ethylhexylsulfonylamino group, a trifluoromethylsulfonylamino group, or the like), a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, or the like), a ureide group (a methylureide group, an ethylureide group, a pentylureide group, a cyclohexylureide group, an octylureide group, a dodecylureide group, a phenylureide group, a naphthylureide group, a 2-pyridylaminoureide group, or the like), an alkylsulfonyl group (a methylsulfonyl group, an ethylsulfonyl group, a butylsulfonyl group, a cyclohexylsulfonyl group, a 2-ethylhexylsulfonyl group, or the like), an arylsulfonyl group (a phenylsulfonyl group, a naphthylsulfonyl group, a 2-pyridylsulfonyl group, or the like), an amino group (an amino group, an ethylamino group, a dimethylamino group, a butylamino group, a dibutylamino group, a cyclopentylamino group, a 2-ethylhexylamino group, a dodecylamino group, an anilino group, a naphthylamino group, a 2-pyridylamino group, or the like), an alkylsulfonyloxy group (methanesulfonyloxy), a cyano group, a nitro group, halogen atoms (a fluorine atom, a chlorine atom, a bromine atom, or the like), and a hydroxy group.

Among these, an alkyl group, an alkenyl group, an aryl group, or a heteroaryl group is preferable, an alkyl group, an aryl group, or a heteroaryl group is more preferable, and an alkyl group is still more preferable.

The substituent that can be adopted as R¹ and R² may further have a substituent. Examples of the substituent which may be further contained therein include the above-described substituents that can be adopted as R¹ and R², and the substituent X which may be contained in A, B, and G in General Formula (1) (the substituent X described in paragraphs 0079 to 0095 of WO2021/221122A). In addition, R¹ and R² may be bonded to each other to form a ring, and R¹ or R² and the substituent contained in B² or B³ may be bonded to each other to form a ring.

As the ring that is formed at this time, a heterocycle or a heteroaryl ring is preferable, and the size of the ring being formed is not particularly limited, but a 5-membered ring or a 6-membered ring is preferable. Further, the number of rings to be formed is not particularly limited, and it may be one or two or more. Examples of the form in which two or more rings are formed include a form in which the substituents of R¹ and B² and the substituents contained in R² and B³ are respectively bonded to each other to form two rings.

In General Formula (2), B¹, B², B³, and B⁴ each independently represent a carbon atom or a nitrogen atom. The ring including B¹, B², B³, and B⁴ is an aromatic ring. It is preferable that at least two or more of B¹ to B⁴ are a carbon atom, and it is more preferable that all of B¹ to B⁴ are a carbon atom.

The carbon atom that can be adopted as B¹ to B⁴ has a hydrogen atom or a substituent. Among carbon atoms that can be employed as B¹ to B⁴, the number of carbon atoms having a substituent is not particularly limited; however, it is preferably zero, one, or two, and more preferably one. Particularly, it is preferable that 1 and B⁴ are a carbon atom and at least one of them has a substituent.

The substituent possessed by the carbon atom that can be employed as B¹ to B⁴ is not particularly limited, and examples thereof include the above-described substituents that can be employed as R¹ and R². Among these, it is preferably an alkyl group, an alkoxy group, an alkoxycarbonyl group, an aryl group, an acyl group, an amide group, a sulfonylamide group, a carbamoyl group, an alkylsulfonyl group, an arylsulfonyl group, an amino group, a cyano group, a nitro group, a halogen atom, or a hydroxy group, and it is more preferably an alkyl group, an alkoxy group, an alkoxycarbonyl group, an aryl group, an acyl group, an amide group, a sulfonylamide group, a carbamoyl group, an amino group, a cyano group, a nitro group, a halogen atom, or a hydroxy group.

The substituent possessed by the carbon atom that can be adopted as B¹ to B⁴ may further have a substituent. Examples of the substituent that may be further contained in the substituent include the substituent that may be further contained in R¹ and R² in General Formula (2) described above, and the substituent X that may be contained in A, B, and G in General Formula (1) described above (the substituent X described in paragraphs 0079 to 0095 of WO2021/221122A).

Examples of the substituent that can be possessed by the carbon atom that can be adopted as B¹ and B⁴ still more preferably include an alkyl group, an alkoxy group, a hydroxy group, an amide group, a sulfonylamide group, or a carbamoyl group, and particularly preferably an alkyl group, an alkoxy group, a hydroxy group, an amide group, or a sulfonylamide group, and a hydroxy group, an amide group, or a sulfonylamide group is most preferable.

It is still more preferable that the substituent that can be possessed by the carbon atom that can be employed as B² and B³ is an alkyl group, an alkoxy group, an alkoxycarbonyl group, an acyl group, an amino group, a cyano group, a nitro group, or a halogen atom, and it is particularly preferable that the substituent as any one of B² or B³ is an electron-withdrawing group (for example, an alkoxycarbonyl group, an acyl group, a cyano group, a nitro group, or a halogen atom).

The coloring agent represented by Formula (2) is preferably a coloring agent represented by any of Formulae (3), (4), and (5).

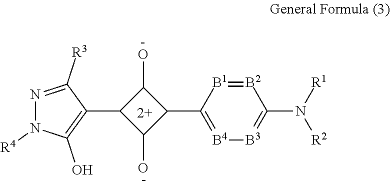

In General Formula (3), R¹ and R² each independently represent a hydrogen atom or a substituent, and they respectively have the same meanings as R¹ and R² in General Formula (2), where the same applies to the preferred ranges thereof.

In General Formula (3), B¹ to B⁴ each independently represent a carbon atom or a nitrogen atom, and they have respectively the same meanings as B¹ to B⁴ in General Formula (2), where the same applies to the preferred ranges thereof.

In General Formula (3), R³ and R⁴ each independently represent a hydrogen atom or a substituent. The substituent that can be employed as R³ and R⁴ is not particularly limited, and the same substituents as the substituents that can be employed as R¹ and R² can be exemplified.

However, as the substituents that can be employed as R³, an alkyl group, an alkoxy group, an amino group, an amide group, a sulfonylamide group, a cyano group, a nitro group, an aryl group, a heteroaryl group, a heterocyclic group, an alkoxycarbonyl group, a carbamoyl group, or a halogen atom is preferable, an alkyl group, an aryl group, or an amino group is more preferable, and an alkyl group is still more preferable.

The substituent which can be adopted as R⁴ is preferably an alkyl group, an aryl group, a heteroaryl group, a heterocyclic group, an alkoxy group, an alkoxycarbonyl group, an acyl group, an acyloxy group, an amide group, a carbamoyl group, an amino group, or a cyano group, more preferably an alkyl group, an alkoxycarbonyl group, an acyl group, a carbamoyl group, or an aryl group, and still more preferably an alkyl group.

The alkyl group that can be employed as R³ and R⁴ may be any of linear, branched, or cyclic and is preferably linear or branched. The alkyl group preferably has 1 to 12 carbon atoms and more preferably 1 to 8 carbon atoms. Examples of the alkyl group preferably include a methyl group, an ethyl group, an n-propyl group, an isopropyl group, a t-butyl group, a 2-ethylhexyl group, or a cyclohexyl group, and more preferably a methyl group or a t-butyl group.

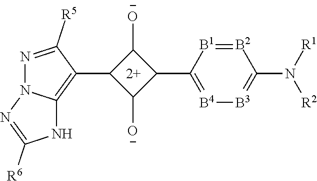

In General Formula (4), R¹ and R² each independently represent a hydrogen atom or a substituent, and have the same meanings as R¹ and R² in General Formula (2), and the preferable ranges are also the same.

In General Formula (4), B¹ to B⁴ each independently represent a carbon atom or a nitrogen atom, and they have respectively the same meanings as B¹ to B⁴ in General Formula (2), where the same applies to the preferred ranges thereof.

In General Formula (4), R⁵ and R⁶ each independently represent a hydrogen atom or a substituent. The substituent that can be adopted as R⁵ and R⁶ is not particularly limited, and examples thereof include the same ones as the substituents that can be adopted as R¹ and R².

However, the substituent that can be employed as R⁵ is preferably an alkyl group, an alkoxy group, an aryloxy group, an amino group, a cyano group, an aryl group, a heteroaryl group, a heterocyclic group, an acyl group, an acyloxy group, an amide group, a sulfonylamide group, a ureide group, or a carbamoyl group, more preferably an alkyl group, an alkoxy group, an acyl group, an amide group, or an amino group, and still more preferably an alkyl group.

The alkyl group that can be adopted as R⁵ has the same meaning as the alkyl group that can be adopted as R³ in General Formula (3), and the same applies to the preferred range thereof.

In General Formula (4), the substituent that can be employed as R⁶ is preferably an alkyl group, an alkenyl group, an aryl group, a heteroaryl group, a heterocyclic group, an alkoxy group, a cycloalkoxy group, an aryloxy group, an alkoxycarbonyl group, an acyl group, an acyloxy group, an amide group, a sulfonylamide group, an alkylsulfonyl group, an arylsulfonyl group, a carbamoyl group, an amino group, a cyano group, a nitro group, or a halogen atom, more preferably an alkyl group, an aryl group, a heteroaryl group, or a heterocyclic group, and still more preferably an alkyl group or an aryl group.

The alkyl group that can be employed as R⁶ has the same meaning as the alkyl group that can be employed as R⁴ in General Formula (3), and the same applies to the preferred range thereof.

The aryl group that can be employed as R⁶ is preferably an aryl group having 6 to 12 carbon atoms, and more preferably a phenyl group. This aryl group may have a substituent, and examples of such a substituent include a group included in the following substituent group B, and an alkyl group, a sulfonyl group, an amino group, an acylamino group, a sulfonylamino group, or the like, which have 1 to 10 carbon atoms, is particularly preferable. These substituents may further have a substituent. Specifically, the substituent is preferably an alkylsulfonylamino group.

### —Substituent Group B—

A halogen atom, an alkyl group, an alkenyl group, an alkynyl group, an aryl group, a heterocyclic group, a cyano group, a hydroxy group, a nitro group, a carboxy group, an alkoxy group, an aminooxy group, an aryloxy group, a silyloxy group, a heterocyclic oxy group, an acyloxy group, a carbamoyloxy group, an amino group, an acylamino group, an aminocarbonylamino group, an alkoxycarbonylamino group, an aryloxycarbonylamino group, a sulfamoylamino group, a sulfonylamino group (including an alkyl or arylsulfonylamino group), a mercapto group, an alkylthio group, an arylthio group, a heterocyclic thio group, a sulfamoyl group, a sulfo group, an alkyl or arylsulfinyl group, a sulfonyl group (including an alkyl or arylsulfonyl group), an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a silyl group, and the like.

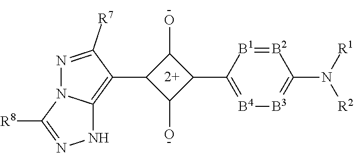

In General Formula (5), R¹ and R² each independently represent a hydrogen atom or a substituent, and have the same meanings as R¹ and R² in General Formula (2), and the preferable ranges are also the same.

In General Formula (5), B¹ to B⁴ each independently represent a carbon atom or a nitrogen atom, and they have respectively the same meanings as B¹ to B⁴ in General Formula (2), where the same applies to the preferred ranges thereof.

In General Formula (5), R⁷ and R⁸ each independently represent a hydrogen atom or a substituent. The substituent that can be adopted as R⁷ and R¹ is not particularly limited, and examples thereof include the same ones as the substituents that can be adopted as R¹ and R².

However, the preferred range, the more preferred range, and the still more preferred range of the substituent that can be adopted as R⁷ are the same as those of the substituent that can be adopted as R⁵ in General Formula (4). The alkyl group that can be employed as R⁵ has the same meaning as the alkyl group that can be employed as R³, and the same applies to the preferred range thereof.

In General Formula (5), a preferable range, a more preferable range, and a still more preferable range of the substituent that can be employed as R⁸ are the same as the substituent that can be employed as R⁶ in General Formula (4). The preferable ranges of the alkyl group and the aryl group that can be employed as R⁸ have the same meaning as the alkyl group and the aryl group that can be employed as R⁶ in General Formula (4), and the preferable ranges are also the same.

As the squaraine-based coloring agent, a squaraine coloring agent represented by any one of General Formulae (1) to (5) can be used without particular limitation. Examples thereof include compounds described in, for example, JP2006-160618A, WO2004/005981A, WO2004/007447A, Dyes and Pigment, 2001, 49, pp. 161 to 179, WO2008/090757A, WO2005/121098A, and JP2008-275726A.

Specific examples of the coloring agent represented by any of General Formulae (1) to (5) include compounds described in paragraphs 0119 to 0122 of WO2021/221122A. However, the present invention is not limited thereto.

In addition, in addition to the above-described specific examples, specific examples of the coloring agent represented by any of General Formulae (3) to (5) include compounds described in paragraphs 0124 to 0132 of WO2021/221122A. However, the present invention is not limited thereto.

As a preferable embodiment of the coloring agent represented by General Formula (1), a coloring agent represented by General Formula (6) is exemplified.

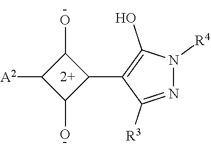

In General Formula (6), R³ and R⁴ each independently represent a hydrogen atom or a substituent and have the same meanings as R³ and R⁴ in General Formula (3), and the preferable ranges are also the same.

In General Formula (6), A² has the same meaning as A in General Formula (1).

Among these, a heterocyclic group which is a nitrogen-containing five-membered ring is preferable.

The coloring agent represented by Formula (6) is preferably a coloring agent represented by any one of General Formulae (7), (8) and (9).

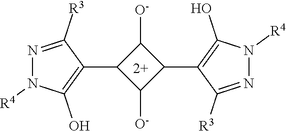

In General Formula (7), R³ and R⁴ each independently represent a hydrogen atom or a substituent, and have the same meanings as R³ and R⁴ in General Formula (3), and the preferable ranges are also the same. Two R³'s and two R⁴'s may be the same as or different from each other.

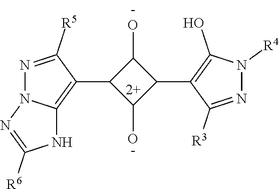

In General Formula (8), R³ and R⁴ each independently represent a hydrogen atom or a substituent, and they respectively have the same meanings as R³ in General Formula (3), where the same applies to the preferred ranges thereof.

In General Formula (8), R⁵ and R⁶ each independently represent a hydrogen atom or a substituent, and have the same meanings as R⁵ and R⁶ in General Formula (4), and the preferable ranges are also the same.

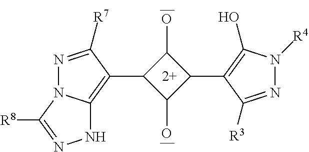

In General Formula (9), R³ and R⁴ each independently represent a hydrogen atom or a substituent, and they respectively have the same meanings as R³ in General Formula (3), where the same applies to the preferred ranges thereof.

In General Formula (9), R⁷ and R⁸ each independently represent a hydrogen atom or a substituent, and they respectively have the same meanings as R⁷ and R⁸ in General Formula (5), where the same applies to the preferred ranges thereof.

In the present invention, in a case where a squaraine coloring agent is used as the dye B, the squaraine coloring agent can be used without particular limitation as long as the squaraine coloring agent is a squaraine coloring agent represented by any of General Formulae (6) to (9). Examples thereof include the compounds described in, for example, JP2002-097383A and JP2015-068945A.

Specific examples of the squaraine coloring agent represented by any of General Formulae (6) to (9) include compounds described in 0145 to 0148 of WO2021/221122A. However, the present invention is not limited thereto.

### (Quencher-Embedded Coloring Agent)

The squaraine-based coloring agent represented by General Formula (1) may be a quencher-embedded coloring agent in which a quencher portion is linked to a coloring agent by a covalent bond via a linking group. The quencher-embedded coloring agent can also be preferably used as the coloring agent of at least one of the dye B or the dye C. That is, the quencher-embedded coloring agent is counted as the dye B or dye C according to the wavelength having the main absorption wavelength band.

Examples of the quencher moiety include a ferrocenyl group in the above-described substituent X (the substituent X described in paragraphs 0079 to 0095 of WO2021/221122A). In addition, the quencher portion in a quencher compound described in paragraphs 0199 to 0212 and paragraphs 0234 to 0310 of WO2019/066043A can be exemplified.

Specific examples of the coloring agent corresponding to the internal quencher-type coloring agent among the squaraine coloring agents represented by General Formula (1) include compounds described in 0151 to 0167 of WO2021/221122A, and the following compounds (C-121) and (C-122). However, the present invention is not limited thereto.

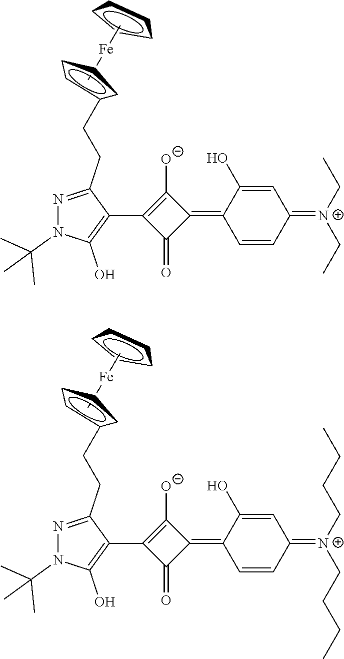

### (Dye D)

The dye D is not particularly limited as long as it has a main absorption wavelength band in a wavelength range of 640 to 780 nm in the light absorption filter according to the embodiment of the present invention, and various dyes can be used.

Specific examples of the dye D include coloring agents (dyes) of porphyrin, squaraine, cyanine (CY), and indoaniline.

Preferred examples of the squaraine coloring agent include a squaraine coloring agent represented by General Formula (1).

### (Coloring Agent Represented by General Formula (1))

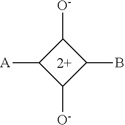

In General Formula (1), the aspects that can be adopted for A and B are as described for A and B in General Formula (1) described in the dye B and the dye C.

In a case where the dye D is a coloring agent represented by General Formula (1), a coloring agent represented by General Formula (14) is preferable.

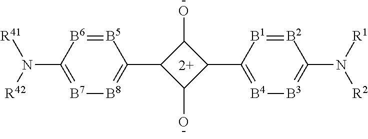

In General Formula (14), R¹ and R² respectively have the same meaning as R¹ and R² in General Formula (2) described above. R⁴¹ and R⁴² respectively have the same meaning as R¹ and R² in General Formula (2) described above.

Among the above, R¹, R², R⁴¹, and R⁴² are each preferably an alkyl group, an alkenyl group, an aryl group, or a heteroaryl group, more preferably an alkyl group, an aryl group, or a heteroaryl group, and still more preferably an alkyl group or an aryl group.

R¹, R², R⁴¹, and R⁴² may further have a substituent. Examples of the substituent which may be further contained therein include the substituent which may be further contained in R¹ and R² in General Formula (2) described above, and the substituent X (the substituent X described in paragraphs 0079 to 0095 of WO2021/221122A) which may be contained in A, B, and G in General Formula (1) described above.

B¹, B², B³, and B⁴ in General Formula (14) respectively have the same meaning as B¹, B², B³, and B⁴ in General Formula (2) described above. In addition, B⁵, B⁶, B⁷, and B¹ in General Formula (14) respectively have the same meaning as B¹, B², B³, and B⁴ in General Formula (2) described above.

The substituent possessed by the carbon atom that can be employed as B¹, B², B³, B⁴, B⁵, B⁶, B⁷, and B⁸ may further have a substituent. Examples of the substituent which may be further contained therein include the substituent X (the substituent X described in paragraphs 0079 to 0095 of WO2021/221122A) which may be contained in A, B, and G in General Formula (1) described above.

In General Formula (14), R¹ and R² may be bonded to each other to form a ring, and R¹ or R² and the substituent contained in B² or B³ may be bonded to each other to form a ring. In addition, R⁴¹ and R⁴² may be bonded to each other to form a ring, and R⁴¹ or R⁴² and the substituent contained in B⁶ or B⁷ may be bonded to each other to form a ring.

In the above description, the ring to be formed is preferably a heterocyclic ring or a heteroaryl ring, and it is preferably a 5-membered ring or a 6-membered ring although the size of the ring to be formed is not particularly limited. Further, the number of rings to be formed is not particularly limited, and it may be one or two or more. Examples of the form in which two or more rings are formed include a form in which the substituents of R¹ and B² and the substituents contained in R² and B³ are respectively bonded to each other to form two rings.

Examples of the coloring agent represented by General Formula (1) as a specific example of the dye D include the compounds described in paragraphs 0097 to 0099 of WO2023/228799A. However, the present invention is not limited thereto.

In addition, the indoaniline coloring agent represented by General Formula (v) in the above-described light absorption disappearing layer can also be preferably used as the dye D of the above-described wavelength-selective absorption layer.

The total content of the dyes (preferably the dyes A to D) in the wavelength-selective absorption layer is preferably 0.10% by mass or more, more preferably 0.15% by mass or more, still more preferably 0.20% by mass or more, particularly preferably 0.25% by mass or more, and especially preferably 0.30% by mass or more. In a case where the total content of the dyes A to D in the wavelength-selective absorption layer is equal to or more than the above-described preferred lower limit value, a good antireflection effect can be obtained.

In addition, the total content of the dyes (preferably the dyes A to D) in the wavelength-selective absorption layer is usually 50% by mass or less, preferably 40% by mass or less, more preferably 30% by mass or less, still more preferably 15% by mass or less, and particularly preferably 10% by mass or less.

That is, the total content of the dyes (preferably the dyes A to D) in the wavelength-selective absorption layer is preferably 0.10% to 50% by mass, more preferably 0.15% to 40% by mass, still more preferably 0.20% to 30% by mass, particularly preferably 0.25% to 15% by mass, and especially preferably 0.30% to 10% by mass.

The content of each of the dyes A to D that can be contained in the wavelength-selective absorption layer is preferably as follows.

The content of the dye A in the wavelength-selective absorption layer is preferably 0.01% to 45% by mass and more preferably 0.1% to 30% by mass. The content of the dye B in the wavelength-selective absorption layer is preferably 0.01% to 45% by mass and more preferably 0.1% to 30% by mass. The content of the dye C in the wavelength-selective absorption layer is preferably 0.01% to 30% by mass and more preferably 0.1% to 10% by mass. The content of the dye D in the wavelength-selective absorption layer is preferably 0.05% to 50% by mass and more preferably 0.2% to 40% by mass.

In a case where the wavelength-selective absorption layer contains all of the four dyes A to D, the content ratio of each of the dyes A to D in the wavelength-selective absorption layer is preferably dye A:dye B:dye C:dye D=1:0.1 to 10:0.05 to 5:0.1 to 10 and more preferably 1:0.2 to 5:0.1 to 3:0.2 to 5 in terms of mass ratio.

In a case where at least one of the dyes B or C is the internal quencher-type coloring agent, the content of the internal quencher-type coloring agent is preferably 0.1% by mass or more with respect to 100% by mass of the wavelength-selective absorption layer from the viewpoint of the antireflection effect. The upper limit value thereof is preferably 45% by mass or less. That is, the upper limit value thereof is preferably 0.1% to 45% by mass.

### <Resin>

The resin contained in the wavelength-selective absorption layer (hereinafter, also referred to as a “matrix resin”) is not particularly limited as long as it can disperse (preferably dissolve) the above-described dye. Among these, a resin which can satisfy the suppression of external light reflection and the suppression of brightness reduction and can maintain the original tint of the image of the OLED display device at an excellent level is preferable.

In a case where at least one of the dyes B or C is the above-described squaraine coloring agent represented by General Formula (1), the matrix resin is preferably a low-polarity matrix resin in which the squaraine coloring agent can exhibit a sharper absorption. In a case where the squaraine coloring agent exhibits a sharper absorption, the above-described relational expressions (I) to (VI) can be satisfied at a preferable level, and the original tint of the image of the OLED display device can be maintained at a more excellent level. Here, the low polarity means that an fd value defined by Relational Expression I is preferably 0.50 or more.

fd=δd/(δd+δp+δh) Relational Expression I:

In Relational Expression I, δd, δp, and δh respectively indicate a term corresponding to a London dispersion force, a term corresponding to a dipole-dipole force, and a term corresponding to a hydrogen bonding force with respect to a solubility parameter δt calculated according to the Hoy method. A specific calculation method of fd will be described later. That is, fd represents a ratio of δd to the sum of δd, δp and δh.

By setting the fd value to 0.50 or more, a sharper absorption waveform can be easily obtained.

Further, in a case where the wavelength-selective absorption layer contains two or more matrix resins, the fd value is calculated as follows.

$$fd = \sum ( {w}_{i} \cdot {fd}_{i} )$$

Here, wᵢ represents the mass fraction of the i-th matrix resin, and fdᵢ represents the fd value of the i-th matrix resin.

### —Term δd Corresponding to London Dispersion Force—

The term δd corresponding to the London dispersion force refers to δd obtained for the Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

### —Term δp Corresponding to Dipole-Dipole Force—

The term δp corresponding to the dipole-dipole force refers to δp obtained for Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

### —Term δ h Corresponding to Hydrogen Bonding Force—

The term δh corresponding to the hydrogen bonding force refers to δh obtained for the Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

In addition, in a case where the matrix resin is a resin exhibiting a certain hydrophobicity, the moisture content of the wavelength-selective absorption layer can be set to a low moisture content such as 0.5% or less, which is preferable from the viewpoint of improving the light resistance of the light absorption filter according to the embodiment of the present invention (excluding the light absorption disappearing layer).

The resin may contain a predetermined conventional component in addition to a polymer. However, the fd of the matrix resin is a calculated value for the polymer constituting the matrix resin.

Preferred examples of the matrix resin include a polystyrene resin and a cyclic polyolefin resin, and the polystyrene resin is more preferable. Usually, the fd value of the polystyrene resin is 0.45 to 0.60, and the fd value of the cyclic polyolefin resin is 0.45 to 0.70. As described above, it is preferable to use the resin having an fd value of 0.50 or more.

Further, for example, in addition to these preferable resins, it is also preferable to use a resin component that imparts functionality to the wavelength-selective absorption layer, such as an extensible resin component and a peelability control resin component, which will be described later. That is, in the present invention, the matrix resin is used in the meaning of including the extensible resin component and the peelability control resin component in addition to the above-mentioned resins.

It is preferable that the matrix resin includes a polystyrene resin in terms of sharpening the absorption waveform of the coloring agent.

### (Polystyrene Resin)

The polystyrene contained in the polystyrene resin means a polymer containing a styrene component. The polystyrene preferably contains 50% by mass or more of the styrene component. The wavelength-selective absorption layer may contain one kind of polystyrene or two or more kinds thereof. Here, the styrene component is a structural unit derived from a monomer having a styrene skeleton in the structure thereof.

The polystyrene more preferably contains 70% by mass or more of the styrene component, and still more preferably 85% by mass or more of the styrene component, in terms of controlling the photo-elastic coefficient and the hygroscopicity to values in ranges preferable for the wavelength-selective absorption layer. In addition, it is preferable that the polystyrene is composed of only the styrene component.

As the above-described polystyrene resin, the description of the polystyrene resin described in 0106 to 0110 of WO2023/228799A can be applied as it is.

The wavelength-selective absorption layer preferably contains a polyphenylene ether resin in addition to the polystyrene resin. By containing the polystyrene resin and the polyphenylene ether resin together, the toughness of the wavelength-selective absorption layer can be improved, and the occurrence of defects such as cracks can be suppressed even in a harsh environment such as high temperature and high humidity.

As the polyphenylene ether resin, XYRON S201A, XYRON S202A, and XYRON S203A (all of which are product names) manufactured by Asahi Kasei Corporation can be preferably used. In addition, a resin in which the polystyrene resin and the polyphenylene ether resin are mixed in advance may also be used. As the mixed resin of the polystyrene resin and the polyphenylene ether resin, for example, XYRON 1002H, XYRON 1000H, XYRON 600H, XYRLON 500H, XYRON 400H, XYRON 300H, XYRON 200H (all of which are product names), and the like manufactured by Asahi Kasei Corporation can be preferably used.

In a case where the polystyrene resin and the polyphenylene ether resin are contained in the wavelength-selective absorption layer, the mass ratio of both resins is preferably 99/1 to 50/50, more preferably 98/2 to 60/40, and still more preferably 95/5 to 70/30, in terms of the polystyrene resin/polyphenylene ether resin. In a case where the formulation ratio of the polyphenylene ether resin is set in the above-described preferred range, the wavelength-selective absorption layer can have sufficient toughness, and a solvent can be appropriately volatilized in a case where a film formation is carried out with a solution.

### (Cyclic Polyolefin Resin)

The cyclic olefin compound that forms the cyclic polyolefin contained in the above-described cyclic polyolefin resin (also referred to as a polycycloolefin resin) is not particularly limited as long as it is a compound having a ring structure including a carbon-carbon double bond, and examples thereof include a norbornene compound, a monocyclic cyclic olefin compound other than the norbornene compound, a cyclic conjugated diene compound, and a vinyl alicyclic hydrocarbon compound.

Examples of the cyclic polyolefin include (1) polymers including a structural unit derived from a norbornene compound; (2) polymers including a structural unit derived from a monocyclic olefin compound other than the norbornene compound; (3) polymers including a structural unit derived from a cyclic conjugated diene compound; (4) polymers including a structural unit derived from a vinyl alicyclic hydrocarbon compound; and hydrogenated products of polymers including a structural unit derived from each of the compounds (1) to (4).

In the present invention, ring-opening polymers of the respective compounds are included in the polymers including a structural unit derived from a norbornene compound and the polymers including a structural unit derived from a monocyclic olefin compound.

As the above-described cyclic polyolefin resin, the description of the cyclic polyolefin resin described in 0112 to 0125 of WO2023/228799A can be applied as it is.

In addition, the resin described in the section of the light absorption disappearing layer above can also be preferably used as the resin of the wavelength-selective absorption layer.

The wavelength-selective absorption layer preferably contains 5% by mass or more of the matrix resin, more preferably 20% by mass or more, still more preferably 50% by mass or more, particularly preferably 70% by mass or more, and most preferably 80% by mass or more.

The content of the matrix resin in the wavelength-selective absorption layer is generally 99.90% by mass or less and preferably 99.85% by mass or less. That is, the content is preferably 5% to 99.90% by mass, more preferably 20% to 99.90% by mass, still more preferably 50% to 99.90% by mass, particularly preferably 70% to 99.90% by mass, and most preferably 80% to 99.85% by mass.

### (Extensible Resin Component)

The wavelength-selective absorption layer can appropriately select and contain a component exhibiting extensibility (also referred to as an extensible resin component) as a resin component. Specific examples thereof include an acrylonitrile-butadiene-styrene resin (an ABS resin), a styrene-butadiene resin (an SB resin), an isoprene resin, a butadiene resin, a polyether-urethane resin, and a silicone resin. Further, these resins may be further hydrogenated as appropriate.

As the extensible resin component, it is preferable to use an ABS resin or an SB resin, and it is more preferable to use an SB resin.

As the SB resin, for example, a commercially available one can be used. As such commercial products, TR2000, TR2003, and TR2250 (all, product name, manufactured by JSR Corporation), CLEAREN 210M, 220M, and 730V (all, product name, manufactured by Denka Corporation), Asaflex 800S, 805, 810, 825, 830, and 840 (all, product name, manufactured by Asahi Kasei Corporation), EPOREX SB2400, SB2610, and SB2710 (all, product name, Sumitomo Chemical Co., Ltd.), and the like can be exemplified.

The wavelength-selective absorption layer preferably contains 15% to 95% by mass of the extensible resin component in the matrix resin, more preferably contains 20% to 50% by mass, and still more preferably contains 25% to 45% by mass.

As the extensible resin component, in a case where a sample having an aspect with a thickness of 30 μm and a width of 10 mm is prepared by using the extensible resin component alone and the breaking elongation at 25° C. is measured in accordance with JIS 7127, a component having the breaking elongation of 10% or more is preferable, and a component having the breaking elongation of 20% or more is more preferable.

### <Other Components>

The light absorption disappearing layer and the wavelength-selective absorption layer according to the embodiment of the present invention may contain a leveling agent (surfactant) or the like in addition to each of the above-described components (dye, resin, and radical generator in the light absorption disappearing layer).

### (Leveling Agent)

Each of the light absorption disappearing layer and the wavelength-selective absorption layer can appropriately contain a leveling agent (surfactant). As the leveling agent, a commonly used compound can be used, and a fluorine-containing surfactant is particularly preferable. Specific examples thereof include compounds described in paragraphs 0028 to 0056 of JP2001-330725A; and preferred examples thereof include a copolymer consisting of a constitutional unit having a fluorine-substituted alkyl group and a constitutional unit derived from an alkyl (meth)acrylate, in a copolymer represented by Formula (IV) described in paragraph 0054 of JP2001-330725A. In addition, as the commercially available product, MEGAFACE F (product name) series manufactured by DIC Corporation can also be used.

The content of the leveling agent in the light absorption disappearing layer or the wavelength-selective absorption layer is appropriately adjusted according to the purpose.

In addition to each of the above-described components, the light absorption disappearing layer and the wavelength-selective absorption layer may each contain a low-molecular-weight plasticizer, an oligomer-based plasticizer, a retardation adjusting agent, an ultraviolet absorber, a degradation inhibitor, a peeling accelerator, an infrared absorber, an antioxidant, a filler, a compatibilizer, and the like.

### (Matting Agent)

Fine particles may be added to the surface of the light absorption filter according to the embodiment of the present invention in order to impart sliding properties and prevent blocking. As the fine particles, silica (silicon dioxide, SiO₂) of which the surface is coated with a hydrophobic group and which has an aspect of secondary particles is preferably used. The fine particles may use, in addition to or instead of silica, fine particles of titanium dioxide, aluminum oxide, zirconium oxide, calcium carbonate, talc, clay, calcined kaolin, calcined calcium silicate, hydrated calcium silicate, aluminum silicate, magnesium silicate, and calcium phosphate. Examples of the commercially available product of the fine particles include the R972 and NX90S (product name, both manufactured by Nippon Aerosil Co., Ltd.).

The fine particles function as a so-called matting agent, and the addition of the fine particles forms minute unevenness on the surface of the light absorption filter according to the embodiment of the present invention. Due to the unevenness, even in a case where the light absorption filters according to the embodiment of the present invention overlap with each other or the light absorption filter according to the embodiment of the present invention and other films overlap with each other, the films do not stick to each other and sliding properties are secured.

In a case where the light absorption filter according to the embodiment of the present invention contains a matting agent as fine particles, the effect of improving sliding properties and blocking properties is particularly large in the fine unevenness due to the protrusions in which fine particles protrude from the filter surface in a case where there are 10⁴/mm² or more of protrusions having a height of 30 nm or more.

Examples of a method of imparting fine particles to the surface layer of the light absorption filter according to the embodiment of the present invention include a method using a multilayer casting, a coating, or the like.

The content of the matting agent in the light absorption filter according to the embodiment of the present invention is appropriately adjusted depending on the intended purpose.

The matting agent (fine particles) added (also referred to as imparted to the surface layer) to the surface of the light absorption filter according to the embodiment of the present invention is also present as it is on the surface of the optical filter according to the embodiment of the present invention, which is obtained using the light absorption filter according to the embodiment of the present invention, and can prevent the optical filters according to the embodiment of the present invention from adhering to each other, or the optical filter according to the embodiment of the present invention from adhering to other films or the like in a case where the optical filters according to the embodiment of the present invention overlap with each other, or the optical filter according to the embodiment of the present invention overlaps with other films or the like.

### <Manufacturing Method for Light Absorption Filter>

### (Method of Manufacturing Light Absorption Disappearing Layer and Wavelength-Selective Absorption Layer)

The light absorption disappearing layer and the wavelength-selective absorption layer in the light absorption filter according to the embodiment of the present invention can be produced according to conventional method by a solution film-forming method, a melt extrusion method, or a method (coating method) of forming a coating layer on a substrate film (support film) by any method, and stretching can also be appropriately combined. The light absorption disappearing layer and the wavelength-selective absorption layer in the light absorption filter according to the embodiment of the present invention are preferably produced by a coating method.

The solution film-forming method and the melt extrusion method described in 0197 to 0203 of WO2021/132674A can be applied as they are to the solution film-forming method and the melt extrusion method described above, except that “light absorption filter” is read as “light absorption disappearing layer” or “wavelength-selective absorption layer”.

### (Coating Method)

In the coating method, a solution of a material of the light absorption disappearing layer or the wavelength-selective absorption layer is applied to a support film to form a coating layer. A release agent or the like may be appropriately applied to the surface of the support film in advance in order to control the adhesiveness to the coating layer. In addition, a coating layer may be formed on the support film through any resin layer. The coating layer can be used by peeling off the support film after being laminated with another member while interposing an adhesive layer in a later step. Any adhesive can be appropriately used as the adhesive constituting the adhesion layer. In a state where the solution of the material of the light absorption disappearing layer or the wavelength-selective absorption layer is applied to the support film or in a state where the coating layer is laminated on the support film, the support film can be appropriately stretched.

The solvent used in the solution of the material of the light absorption disappearing layer or the wavelength-selective absorption layer can be appropriately selected from the viewpoint that the solvent can dissolve or disperse the material of the light absorption disappearing layer or the wavelength-selective absorption layer, the solvent can easily form a uniform surface in the coating step and the drying step, liquid preservability can be ensured, the solvent has an appropriate saturated vapor pressure, and the like.

### —Addition of Component Constituting Light Absorption Disappearing Layer or Wavelength-Selective Absorption Layer—

The timing of adding the dye and the radical generator to the material of the light absorption disappearing layer is not particularly limited as long as the dye and the radical generator are added at the time of film formation. For example, the dye and the radical generator may be added at the time of synthesizing the polymer constituting the matrix resin, or may be mixed with the material of the light absorption disappearing layer at the time of preparing the coating liquid of the material of the light absorption disappearing layer. It is noted that in a case where the radical generator includes a combination of the compound A and the compound B, and the compound A is bonded to the polymer that constitutes the resin, the compound A is added at the time of adding the polymer that constitutes the resin.

The timing of adding the dye to the wavelength-selective absorption layer material is not particularly limited as long as the dye is added at the time of film formation. For example, the dye may be added at the time of synthesizing the polymer constituting the resin, or may be mixed with the material of the wavelength-selective absorption layer at the time of preparing the coating liquid of the material of the wavelength-selective absorption layer.

### —Support Film—

A support film used for forming the light absorption disappearing layer or the wavelength-selective absorption layer by a coating method or the like preferably has a film thickness of 5 to 100 μm, more preferably 10 to 75 μm, and still more preferably 15 to 55 μm. In a case where the film thickness is equal to or more than the above-described preferred lower limit value, sufficient mechanical strength can be easily secured, and failures such as curling, wrinkling, and buckling are less likely to occur. In addition, in a case where the film thickness is equal to or less than the above-described preferred upper limit value, in a case where a multilayer film of the light absorption disappearing layer or the wavelength-selective absorption layer and the support film, and a multilayer film including the light absorption disappearing layer, the wavelength-selective absorption layer, and the support film are stored in the form of, for example, a long roll, a surface pressure applied to the multilayer film is easily adjusted to be in an appropriate range, and adhesion failure is less likely to occur.

The surface energy of the support film is not particularly limited, but the adhesive strength between the light absorption filter according to the embodiment of the present invention and the support film can be adjusted by adjusting the relationship between the surface energies of the material of the light absorption disappearing layer or the wavelength-selective absorption layer and of the coating liquid and the surface energy of the surface of the support film on the side where the light absorption disappearing layer or the wavelength-selective absorption layer is formed. In a case where the surface energy difference is reduced, the adhesive force tends to increase, in a case where the surface energy difference is increased, the adhesive force tends to decrease, and thus the surface energy difference can be set appropriately.

In addition, the surface irregularities of the support film are not particularly limited, but can be adjusted for the purpose of preventing adhesion failure in a case where a multilayer film of the light absorption filter according to the embodiment of the present invention and the support film is stored in the form of, for example, a long roll, according to the relationship between the surface energy, the hardness, and the surface irregularities of the surface of the light absorption filter according to the embodiment of the present invention on the side opposite to the support film, and the surface energy and the hardness of the surface of the support film on the side opposite to the side where the light absorption filter according to the embodiment of the present invention is formed. In a case where the surface unevenness is increased, adhesion defect tends to be suppressed, and in a case where the surface unevenness is reduced, the surface unevenness of the light absorption filter according to the embodiment of the present invention tends to be decreased and the haze of the light absorption filter according to the embodiment of the present invention tends to be small. Thus, the surface unevenness can be set appropriately.

For such a support film, any material and film can be appropriately used. Specific examples of the material include a polyester-based polymer (including a polyethylene terephthalate-based polymer), an olefin-based polymer, a cycloolefin-based polymer, a (meth)acrylic polymer, a cellulose-based polymer, and a polyamide-based polymer. In addition, a surface treatment can be appropriately carried out for the intended purpose of adjusting the surface properties of the support film. For example, a corona treatment, a normal temperature plasma treatment, or a saponification treatment can be carried out to decrease the surface energy, and a silicone treatment, a fluorine treatment, an olefin treatment, or the like can be carried out to raise the surface energy.

### (Diffusion Inhibiting Layer)

In the light absorption filter according to the embodiment of the present invention, it is preferable that the wavelength-selective absorption layer, the diffusion inhibiting layer, and the light absorption disappearing layer are laminated in this order to be in direct contact with each other.

The diffusion inhibiting layer may be provided between the wavelength-selective absorption layer and the light absorption disappearing layer, and it is sufficient that the diffusion inhibiting layer has an effect of suppressing the diffusion of the component such as the dye contained in the wavelength-selective absorption layer into the light absorption disappearing layer and an effect of suppressing the diffusion of the component such as the dye and the radical generator contained in the light absorption disappearing layer into the wavelength-selective absorption layer.

The diffusion of the component in the wavelength-selective absorption layer into the light absorption disappearing layer can occur in any state during the formation of the wavelength-selective absorption layer on the light absorption disappearing layer and during the formation of the wavelength-selective absorption layer on the light absorption disappearing layer. The diffusion of the component in the light absorption disappearing layer into the wavelength-selective absorption layer can occur in any state during the formation of the light absorption disappearing layer on the wavelength-selective absorption layer and during the formation of the light absorption disappearing layer on the wavelength-selective absorption layer.

In the light absorption filter according to the embodiment of the present invention, by providing the diffusion inhibiting layer between the wavelength-selective absorption layer and the light absorption disappearing layer, as described above, the diffusion of the component in the wavelength-selective absorption layer into the light absorption disappearing layer and the diffusion of the component in the light absorption disappearing layer into the wavelength-selective absorption layer can be suppressed. As a result, the fading and decolorization reaction of the dye in the light absorption disappearing layer due to the ultraviolet irradiation of the light absorption filter according to the embodiment of the present invention can be performed as the fading and decolorization reaction of the dye due to the compound that generates a radical upon ultraviolet irradiation in the light absorption disappearing layer. By providing the diffusion inhibiting layer, it is possible to further realize the desired light absorption characteristics derived from each of the wavelength-selective absorption layer and the light absorption disappearing layer in the optical filter according to the embodiment of the present invention obtained by using the light absorption filter according to the embodiment of the present invention.

In the form in which the wavelength-selective absorption layer, the diffusion inhibiting layer, and the light absorption disappearing layer are laminated to be in direct contact with each other in this order, it is considered that the effect of the swelling of the diffusion inhibiting layer due to the solvent (solvent) in the coating liquid for forming the light absorption disappearing layer or the wavelength-selective absorption layer and the increase in the free volume in the diffusion inhibiting layer is large during the formation of the light absorption disappearing layer on the diffusion inhibiting layer or during the formation of the wavelength-selective absorption layer on the diffusion inhibiting layer. From this viewpoint, in the light absorption filter according to the embodiment of the present invention, it is preferable that the resin constituting the diffusion inhibiting layer provided between the wavelength-selective absorption layer and the light absorption disappearing layer has a low affinity for the solvent used in a case of forming the wavelength-selective absorption layer or the light absorption disappearing layer on the diffusion inhibiting layer. For example, in a case where the light absorption disappearing layer is formed on the diffusion inhibiting layer, in a case where the component such as the dye contained in the light absorption disappearing layer and the compound that generates a radical upon ultraviolet irradiation is a material that is dissolved in an organic solvent (non-aqueous solvent), it is preferable that the resin constituting the diffusion inhibiting layer is a resin having a low affinity for the organic solvent, that is, a water-soluble resin. In addition, in a case where the wavelength-selective absorption layer is formed on the diffusion inhibiting layer, in a case where the component such as the dye contained in the wavelength-selective absorption layer is a material that is dissolved in an organic solvent (non-aqueous solvent), it is preferable that the resin constituting the diffusion inhibiting layer is a resin having a low affinity for the organic solvent, that is, a water-soluble resin.

The affinity between the solvent used in a case of forming the wavelength-selective absorption layer or the light absorption disappearing layer and the resin constituting the diffusion inhibiting layer can be evaluated by a solubility parameter St calculated by the Hoy method. For example, the solubility parameter St can be calculated by a method described in the column of “2) Method of Hoy (1985, 1989)” on pages 214 to 220 of the literature “Properties of Polymers 3^{rd}, ELSEVIER, (1990)”.

In the present invention, the absolute value of the difference between the St value of the solvent used in a case of forming the wavelength-selective absorption layer or the light absorption disappearing layer and the St value of the resin constituting the diffusion inhibiting layer is preferably 1.0 or more, more preferably 2.0 or more, still more preferably 3.0 or more, and particularly preferably 4.0 or more. It is preferable that the absolute value of the difference between the δt value of the solvent used in a case of forming the wavelength-selective absorption layer or the light absorption disappearing layer and the δt value of the resin constituting the diffusion inhibiting layer is adjusted to be equal to or more than the above-described preferred value, because in a case where the liquid for forming the wavelength-selective absorption layer or the light absorption disappearing layer is applied onto the diffusion inhibiting layer, the solvent contained in the liquid for forming the wavelength-selective absorption layer or the light absorption disappearing layer is suppressed from being transmitted through the diffusion inhibiting layer, and the swelling of the layer positioned on the lower side of the diffusion inhibiting layer (the light absorption disappearing layer in a case where the wavelength-selective absorption layer is provided on the diffusion inhibiting layer, and the wavelength-selective absorption layer in a case where the light absorption disappearing layer is provided on the diffusion inhibiting layer) is effectively suppressed. The upper limit value of the absolute value of the difference between the δt value of the solvent used in a case of forming the wavelength-selective absorption layer or the light absorption disappearing layer and the δt value of the resin constituting the diffusion inhibiting layer is practically 20.0 or less, and the absolute value of the difference between the δt value of the solvent used in a case of forming the wavelength-selective absorption layer or the light absorption disappearing layer and the δt value of the resin constituting the diffusion inhibiting layer is preferably 1.0 to 20.0, more preferably 2.0 to 20.0, still more preferably 3.0 to 20.0, and particularly preferably 4.0 to 20.0.

In a case where two or more kinds of solvents are used in a case of forming the wavelength-selective absorption layer or the light absorption disappearing layer, the δt value of the solvent means a weight-average value of the δt values of the respective solvents. In addition, in a case where the diffusion inhibiting layer is composed of two or more kinds of resins, the δt value of the resin means a weight-average value of the δt values of the respective resins.

### (Resin)

As the resin constituting the diffusion inhibiting layer, a water-soluble resin is preferable. The water-soluble resin may be any of a thermosetting resin or a thermoplastic resin, and in a case where the water-soluble resin is a thermoplastic resin, the water-soluble resin may be crystalline or non-crystalline.

For example, as the water-soluble resin, polyvinyl alcohol, polyvinylpyridine, a (meth)acrylic resin, polyurethane, polyester, an epoxy resin, a cellulose resin, or the like can be preferably used. At least a part of these water-soluble resins may be modified.

The polyvinyl alcohol may be modified or may not be modified. Examples of the modified polyvinyl alcohol include modified polyvinyl alcohol into which a group such as an acetoacetyl group and a carboxy group is introduced.

From the viewpoint of further increasing the barrier properties (transmission inhibiting performance) of the organic solvent, the saponification degree of the above-described polyvinyl alcohol is preferably 60.0 mol % or more, more preferably 80.0 mol % or more, and still more preferably 90.0 mol % or more. The upper limit value thereof is not particularly limited; however, it is practically 99.99% by mole or less. The saponification degree of the polyvinyl alcohol is a value calculated based on the method described in JIS K 6726 (1994).

The above-described (meth)acrylic resin may be any resin including at least one of a constitutional unit derived from (meth)acrylic acid or a constitutional unit derived from a (meth)acrylic acid ester, and a resin including a constitutional unit derived from (meth)acrylic acid is preferable. The proportion of the constitutional unit derived from (meth)acrylic acid in all constitutional units constituting the (meth)acrylic resin is preferably 70 to 100 mol %, more preferably 80 to 100 mol %, and still more preferably 90 to 100 mol %.

Among these, from the viewpoint that the crystal portion can effectively suppress the permeation of solvent molecules and the viewpoint that swelling due to the organic solvent used in the dye layer is unlikely to occur, as the resin constituting the diffusion inhibiting layer, at least one of a polyvinyl alcohol or a (meth)acrylic resin is preferably used, and at least one of a polyvinyl alcohol or a poly(meth)acrylic acid is more preferably used.

Furthermore, from the viewpoint of further improving the adhesiveness between each layer constituting the light absorption filter according to the embodiment of the present invention, the resin constituting the diffusion inhibiting layer is still more preferably poly(meth)acrylic acid.

The content of the resin (preferably, the water-soluble resin) in the diffusion inhibiting layer is, for example, preferably 90% by mass or more and more preferably 95% by mass or more. The upper limit value thereof is not particularly limited, and it can be set to 100% by mass.

From the viewpoint of further improving the diffusion inhibition ability, the thickness of the diffusion inhibiting layer is preferably 0.1 to 5.0 μm and more preferably 0.2 to 4.0 μm.

### (Method for Producing Diffusion Inhibiting Layer)

The method for forming the diffusion inhibiting layer is not particularly limited, and examples thereof include a method of producing the diffusion inhibiting layer on the wavelength-selective absorption layer or the light absorption disappearing layer by any casting method such as spin coating and slit coating according to a conventional method.

The solvent used in this case can be used without particular limitation as long as a desired diffusion inhibiting layer can be obtained. For example, in a case where the resin constituting the diffusion inhibiting layer is a water-soluble resin, a water-soluble solvent such as water, ethanol, or isopropyl alcohol can be preferably used.

### <Film Thickness of Light Absorption Disappearing Layer and Wavelength-Selective Absorption Layer>

The film thicknesses of the light absorption disappearing layer and the wavelength-selective absorption layer are not particularly limited, but are each preferably 1 to 18 μm, more preferably 1 to 12 μm, and still more preferably 1 to 8 μm. In a case where the film thickness is equal to or less than the above-described preferred upper limit value, the decrease in the degree of polarization due to the fluorescence emitted by a dye (a coloring agent) can be suppressed by adding the dye to the thin film at a high concentration. In addition, in the light absorption disappearing layer, the effect of the quencher is also likely to be exhibited. On the other hand, in a case where the film thickness is equal to or more than the above-described preferred lower limit value, it is easy to maintain the evenness of the in-plane absorbance.

In the present invention, the film thickness of 1 to 18 μm means that the thickness of the light absorption disappearing layer and the thickness of the wavelength-selective absorption layer are within a range of 1 to 18 μm even in a case of being measured at any portion. The same applies to the film thicknesses of 1 to 12 μm and 2 to 8 μm. The film thickness can be measured with an electronic micrometer (for example, manufactured by Anritsu Corporation).

### <Absorbance of Light Absorption Filter According to Embodiment of Present Invention>

In the light absorption filter according to the embodiment of the present invention, the highest absorbance among the absorbances at the wavelength showing the maximum absorption (hereinafter, also simply referred to as “Ab(λₘₐₓ)”) in a wavelength range of 400 to 700 nm is preferably 0.3 or more, more preferably 0.5 or more, and still more preferably 0.7 or more.

However, the absorbance of the light absorption filter according to the embodiment of the present invention can be adjusted by the type, amount added, or film thickness of the dye.

### <Decolorization Rate of Light Absorption Disappearing Layer>

In the light absorption disappearing layer in the light absorption filter according to the embodiment of the present invention, the decolorization rate upon ultraviolet irradiation at 25° C. is preferably 85% or more, more preferably 87% or more, and still more preferably 90% or more. The upper limit value thereof is not particularly limited, and it is preferably 100%. That is, the decolorization rate is preferably 85% to 100%, more preferably 87% to 100%, and still more preferably 90% to 100%.

The decolorization rate is calculated according to the following expression using the values of Ab(λₘₐₓ) before and after the ultraviolet irradiation test.

$$Decolorization rate ( \% ) = 100 - ( Ab ( {λ}_{max} ) after ultraviolet irradiation / Ab ( {λ}_{max} ) before ultraviolet irradiation ) \times 100 \%$$

Here, in the ultraviolet irradiation test, the light absorption filter is irradiated with ultraviolet rays having an illuminance of 100 mW/cm² and an irradiation dose of 2,000 mJ/cm² at room temperature (45° C.) using an ultra-high pressure mercury lamp (for example, trade name: UL750, manufactured by HOYA Corporation) under atmospheric pressure (101.33 kPa).

The absorbance, the ultraviolet irradiation test, and the decolorization rate can be measured and calculated according to the methods described in Examples.

In addition, it is preferable that the light absorption disappearing layer hardly causes absorption (secondary absorption) derived from a new coloration structure associated with the decomposition of the coloring agent.

For example, the presence or absence of the absorption derived from the new coloration structure associated with the decomposition of the coloring agent can be checked based on the ratio of the absorbance at a specific wavelength to the above Ab(λₘₐₓ). As the specific wavelength, a wavelength at which the coloring agent before ultraviolet irradiation hardly exhibits absorption but new absorption due to the decomposition of the coloring agent is observed is selected.

As a specific example, as described in Examples described later, the presence or absence of the absorption derived from the new coloration structure associated with the decomposition of the coloring agent can be checked based on the ratio of the absorbance at a specific wavelength to the above Ab(λₘₐₓ). As the specific wavelength, a wavelength at which the coloring agent before ultraviolet irradiation hardly exhibits absorption but new absorption due to the decomposition of the coloring agent is observed is selected.

As a specific example, as described in Examples described later, the presence or absence of the absorption derived from a new coloration structure associated with the decomposition of the coloring agent can be checked based on the ratio of the absorbance in a wavelength range of 450 nm to the above Ab(λₘₐₓ) (hereinafter, also simply referred to as “Ab(450)”). That is, the smaller the value obtained by subtracting the ratio of the following (I) from the ratio of the following (II), the less absorption derived from the new coloration structure associated with the decomposition of the coloring agent occurs, and this value is preferably less than 8.5%, more preferably 7.0% or less, and still more preferably 5.0% or less. The lower limit value thereof is not particularly limited; however, it is practically −10% or more and preferably −6% or more from the viewpoint of making valid the evaluation related to the presence or absence of the secondary absorption associated with the decomposition of the coloring agent.

$$( Ab ( 450 ) before ultraviolet irradiation / Ab ( {λ}_{max} ) before ultraviolet irradiation ) \times 100 \% \qquad ( I )$$

$$( Ab ( 450 ) after ultraviolet irradiation / Ab ( {λ}_{max} ) before ultraviolet irradiation ) \times 100 \% \qquad ( II )$$

The checking of the presence or absence of the absorption derived from the new coloration structure associated with the decomposition of the coloring agent can be carried out by the measurement and the calculation according to the method described in Examples.

In addition, the evaluation can also be performed by using a value of the absorbance at a wavelength of 650 nm (hereinafter, also simply referred to as “Ab(650)”) instead of the absorbance at a wavelength of 450 nm, and subtracting the ratio of (III) from the ratio of (IV). The preferred range of the value obtained by subtracting the ratio of (III) from the ratio of (IV) is synonymous with the value obtained by subtracting the ratio of (I) from the ratio of (II).

$$( Ab ( 650 ) before ultraviolet irradiation / Ab ( {λ}_{max} ) before ultraviolet irradiation ) \times 100 \% \qquad ( III )$$

$$( Ab ( 650 ) after ultraviolet irradiation / Ab ( {λ}_{max} ) before ultraviolet irradiation ) \times 100 \% \qquad ( IV )$$

Here, the description of the ultraviolet irradiation test regarding the above decolorization rate can be preferably applied to the ultraviolet irradiation test.

The checking of the presence or absence of the absorption derived from the new coloration structure associated with the decomposition of the coloring agent can be carried out by the measurement and the calculation according to the method described in Examples.

In the light absorption disappearing layer, both the decolorization rate and the value for confirming the presence or absence of the absorption derived from the new coloration structure associated with the decomposition of the coloring agent satisfy the preferred ranges, whereby excellent decolorization properties can be exhibited.

In the optical filter obtained by using the light absorption filter according to the embodiment of the present invention, it is preferable that the ultraviolet ray non-irradiated portion (portion having a light absorption effect) in the light absorption disappearing layer satisfies the description of Ab(λₘₐₓ) according to the light absorption filter according to the embodiment of the present invention.

### <Treatment of Light Absorption Filter According to Embodiment of Present Invention>

The light absorption filter according to the embodiment of the present invention may be subjected to a hydrophilic treatment by any of glow discharge treatment, corona discharge treatment, or alkali saponification treatment, and a corona discharge treatment is preferably used. It is also preferable to apply the method described in JP1994-094915A (JP-H6-094915A) and JP1994-118232A (JP-H6-118232A).

If necessary, the obtained film may be subjected to a heat treatment step, a superheated steam contact step, an organic solvent contact step, or the like. In addition, a surface treatment may be suitably performed.

In addition, as a pressure sensitive adhesive layer, a layer consisting of a pressure sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description regarding the pressure sensitive adhesive layer in the OLED display device described later can be applied.

### <Gas Barrier Layer>

The light absorption filter according to the embodiment of the present invention may have a gas barrier layer on at least one surface. In a case where the light absorption filter according to the embodiment of the present invention has a gas barrier layer, the light absorption filter according to the embodiment of the present invention can be made to be a light absorption filter that achieves both high decolorizing properties and excellent light resistance and can be suitably used in the production of an optical filter described later.

The material that forms the gas barrier layer is not particularly limited, and examples thereof include an organic material (preferably a crystalline resin) such as polyvinyl alcohol or polyvinylidene chloride, an organic-inorganic hybrid material such as a sol-gel material, and an inorganic material such as SiO₂, SiOₓ, or SiON, SiNₓ, or Al₂O₃. The gas barrier layer may be a single layer or a multi-layer. In the case of a multi-layer, examples thereof include configurations such as an inorganic dielectric multi-layer film and a multi-layer film obtained by alternately laminating organic materials and inorganic materials.

In the light absorption filter according to the embodiment of the present invention, the gas barrier layer is provided at least on a surface of the light absorption filter according to the embodiment of the present invention (further, an optical filter according to the embodiment of the present invention described later) that comes into contact with air, whereby a decrease in the absorption intensity of the dye in the light absorption filter according to the embodiment of the present invention can be suppressed. As long as the gas barrier layer is provided at an interface of the light absorption filter according to the embodiment of the present invention in contact with air, the gas barrier layer may be provided on only one surface of the light absorption filter according to the embodiment of the present invention, or may be provided on both surfaces.

Among the above, in a case of a configuration in which the gas barrier layer contains a crystalline resin, the gas barrier layer contains a crystalline resin, and it is preferable that the thickness of the layer is 0.1 μm to 10 μm and the oxygen permeability of the layer is 60 cc/m²·day·atm or less.

In the gas barrier layer, the “crystalline resin” is a resin having a melting point that undergoes a phase transition from a crystal to a liquid in a case where the temperature is raised, and it can impart gas barrier properties related to oxygen gas to the gas barrier layer.

“The gas barrier layer containing a crystalline resin, where the thickness of the layer is 0.1 μm to 10 μm and the oxygen permeability of the layer is 60 cc/m²·day·atm or less” described above is the same as the gas barrier layers described in [0180] to [0184] of WO2022/149510A, and these descriptions can be applied as they are.

### <Manufacturing Method for Gas Barrier Layer>

The method of forming the gas barrier layer is not particularly limited, and examples thereof include a producing method according to a conventional method according to a casting method such as spin coating or slit coating, for example, in a case of an organic material. In addition, examples thereof can include a method of bonding a commercially available resin gas barrier film or a resin gas barrier film produced in advance to the light absorption filter according to the embodiment of the present invention. In addition, examples thereof include a plasma enhanced chemical vapor deposition (PECVD) method, a sputtering method and a vapor deposition method in a case of an inorganic material.

In a case where the above-described gas barrier layer is provided in the light absorption filter according to the embodiment of the present invention, for example, a method of directly producing the above-described gas barrier layer on the light absorption filter according to the embodiment of the present invention produced according to the above-described production method is included. In this case, it is also preferable to apply a corona treatment to the surface of the light absorption filter according to the embodiment of the present invention to which the gas barrier layer is provided.

In addition, in a case where the optional optical functional film described later is provided, it is also preferable to carry out bonding while interposing a pressure sensitive adhesive layer. For example, it is also preferable that a gas barrier layer is provided on the light absorption filter according to the embodiment of the present invention and then bonded to an optical functional film while interposing a pressure sensitive adhesive layer.

### <Optical Functional Film>

The light absorption filter according to the embodiment of the present invention may appropriately have the gas barrier layer or any optical functional film as long as the effect of the present invention is not impaired.

The optional optical functional film is not particularly limited in terms of any of the optical properties and the materials, and a film containing (or containing as a main component) at least any of a cellulose ester resin, an acrylic resin, a cyclic olefin resin, or a polyethylene terephthalate resin can be preferably used. An optically isotropic film or an optically anisotropic retardation film may be used.

For the above optional optical functional films, for example, Fujitac TD80UL (manufactured by FUJIFILM Corporation) or the like can be used as a film containing a cellulose ester resin.

Regarding the optional optical functional film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical functional film containing a (meth)acrylic resin having a glutaric anhydride unit described in JP2009-139754A can be used.

In addition, regarding the optional optical functional films, as those containing a cyclic olefin resin, cyclic olefin-based resin film described in paragraphs [0029] and subsequent paragraphs of JP2009-237376A, and cyclic olefin resin film containing an additive reducing Rth described in JP4881827B, and JP2008-063536A can be used.

### [Optical Filter]

The optical filter according to the embodiment of the present invention is obtained by a method including mask exposure of the light absorption filter according to the embodiment of the present invention by ultraviolet irradiation. In the optical filter according to the embodiment of the present invention, a layer derived from the wavelength-selective absorption layer and the light absorption disappearing layer in the light absorption filter according to the embodiment of the present invention will be described as a wavelength-selective absorption layer in the optical filter according to the embodiment of the present invention and a light absorption disappearing layer in the optical filter according to the embodiment of the present invention, respectively.

The light absorption disappearing layer in the optical filter according to the embodiment of the present invention has a light absorptive portion having a light absorption effect and a site (light absorption disappearing portion) where the light absorptivity disappears, according to a pattern of mask exposure by ultraviolet irradiation (hereinafter, also referred to as a “mask pattern”). On the other hand, the wavelength-selective absorption layer in the optical filter according to the embodiment of the present invention has almost the same light absorption characteristics as the wavelength-selective absorption layer in the light absorption filter according to the embodiment of the present invention, regardless of the mask exposure by ultraviolet irradiation.

That is, by mask-exposing the light absorption filter according to the embodiment of the present invention by ultraviolet irradiation, a masked portion in the light absorption filter according to the embodiment of the present invention is not exposed and remains as a light absorptive portion having a light absorption effect, and a non-masked portion is exposed, the light absorption disappearing layer in the non-masked portion is decolorized to become a light absorption disappearing portion, and the non-masked portion becomes a site having low light absorptivity.

The light absorptive portion can exhibit a desired absorbance.

In addition, the above-described light absorption disappearing portion is such that, since the above-described light absorption disappearing layer exhibits an excellent decolorization rate and secondary absorption due to the decomposition of the dye hardly occurs, the light absorption disappearing layer in the optical filter according to the embodiment of the present invention can exhibit optical characteristics close to colorless, and can exhibit light absorption characteristics specific to the wavelength-selective absorption layer in the optical filter according to the embodiment of the present invention.

### <Method for Manufacturing Optical Filter>

The optical filter according to the embodiment of the present invention can be obtained by irradiating the light absorption filter according to the embodiment of the present invention with ultraviolet rays to carry out mask exposure.

The mask pattern can be appropriately adjusted such that the optical filter according to the embodiment of the present invention having a desired pattern composed of a site having high light absorptivity and a site having low light absorptivity is obtained.

In particular, in the present invention, it is preferable that the mask pattern is set such that a site corresponding to a non-display portion (a site where display light is not emitted) in a display device is a site having high light absorptivity, and a site corresponding to a display portion (a site where display light is emitted) in the display device is a site having low light absorptivity. That is, in the light absorption filter according to the embodiment of the present invention, the optical filter according to the embodiment of the present invention can be suitably obtained by performing ultraviolet irradiation with a mask pattern in which a site corresponding to a non-display portion in a display device is masked and a site corresponding to a display portion in the display device is not masked.

In the display device, the area ratio of the non-display portion of the display device to the display portion of the display device is usually the non-display portion of the display device/the display portion of the display device=90/10 to 60/40, and from the viewpoint that both the suppression of external light reflection and the suppression of reflection tint and the suppression of brightness reduction can be achieved at a higher level, it is preferably 80/20 to 60/40. It is considered that even in a case of a display device having an area ratio of the non-display portion of the display device/the display portion of the display device=90/10, by using the optical filter according to the embodiment of the present invention obtained by mask-exposing the light absorption filter according to the embodiment of the present invention including the above-described light absorption disappearing layer and wavelength-selective absorption layer, the light absorption characteristics of the display portion and the light absorption characteristics of the non-display portion can be controlled separately, and thus both the suppression of external light reflection and the suppression of reflection tint and the suppression of brightness reduction can be achieved at a higher level, and the tint of reflected light can also be adjusted to be neutral.

The conditions of the ultraviolet irradiation can be appropriately adjusted to obtain the optical filter according to the embodiment of the present invention having a site having low light absorptivity. For example, the ultraviolet irradiation can be performed under atmospheric pressure (101.33 kPa) as a pressure condition, can be performed under a mild temperature condition of 10° C. to 60° C. as a temperature condition, the lamp output can be set to 10 to 320 W/cm, and as a lamp to be used, an air-cooled metal halide lamp, a mercury lamp such as an ultra-high pressure mercury lamp, or the like can be used. The irradiation dose can be set to 200 to 5,000 mJ/cm².

The optical filter according to the embodiment of the present invention may have an optical functional film described in the light absorption filter according to the embodiment of the present invention.

In addition, the optical filter according to the embodiment of the present invention may have a layer containing an ultraviolet absorbing agent. As the ultraviolet absorbing agent, a commonly used compound can be used without particular limitation, and examples thereof include an ultraviolet absorbing agent in the ultraviolet absorbing layer described later. The resin constituting the layer containing the ultraviolet absorbing agent is also not particularly limited, and examples thereof include a resin in the ultraviolet absorbing layer described later.

The content of the ultraviolet absorbing agent in the layer containing the ultraviolet absorbing agent is appropriately adjusted according to the intended purpose.

### [Display Element Intermediate Product and Display Element]

The display element intermediate according to the embodiment of the present invention includes the light absorption filter according to the embodiment of the present invention.

In the display element intermediate according to the embodiment of the present invention, as other configurations, a configuration of a display element that is usually used in a display device can be used without particular limitation as long as the light absorption filter according to the embodiment of the present invention is included, and examples thereof include an OLED display element, an inorganic EL display element, and a liquid crystal cell (liquid crystal display element) described later.

In the display element intermediate according to the embodiment of the present invention, the light absorption filter according to the embodiment of the present invention and the display element may be laminated to be in direct contact with each other, or may be laminated through a pressure sensitive adhesive layer. As the pressure sensitive adhesive layer, the description of the pressure sensitive adhesive layer described later can be applied. In addition, the light absorption filter according to the embodiment of the present invention and the display element may be further laminated through any layer such as a barrier film in addition to the pressure sensitive adhesive layer. As any layer such as a barrier film, any layer that is usually used in a display element can be appropriately used, and as the barrier film, for example, the description of the gas barrier layer described above can be applied.

In the display element intermediate according to the embodiment of the present invention, a laminated structure in which any layer of the wavelength-selective absorption layer or the light absorption disappearing layer in the light absorption filter according to the embodiment of the present invention is closer to the display element may be adopted. In the display element intermediate according to the embodiment of the present invention, from the viewpoint of decolorizing the light absorption disappearing layer by a small amount of ultraviolet irradiation, it is preferable that the wavelength-selective absorption layer in the light absorption filter according to the embodiment of the present invention has a laminated structure in which the wavelength-selective absorption layer is closer to the display element than the light absorption disappearing layer.

By subjecting the display element intermediate according to the embodiment of the present invention to mask exposure by ultraviolet irradiation, the display element according to the embodiment of the present invention, which is obtained by converting the light absorption filter according to the embodiment of the present invention included in the display element intermediate according to the embodiment of the present invention into the optical filter according to the embodiment of the present invention, is obtained. That is, the display element intermediate according to the embodiment of the present invention is an intermediate product as a stage before the display element according to the embodiment of the present invention, and the display element according to the embodiment of the present invention means a finished product as a display element.

The display element according to the embodiment of the present invention may include a display element corresponding to a display device to be incorporated, and a display element including an OLED display element is referred to as the OLED display element according to the embodiment of the present invention, a display element including an inorganic EL display element is referred to as the inorganic EL display element according to the embodiment of the present invention, and a display element including a liquid crystal display element is referred to as the liquid crystal display element according to the embodiment of the present invention.

### [OLED Display Device]

The organic electroluminescent display device according to the embodiment of the present invention (referred to as an organic electroluminescence (EL) display device or an organic light emitting diode (OLED) display device, and abbreviated as an OLED display device in the present invention) includes the optical filter according to the embodiment of the present invention or the OLED display element according to the embodiment of the present invention.

As the OLED display device according to the embodiment of the present invention, a configuration of a generally used OLED display device can be used without particular limitation as another configuration as long as the optical filter according to the embodiment of the present invention or the OLED display element according to the embodiment of the present invention is included. The OLED display element according to the embodiment of the present invention is incorporated in the OLED display device according to the embodiment of the present invention such that the optical filter according to the embodiment of the present invention is on the external light side.

A configuration example of the OLED display device according to the embodiment of the present invention is not particularly limited, and in a case of including the optical filter according to the embodiment of the present invention, for example, a display device including, in order from the side opposite to the external light, glass, a layer including a thin film transistor (TFT), an OLED display element, a barrier film, a pressure sensitive adhesive layer, the optical filter according to the embodiment of the present invention, a pressure sensitive adhesive layer, glass, a pressure sensitive adhesive layer, and a surface film is an exemplary example. In addition, in a case of including the OLED display element according to the embodiment of the present invention, for example, a display device including, in order from the side opposite to the external light, glass, a layer including a thin film transistor (TFT), the OLED display element according to the embodiment of the present invention, a barrier film, glass, a pressure sensitive adhesive layer, and a surface film is an exemplary example.

The above-described OLED display element has a configuration in which an anode electrode, alight emitting layer, and a cathode electrode are laminated in this order. In addition to the light emitting layer, a hole injection layer, a hole transport layer, an electron transport layer, an electron injection layer, or the like is included between the anode electrode and the cathode electrode. In addition, for example, the description in JP2014-132522A can also be referenced.

A resin film can be used instead of the above-described glass.

### <Pressure Sensitive Adhesive Layer>

In the OLED display device according to the embodiment of the present invention, a surface of the optical filter according to the embodiment of the present invention or the OLED display element according to the embodiment of the present invention on the external light side may be bonded to an optical functional film having glass, a barrier film, an antireflection layer, or the like through a pressure sensitive adhesive layer, or a polarizing plate including a polarizer and a polarizing plate protective film. In addition, it is preferable that a surface of the optical filter according to the embodiment of the present invention or the OLED display element according to the embodiment of the present invention, which is located on the side opposite to the external light, is bonded to glass (substrate), a barrier film, or a layer including a TFT through a pressure sensitive adhesive layer.

In a case where the OLED display element according to the embodiment of the present invention has a pressure sensitive adhesive layer on the outermost surface, the description of the pressure sensitive adhesive layer is read as the description related to the pressure sensitive adhesive layer provided on the outermost surface of the OLED display element according to the embodiment of the present invention.

For the pressure sensitive adhesive layer, the descriptions related to the pressure sensitive adhesive layer and the forming method in the OLED display device, which are described in 0239 to 0290 of WO2021/132674A, can be applied as they are.

From the viewpoint of light resistance of the optical filter and the optical filter included in the OLED display element according to the embodiment of the present invention, it is preferable that the pressure sensitive adhesive composition described in WO2021/132674A contains an ultraviolet absorber described later.

### <Substrate>

In the OLED display device according to the embodiment of the present invention, the optical filter according to the embodiment of the present invention or the OLED display element according to the embodiment of the present invention may be bonded to an optical functional film through a pressure sensitive adhesive layer on a surface located on the external light side. In addition, it is preferable that the optical filter according to the embodiment of the present invention or the OLED display element according to the embodiment of the present invention is bonded to glass (substrate) through a pressure sensitive adhesive layer on a surface located on the side opposite to the external light.

A method of forming the pressure sensitive adhesive layer is not particularly limited, and for example, a method of applying the pressure sensitive adhesive composition to the light absorption filter according to the embodiment of the present invention, the optical filter according to the embodiment of the present invention, or the OLED display element according to the embodiment of the present invention by a typical means such as a bar coater, and drying and curing the pressure sensitive adhesive composition; a method of applying the pressure sensitive adhesive composition to a surface of a release substrate, drying the pressure sensitive adhesive composition, and then transferring the pressure sensitive adhesive layer to the light absorption filter according to the embodiment of the present invention, the optical filter according to the embodiment of the present invention, or the OLED display element according to the embodiment of the present invention using the release substrate, and aging and curing the pressure sensitive adhesive layer; and the like can be used.

The peelable substrate is not particularly limited, and any peelable substrate can be used. Examples thereof include the support film in the manufacturing method for the light absorption filter according to the embodiment of the present invention described above.

In addition, the conditions of application, drying, aging, and curing can be appropriately adjusted based on a conventional method.

### [Inorganic Electroluminescent Display Device]

The inorganic electroluminescent display device according to the embodiment of the present invention (also referred to as an inorganic electroluminescence (EL) display device, and also abbreviated as an inorganic EL display device in the present invention) includes the optical filter according to the embodiment of the present invention or the inorganic EL display element according to the embodiment of the present invention. The inorganic EL display element according to the embodiment of the present invention is incorporated into the inorganic EL display device according to the embodiment of the present invention such that the optical filter according to the embodiment of the present invention is located on the external light side.

As the inorganic EL display device according to the embodiment of the present invention, the configuration of the inorganic EL display device that is generally used can be used without particular limitation as long as the optical filter according to the embodiment of the present invention or the inorganic EL display element according to the embodiment of the present invention is included. For example, the description of the inorganic EL element (inorganic EL display element) and the inorganic electroluminescent display device described in JP2005-338640A can be preferably applied.

### [Liquid Crystal Display Device]

The liquid crystal display device according to the embodiment of the present invention includes the optical filter according to the embodiment of the present invention or the liquid crystal display element according to the embodiment of the present invention. The liquid crystal display element according to the embodiment of the present invention is incorporated into the liquid crystal display device according to the embodiment of the present invention such that the optical filter according to the embodiment of the present invention is located on the external light side.

The optical filter according to the embodiment of the present invention may be used as at least one of a polarizing plate-protective film or a pressure sensitive adhesive layer as described later, or it may be included in a backlight unit that is used in the liquid crystal display device.

In a case where the liquid crystal display device according to the embodiment of the present invention includes the optical filter according to the embodiment of the present invention, the liquid crystal display device preferably includes the optical filter according to the embodiment of the present invention, a polarizing plate including a polarizer and a polarizing plate protective film, a pressure sensitive adhesive layer, and a liquid crystal cell, and the polarizing plate is preferably bonded to the liquid crystal cell with the pressure sensitive adhesive layer being interposed. In the liquid crystal display device, the optical filter according to the embodiment of the present invention may also serve as the polarizing plate-protective film or the pressure sensitive adhesive layer. That is, the liquid crystal display device is divided into a case where the liquid crystal display device includes a polarizing plate including a polarizer and the optical filter (polarizing plate-protective film) according to the embodiment of the present invention, an adhesive layer, and a liquid crystal cell, and a case where the liquid crystal display device includes a polarizing plate including a polarizer and a polarizing plate-protective film, the optical filter (adhesive layer) according to the embodiment of the present invention, and a liquid crystal cell.

The FIGURE is a schematic view showing an example of the liquid crystal display device according to the embodiment of the present invention. In the FIGURE, a liquid crystal display device 10 consists of a liquid crystal cell having a liquid crystal layer 5 and having a liquid crystal cell upper electrode substrate 3 and a liquid crystal cell lower electrode substrate 6, which are respectively disposed above and below the liquid crystal layer 5, and an upper polarizing plate 1 and a lower polarizing plate 8, which are respectively disposed on both sides of the liquid crystal cell. A color filter layer may be laminated on the upper electrode substrate 3 or the lower electrode substrate 6. On a rear surface of the above-described liquid crystal display device 10, a backlight is disposed. As a light source of the backlight, those described in the above backlight unit can be used.

Each of the upper polarizing plate 1 and the lower polarizing plate 8 has a configuration in which each of them is laminated such that a polarizer is sandwiched between two polarizing plate protective films, and in the liquid crystal display device 10, at least one polarizing plate is preferably a polarizing plate including the optical filter according to the embodiment of the present invention.

In addition, in the liquid crystal display device 10, the liquid crystal cell and the polarizing plate (upper polarizing plate 1 and/or lower polarizing plate 8) may be bonded together through a pressure sensitive adhesive layer (not shown). In this case, the optical filter according to the embodiment of the present invention may also serve as the above-described pressure sensitive adhesive layer.

The liquid crystal display device 10 includes an image direct vision-type liquid crystal display, an image projection-type liquid crystal display device, and a light modulation-type liquid crystal display device. The present invention is effective for an active matrix liquid crystal display device that uses a three-terminal or two-terminal semiconductor element such as a thin film transistor (TFT) or a metal insulator metal (MIM). Of course, it is also effective for a passive matrix liquid crystal display device represented by a super twisted nematic (STN) mode which is referred to as the time division driving.

In a case where the optical filter according to the embodiment of the present invention is included in the backlight unit, the polarizing plate of the liquid crystal display device may be a general polarizing plate (a polarizing plate that does not include the optical filter according to the embodiment of the present invention) or may be a polarizing plate that includes the optical filter according to the embodiment of the present invention. In addition, the pressure sensitive adhesive layer may be a typical pressure sensitive adhesive layer (not the optical filter according to the embodiment of the present invention) or may be a pressure sensitive adhesive layer formed of the optical filter according to the embodiment of the present invention.

The in plane switching (IPS) mode liquid crystal display device described in paragraphs 0128 to 0136 of JP2010-102296A is preferable as the liquid crystal display device according to the embodiment of the present invention except that the optical filter according to the embodiment of the present invention is used.

### <Polarizing Plate>

The polarizing plate used in the present invention includes a polarizer and at least one polarizing plate protective film.

The polarizing plate that is used in the present invention is preferably a polarizing plate having a polarizer and polarizing plate-protective films on both surfaces of the polarizer, and it is preferable that at least one surface of the polarizer includes the optical filter according to the embodiment of the present invention as the polarizing plate-protective film. The surface of the polarizer opposite to the surface having the optical filter according to the embodiment of the present invention (the polarizing plate-protective film according to the embodiment of the present invention) may have a general polarizing plate-protective film.

The film thickness of the polarizing plate protective film is preferably 5 to 120 μm and more preferably 10 to 100 μm. A thinner film is preferable in that, in a case of being incorporated in the liquid crystal display device, display unevenness over time in high temperature and high humidity is less likely to occur. On the other hand, a thicker film is preferable from the viewpoint of stable transportation during film manufacturing and polarizing plate production. In a case where the optical filter according to the embodiment of the present invention also serves as the polarizing plate-protective film, it is preferable that the thickness of the optical filter satisfies the above-described range.

For the polarizing plate that is used in the present invention, the descriptions related to the performance, the shape, the configuration, the polarizer, the method of laminating the polarizer and the polarizing plate-protective film, the functionalization of the polarizing plate, and the like regarding the polarizing plate described in [0299] to [0309] of WO2021/132674A can be applied as they are.

### <Pressure Sensitive Adhesive Layer>

In the liquid crystal display device according to the embodiment of the present invention, the polarizing plate is preferably attached to the liquid crystal cell through an adhesive layer. The optical filter according to the embodiment of the present invention may also serve as the pressure sensitive adhesive layer. In a case where the optical filter according to the embodiment of the present invention does not serve as the pressure sensitive adhesive layer, a typical pressure sensitive adhesive layer can be used as the pressure sensitive adhesive layer.

The pressure sensitive adhesive layer is not particularly limited as long as the polarizing plate can be bonded to the liquid crystal cell, and for example, an acrylic type, a urethane type, polyisobutylene, or the like is preferable.

In a case where the optical filter according to the embodiment of the present invention also serves as the pressure sensitive adhesive layer, the wavelength-selective absorption layer in the optical filter according to the embodiment of the present invention and the light absorption disappearing layer in the optical filter according to the embodiment of the present invention contain the above-described base polymer in addition to the components contained in each layer (the above-described resin and the above-described dye in the wavelength-selective absorption layer in the optical filter according to the embodiment of the present invention, and the above-described resin and the above-described dye in the light absorption disappearing layer in the optical filter according to the embodiment of the present invention), and further contain a crosslinking agent, a coupling agent, and the like to impart pressure sensitive adhesiveness. In addition, the resin in the wavelength-selective absorption layer in the optical filter according to the embodiment of the present invention and the resin in the light absorption disappearing layer in the optical filter according to the embodiment of the present invention, which function as the base polymer in the pressure sensitive adhesive layer, may be used in a form of also serving as the base polymer.

In a case where the optical filter according to the embodiment of the present invention also serves as the pressure sensitive adhesive layer, each of the pressure sensitive adhesive layer (the wavelength-selective absorption layer in the optical filter according to the embodiment of the present invention and the light absorption disappearing layer in the optical filter according to the embodiment of the present invention) preferably contains 90% by mass or more and less than 100% by mass of the above-described base polymer, and more preferably contains 95% by mass or more and less than 100% by mass of the above-described base polymer. The content of the dye is as described above.

The thickness of the adhesive layer is not particularly limited; however, it is preferably 1 to 50 μm and more preferably 3 to 30 μm.

### <Liquid Crystal Cell (Liquid Crystal Display Element)>

The liquid crystal cell is not particularly limited, and a normal liquid crystal cell can be used.

In a case where the liquid crystal display device according to the embodiment of the present invention includes the liquid crystal display element according to the embodiment of the present invention, a configuration related to a normal liquid crystal display device can be used, except that the liquid crystal display element according to the embodiment of the present invention is used as the liquid crystal cell in the description related to the liquid crystal display device described above.

### <Ultraviolet Absorbing Layer>

In the organic electroluminescent display device according to the embodiment of the present invention, the inorganic electroluminescent display device according to the embodiment of the present invention, and the liquid crystal display device according to the embodiment of the present invention, which include the optical filter according to the embodiment of the present invention or the display element according to the embodiment of the present invention, it is preferable that a layer (hereinafter, also referred to as “ultraviolet absorbing layer”) that inhibits light absorption (ultraviolet absorption) of the compound that generates a radical by the ultraviolet irradiation is provided on the viewer side with respect to the optical filter according to the embodiment of the present invention or the display element according to the embodiment of the present invention. By providing the ultraviolet absorbing layer, it is possible to prevent the optical filter according to the embodiment of the present invention or the optical filter included in the display element according to the embodiment of the present invention from fading due to external light.

Hereinafter, the ultraviolet absorbing layer that is used in the present invention will be described.

### (Ultraviolet Absorber)

The ultraviolet absorbing layer usually contains a resin and an ultraviolet absorbing agent.

Specific examples of the ultraviolet absorbing agent preferably used in the present invention include a hindered phenol-based compound, a benzophenone-based compound such as a hydroxybenzophenone-based compound, a benzotriazole-based compound, a salicylic acid ester-based compound, a cyanoacrylate-based compound, and a nickel complex salt-based compound.

As examples of the hindered phenol-based compound and the benzotriazole-based compound, the hindered phenol-based compound and the benzotriazole-based compound described in paragraph 0227 of WO2023/234353A can also be suitably used in the present invention.

The amount of the ultraviolet absorbing agent added is preferably 0.1 parts by mass to 30.0 parts by mass with respect to 100 parts by mass of the resin.

In addition, from the viewpoint of further improving the light resistance of the optical filter according to the embodiment of the present invention or the optical filter included in the display element according to the embodiment of the present invention, it is also preferable to use a compound (1) represented by Formula (1) described in paragraphs 0229 to 0283 of WO2023/234353A as the ultraviolet absorber. The description in paragraphs 0279 to 0283 of WO2023/234353A regarding the absorption characteristics, the synthesis method, and the content of the compound (1) represented by Formula (1) described in WO2023/234353A can also be suitably used in the present invention.

### (Resin)

As the resin that is used for the ultraviolet absorbing layer, a known resin can be used, which is not particularly limited as long as it does not contradict the gist of the present invention. Examples of the resin include a cellulose acylate resin, an acrylic resin, a cycloolefin-based resin, a polyester-based resin, and an epoxy resin.

### (Installation Position of Ultraviolet Absorbing Layer)

The disposition of the ultraviolet absorbing layer is not particularly limited as long as it is on the viewer side with respect to the optical filter according to the embodiment of the present invention or the display element according to the embodiment of the present invention, and the ultraviolet absorbing layer can be provided at any position. For example, an ultraviolet absorber can be added to a member such as a protective film of a polarizing plate or an antireflection film to provide the function of the ultraviolet absorbing layer. In addition, an ultraviolet absorbing agent can also be added to the above-described pressure sensitive adhesive layer.

### EXAMPLES

Hereinafter, the present invention will be more specifically described based on examples. Materials, using amounts, proportions, treatment details, treatment procedures, and the like shown in the following examples can be appropriately changed without departing from the gist of the present invention. Therefore, it is to be understood that the scope of the present invention is not limited to Examples described below.

In the following examples, “parts” and “%” representing the composition are based on mass unless otherwise specified. Room temperature means “25° C.”.

All of the step of preparing the light absorption disappearing layer forming liquid, the step of producing a light absorption filter using the light absorption disappearing layer forming liquid, and the step of performing an ultraviolet irradiation test were all carried out under a yellow light so that the ultraviolet rays were not applied.

λₘₐₓ is a value measured by a method described in <Absorbance of light absorption filter (before ultraviolet irradiation)> described later.

### [Production of Light Absorption Filter]

Materials used to produce the light absorption filter are shown below.

### <Polymer (Resin)>

### (Resin 1)

ARUFON UC-3920 (trade name) manufactured by Toagosei Co., Ltd., carboxy group-containing acrylic polymer, weight-average molecular weight: 15,500

### (Resin 2)

Adamantyl methacrylate-acrylic acid random copolymer, acrylic acid content: 52 mol %, weight-average molecular weight: 46300.

The constitutional unit derived from acrylic acid in the resin 2 corresponds to the constitutional unit having a carboxy group as the acid group in the compound A defined in the present invention.

### <Compound B>

4-methylquinoline (manufactured by Tokyo Chemical Industry Co., Ltd., Lepidine, pKaH: 5.1)

### <Dye>

In the structural formulae described below, Bu represents a butyl group.

### (Dye Contained in Light Absorption Disappearing Layer)

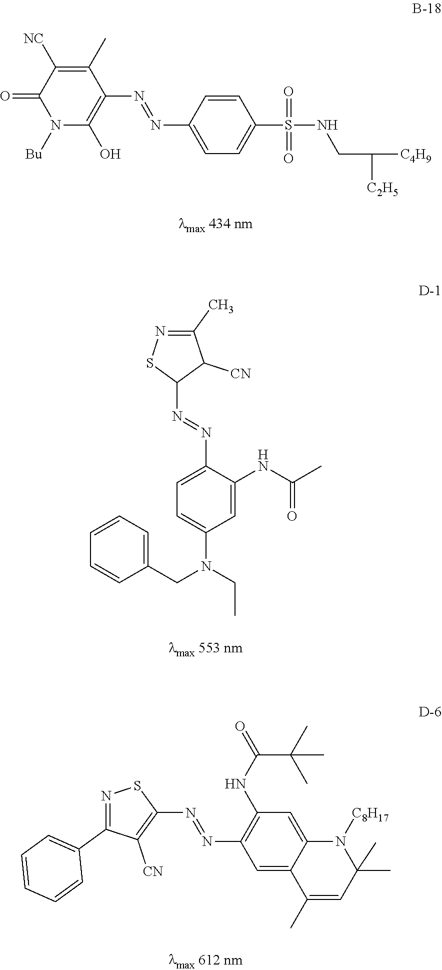

### (Dye Contained in Wavelength-Selective Absorption Layer)

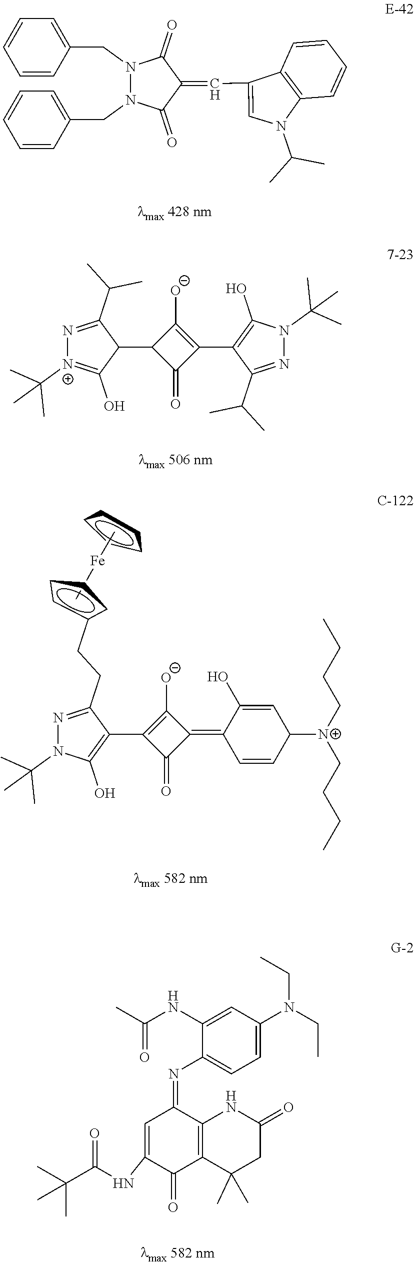

### (Leveling Agent 1)

A polymer surfactant composed of the following constitutional components was used as a leveling agent 1. In the following structural formulae, a proportion of each constitutional component is a molar ratio, and t-Bu means a tert-butyl group.

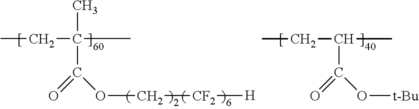

### (Substrate 1)

A polyethylene terephthalate film, LUMIRROR XD-510P (product name, film thickness: 50 μm, manufactured by Toray Industries, Inc.) was used as a substrate 1.

### Example 1

### [Production of Light Absorption Filter No. 101 Having Gas Barrier Layer]

### [Production of Wavelength-Selective Absorption Layer]

### (1) Preparation of Wavelength-Selective Absorption Layer Forming Liquid 1

Each component was mixed according to the composition shown below to prepare a wavelength-selective absorption layer forming liquid 1.

Composition of wavelength-selective
absorption layer forming liquid 1

| | | |
|---|---|---|
| Resin 1 | 93.21 | parts by mass |
| Leveling agent 1 | 0.08 | parts by mass |
| Dye E-42 | 2.50 | parts by mass |
| Dye 7-23 | 1.57 | parts by mass |
| Dye C-122 | 0.66 | parts by mass |
| Dye G-2 | 1.98 | parts by mass |
| Tetrahydrofuran (solvent) | 566.7 | parts by mass |

Subsequently, the obtained wavelength-selective absorption layer forming liquid 1 was filtered using a filter having an absolute filtration precision of 5 μm (product name: Hydrophobic Fluorepore Membrane, manufactured by Millex).

### (2) Production of Wavelength-Selective Absorption Layer 1

The wavelength-selective absorption layer forming liquid 1 after the filtration treatment was applied onto the substrate 1 using a bar coater such that the film thickness after drying was 2.4 μm, and dried at 120° C. to produce a substrate 2 with a wavelength-selective absorption layer.

<Production of Substrate 3 with Diffusion Inhibiting Layer>

### (1) Preparation of Diffusion Inhibiting Layer Forming Liquid A

Each component was mixed with the composition shown below, and the mixture was stirred in a constant-temperature tank at 50° C. for 1 hour to dissolve poly(methacrylic acid) (manufactured by FUJIFILM Wako Pure Chemical Corporation, weight-average molecular weight: 100,000, δt value=19.0), thereby preparing a diffusion inhibiting layer forming liquid B.

Composition of diffusion inhibiting layer forming liquid A

| Poly(methacrylic acid) (manufactured by | 4.0 | parts by mass |
|---|---|---|
| FUJIFILM Wako Pure Chemical Corporation, | | |
| weight-average molecular weight: 100,000) | | |
| Pure water | 60.0 | parts by mass |
| Ethanol | 36.0 | parts by mass |

Subsequently, the obtained diffusion inhibiting layer forming liquid A was filtered using a filter having an absolute filtration precision of 5 μm (product name: Hydrophobic Fluorepore Membrane, manufactured by Millex).

### (2) Production of Diffusion Inhibiting Layer

The diffusion inhibiting layer forming liquid A after the filtration treatment was applied onto the wavelength-selective absorption layer of the substrate 2 with a wavelength-selective absorption layer using a bar coater such that the film thickness after drying was 1.1 μm, and dried under the conditions of 120° C. for 60 seconds to produce a substrate 3 with a diffusion inhibiting layer.

### [Production of Light Absorption Filter]

### (1) Preparation of Light Absorption Disappearing Layer Forming Liquid

Each component was mixed with the following formulation to prepare a light absorption disappearing layer forming liquid (composition) Ba-1.

Formulation of light absorption disappearing
layer forming liquid Ba-1

| Resin 2 | 76.8 | parts by mass |
|---|---|---|
| Leveling agent 1 | 0.08 | parts by mass |
| Dye B-18 | 3.13 | parts by mass |
| Dye D-1 | 1.22 | parts by mass |
| Dye D-6 | 2.03 | parts by mass |
| 4-methylquinoline (manufactured by | 17.2 | parts by mass |
| Tokyo Chemical Industry Co., Ltd.) | | |
| Tetrahydrofuran (solvent, δt value = 23.6) | 566.7 | parts by mass |

Subsequently, the obtained light absorption disappearing layer forming liquid Ba-1 was filtered using filter paper (#63, manufactured by Toyo Filter Paper Co., Ltd.) having an absolute filtration precision of 10 μm, and further filtered using a metal sintered filter (trade name: PALL Filter PMF, media code: FH025, manufactured by PALL) having an absolute filtration precision of 2.5 μm.

### (2) Production of Light Absorption Filter

The light absorption disappearing layer forming liquid Ba-1 after the filtration treatment was applied onto the diffusion inhibiting layer of the substrate 3 with a diffusion inhibiting layer using a bar coater such that the film thickness after drying was 2.2 μm, and dried at 120° C. to form a light absorption disappearing layer, thereby producing a light absorption filter No. 101 not having a gas barrier layer.

### [Production of Light Absorption Filter Having Gas Barrier Layer]

A light absorption filter No. 101 (also referred to as “light absorption filter No. 101 having gas barrier layer”) in which a gas barrier layer was further laminated on the light absorption disappearing layer of the light absorption filter No. 101 not having a gas barrier layer as described below was produced, and the evaluation described later was performed.

### (1) Preparation of Resin Solution

Each component was adjusted to have the composition ratio shown below, and Kuraray EKSEVAL AQ-4105 (trade name, manufactured by Kuraray Co., Ltd., modified polyvinyl alcohol, saponification degree: 98% to 99% by mole) was dissolved by stirring in a constant-temperature tank at 90° C. for 1 hour in pure water and isopropyl alcohol, and then cooled to room temperature, and polyethyleneimine (manufactured by FUJIFILM Wako Pure Chemical Corporation, weight-average molecular weight: about 10,000) was added thereto to prepare a gas barrier layer forming liquid.

Composition of gas barrier layer forming liquid

| | | |
|---|---|---|
| Kuraray Exceval AQ-4105 (product name, | 3.6 | parts by mass |
| manufactured by KURARAY Co., Ltd.) | | |
| Polyethyleneimine (manufactured by FUJIFILM | 0.4 | parts by mass |
| Wako Pure Chemical Corporation, weight- | | |
| average molecular weight: about 10,000) | | |
| Pure water | 88.5 | parts by mass |
| Isopropyl alcohol | 7.5 | parts by mass |

Subsequently, the obtained gas barrier layer forming liquid was filtered using a filter having an absolute filtration precision of 5 μm (product name: Hydrophobic Fluorepore Membrane, manufactured by Millex).

### (2) Lamination of Gas Barrier Layer

The gas barrier layer forming liquid after the filtration treatment was applied to the light absorption disappearing layer side of the light absorption filter using a bar coater so that the film thickness after drying was 0.6 μm, and dried at 120° C. for 60 seconds to produce a light absorption filter No. 101 having a gas barrier layer.

The light absorption filter No. 101 having a gas barrier layer has a configuration in which the substrate 1, the wavelength-selective absorption layer, the diffusion inhibiting layer, the light absorption disappearing layer, and the gas barrier layer are laminated in this order.

### [Production of Light Absorption Filter No. 102 Having Gas Barrier Layer]

A light absorption filter No. 102 having a gas barrier layer was produced in the same manner as in the production of the light absorption filter No. 101 having a gas barrier layer, except that the thickness of the light absorption disappearing layer was changed to the value shown in Table 1 in the production of the light absorption filter No. 101 having a gas barrier layer.

[Production of Light Absorption Filter No. R301 Having Gas Barrier Layer]

A light absorption filter No. r301 having a gas barrier layer was produced in the same manner as in the production of the light absorption filter No. 101 having a gas barrier layer, except that the dyes E-42, 7-23, C-122, and G-2 in the wavelength-selective absorption layer forming liquid were removed, and the dyes B-18, D-1, and D-6 and 4-methylquinoline in the light absorption disappearing layer forming liquid were further removed in the production of the light absorption filter No. 101 having a gas barrier layer.

[Production of Light Absorption Filter No. C201, c202, and c204 Having Gas Barrier Layer]

Light absorption filters No. c201, c202, and c204 having a gas barrier layer were produced in the same manner as in the production of the light absorption filter No. 101 having a gas barrier layer, except that the dyes B-18, D-1, and D-6 in the light absorption disappearing layer forming liquid were removed in the production of the light absorption filter No. 101 having a gas barrier layer, the thickness of the wavelength-selective absorption layer was further changed to the value shown in Table 1 in the light absorption filter No. c202 having a gas barrier layer, and the blending amount of the dye in the wavelength-selective absorption layer was further changed to the value shown in Table 1 in the light absorption filter No. c204 having a gas barrier layer.

In the production of the wavelength-selective absorption layer of the light absorption filter No. c204 having a gas barrier layer, the blending amount of the leveling agent 1 in the wavelength-selective absorption layer of the light absorption filter No. 101 having a gas barrier layer was fixed, and the blending amount of the resin 1 was adjusted in accordance with the change in the blending amount of the dye so that the mass as the wavelength-selective absorption layer was not changed.

[Production of Light Absorption Filter No. c203 Having Gas Barrier Layer]

A light absorption filter No. c203 having a gas barrier layer was produced in the same manner as in the production of the light absorption filter No. 101 having a gas barrier layer, except that the dyes E-42, 7-23, C-122, and G-2 in the wavelength-selective absorption layer forming liquid were removed in the production of the light absorption filter No. 101 having a gas barrier layer.

Here, Nos. 101 and 102 are the light absorption filters according to the embodiment of the present invention having a gas barrier layer, Nos. c201 to c204 are the light absorption filters of Comparative Examples having a gas barrier layer, and No. r301 is a light absorption filter for reference having a gas barrier layer.

In the following description, the “light absorption filter having a gas barrier layer” will be simply referred to as “light absorption filter”.

### <Absorbance of Light Absorption Filter (Before Ultraviolet Irradiation)>

### (1) Measurement of Absorbance

Using a UV3600 spectrophotometer (product name) manufactured by Shimadzu Corporation, the absorbance of the light absorption filter and the standard filter in a wavelength range of 380 to 800 nm was measured for every 1 nm.

The standard filter for the light absorption filters Nos. 101, 102, and c201 to c204 is a light absorption filter No. r301, which was modified so as not to contain the dyes and 4-methylquinoline, which is the compound B.

### (2) Calculation of Absorbance

Using the value Abₓ (λ) of the absorbance of the light absorption filter at each wavelength λ nm measured as described above and the value Ab₀(λ) of the absorbance of the corresponding standard filter at each wavelength λ nm, the absorbance Ab (λ) of the light absorption filter before ultraviolet irradiation was calculated according to the following expression.

$$Ab ( λ ) = {Ab}_{x} ( λ ) - {Ab}_{0} ( λ )$$

Hereinafter, among the wavelengths showing maximum absorption in the absorbance Ab(λ) of the light absorption filter in the wavelength region of 400 to 700 nm, the wavelength showing the largest absorbance Ab(λ) was defined as the maximum absorption wavelength (hereinafter, also simply referred to as “λₘₐₓ”), and the absorbance at this λₘₐₓ was defined as the maximum absorbance value (hereinafter, also simply referred to as “Ab(λₘₐₓ)”).

The obtained Ab(λₘₐₓ) of each dye is described together in the description of the chemical structure of the dye described above.

TABLE 1

| Light absorption | Wavelength-selective absorption layer | | | | | Light absorption disappearing layer | | | |
|---|---|---|---|---|---|---|---|---|---|
| filter | Thickness | Blending amount of dye | | | | Thickness | Blending amount of dye | | |
| No. | (um) | E-42 | 7-23 | C-122 | G-2 | (um) | B-8 | D-1 | D-6 |
| 101 | 2.4 | 2.50 | 1.57 | 0.66 | 1.98 | 2.2 | 3.13 | 1.22 | 2.03 |
| 102 | 2.4 | 2.50 | 1.57 | 0.66 | 1.98 | 1.3 | 3.13 | 1.22 | 2.03 |
| c201 | 2.4 | 2.50 | 1.57 | 0.66 | 1.98 | 2.2 | 0.00 | 0.00 | 0.00 |
| c202 | 4.8 | 2.50 | 1.57 | 0.66 | 1.98 | 2.2 | 0.00 | 0.00 | 0.00 |
| c203 | 2.4 | 0.00 | 0.00 | 0.00 | 0.00 | 2.2 | 3.13 | 1.22 | 2.03 |
| c204 | 2.4 | 5.00 | 3.14 | 1.32 | 3.96 | 2.2 | 0.00 | 0.00 | 0.00 |
| r301 | 2.4 | 0.00 | 0.00 | 0.00 | 0.00 | 2.2 | 0.00 | 0.00 | 0.00 |

(Notes in table)

The blending amount of the dye in the wavelength-selective absorption layer and the light absorption disappearing layer means the parts by mass of the dye in 100 parts by mass of the wavelength-selective absorption layer and the parts by mass of the dye in 100 parts by mass of the light absorption disappearing layer, respectively.

The unit of the thickness of the wavelength-selective absorption layer and the unit of the thickness of the light absorption disappearing layer are both m.

### REFERENCE EXAMPLES

In light absorption filter No. c203 of Comparative Example, in which dye was added only to the light absorption disappearing layer, light absorption filters Nos. r302 to r304 in which the blending amount of each dye was changed to the values shown in Table 2 were prepared, and the decolorization rate of each dye contained in the light absorption disappearing layer was evaluated as follows.

The results are summarized in Table 2 below.

### (Ultraviolet Irradiation Test)

Under atmospheric pressure (101.33 kPa), the light absorption filter and the standard filter were irradiated with ultraviolet rays (UV) at an illuminance of 100 mW/cm² and an irradiation dose of 2,000 mJ/cm² from the gas barrier layer side (the side opposite to the substrate 1) on a hot plate at 45° C. using an ultra-high pressure mercury lamp (manufactured by HOYA Corporation, trade name: UL750).

The standard filter for the light absorption filters Nos. r302 to r304 is the light absorption filter No. r301.

<Absorbance of Light Absorption Filter (after Ultraviolet Irradiation)>

Using the light absorption filter after ultraviolet irradiation and the standard filter, the absorbance Ab(λ) after ultraviolet irradiation was calculated according to the same method as described in <Absorbance of light absorption filter (before ultraviolet irradiation)> described above.

The absorbance Ab(λ) of the light absorption filter before the ultraviolet ray irradiation test was also calculated by the same method as described in <Absorbance of light absorption filter (before ultraviolet ray irradiation)> above.

### [1. Evaluation of Decolorization Rate]

The decolorization rate was calculated according to the following expression using the maximum absorbance values (Ab(λₘₐₓ)) before and after the ultraviolet irradiation test.

Decolorization rate (%)=100−(Ab(λₘₐₓ) after ultraviolet irradiation/Ab(λₘₐₓ) before ultraviolet irradiation)×100%

[2. Absorption (Secondary Absorption) Derived from New Coloration Structure, Associated with Decomposition of Coloring Agent]

In all of the light absorption filters Nos. r302 to r304 of the reference examples, the value obtained by subtracting the ratio of (I) from the ratio of (II) defined in the above-described paragraph 0223 was 5.0% or less, and the secondary absorption associated with the decomposition of the dye due to ultraviolet ray irradiation was suppressed.

TABLE 2

| | |
|---|---|
| Light | Light absorption disappearing layer |

| | absorption | Thickness | Blending amount of dye | | | Decolorization |
|---|---|---|---|---|---|---|
| | filter No. | (μm) | B-18 | D-1 | D-6 | rate |
| Reference | r302 | 2.2 | 2.92 | 0.00 | 0.00 | 99% |
| Example 2 | | | | | | |
| Reference | r303 | 2.2 | 0.00 | 1.14 | 0.00 | 99% |
| Example 3 | | | | | | |
| Reference | r304 | 2.2 | 0.00 | 0.00 | 1.90 | 99% |
| Example 4 | | | | | | |

(Notes in table)

The blending amount of the dye in the light absorption disappearing layer means the mass part of the dye in 100 parts by mass of the light absorption disappearing layer.

The unit of the thickness of the light absorption disappearing layer is m.

From the results in Table 2, it was found that all of the light absorption filters Nos. r302 to r304 of the reference examples exhibited an excellent decolorization rate, and almost no secondary absorption associated with the decomposition of the dye due to the irradiation with ultraviolet rays occurred, and thus the decolorization properties were excellent.

### <Simulation of Brightness, Reflectivity, and Tint>

The OLED display device including the light absorption filter produced as described above was subjected to a simulation of external light reflection, and the brightness, the reflectivity, and the tint (a* and b*) were calculated.

### (1) Simulation Conditions

In the simulation of the reflectivity and the reflection tint of external light in the OLED display device, the reflectivity, the transmission spectrum, and the reflection spectrum of each constitutional member were defined as follows.
(i) As the reflectivity of the OLED substrate, a reflection spectrum of a substrate measured by disassembling an iPhone (registered trademark) X (trade name) manufactured by Apple Inc. and peeling off a circularly polarizing plate was used.
(ii) As the transmission spectrum of the light absorption filter, a spectrum obtained by converting the absorbance Ab(λ) of the light absorption filter before ultraviolet ray irradiation into a transmittance was used as “transmission spectrum of portion covering the non-display portion (transmission spectrum in portion having high light absorbency)”, and a spectrum obtained by converting the absorbance Ab(λ) of the light absorption filter after ultraviolet ray irradiation under the conditions described in the ultraviolet ray irradiation test in <Reference Examples>> described above into a transmittance was used as “transmission spectrum of portion covering the display portion (transmission spectrum in portion having low light absorbency)”.
(iii) As the emission spectrum of the display light, a value measured using a spectroradiometer SR-UL1R (trade name, manufactured by Topcon Technohouse Corporation) was used for the emission spectrum of the iPhone (registered trademark) X (trade name) manufactured by Apple Inc.
(iv) The area ratio of the non-display portion to the display portion of the display device was set to 77/23.

Therefore, for the optical filter obtained by subjecting the light absorption filter to mask exposure (pattern exposure) with ultraviolet rays, the area ratio of the masked ultraviolet-unirradiated portion (portion covering the non-display portion, portion having high light absorptivity) to the unmasked ultraviolet-irradiated portion (portion covering the display portion, portion having low light absorptivity) was set to 77/23.

### (2) Calculation of Reflectance and Reflection Tint

The reflectivity and the reflection tint were calculated by calculating the reflection spectrum of each of the portion having low light absorbency and the portion having high light absorbency and multiplying the reflection spectrum by the area ratio. Specifically, it is as follows.

First, the reflection spectrum in the portion having low light absorbency and the reflection spectrum in the portion having high light absorbency were obtained by calculating for each wavelength based on the following expression, in which the reflectivity in the portion having low light absorbency was denoted by R_{L}, the reflectivity in the portion having high light absorbency was denoted by R_{H}, the transmittance in the portion having low light absorbency was denoted by T_{L}, the transmittance in the portion having high light absorbency was denoted by T_{H}, the reflectivity of the OLED substrate was denoted by R_{sub}, and the reflectivity of the air interface of the outermost surface was set to 1.5%. As T_{L} and T_{H}, values obtained by multiplying by 0.01 the transmittance values at the respective wavelengths obtained from the transmission spectrum of the light absorption filter described above, expressed in percentage, were used.

$${R}_{L} = {( {T}_{L} )}^{2} \times ( {R}_{sub} - 1.5 \% ) + 1.5 \%$$

$${R}_{H} = {( {T}_{H} )}^{2} \times ( {R}_{sub} - 1.5 \% ) + 1.5 \%$$

Next, the area ratio of the portion having low light absorbency and the area ratio of the portion having high light absorbency were denoted by A_{L} and A_{H}, respectively, and the reflection spectrum of the OLED display device was calculated by the following expression. As A_{L} and A_{H}, values obtained by multiplying the values expressed as percentages by 0.01 were used.

$$Reflection spectrum of OLED display device = {R}_{L} \times {A}_{L} + {R}_{H} \times {A}_{H}$$

Based on the reflection spectrum of the OLED display device calculated above, the reflectivity (luminosity correction), a*, and b* were calculated.

### (3) Calculation of Relative Brightness

The relative brightness in a case where the light absorption filter produced as described above was used was calculated as follows.

The emission spectrum S(λ) of the display was calculated using the emission spectrum of iPhone (registered trademark) X (trade name) manufactured by Apple Inc. In addition, a spectrum obtained by converting the absorbance Ab(λ) of the light absorption filter after the ultraviolet irradiation under the conditions described in the ultraviolet irradiation test in <<Reference Examples>> described above into a transmittance was denoted by T(λ).

The brightness in a case where the light absorption filter was not used was calculated by performing luminosity correction on the above-described emission spectrum S(λ), and this brightness was set to 100. The brightness of the spectrum S (κ)×T (κ) in a case where the light absorption filter was used was calculated as the relative brightness with respect to the brightness in a case where the above light absorption filter was not used.

### <Evaluation of Suppression Effect of Brightness Reduction>

Using the relative brightness values obtained in the above simulation, the suppression effect of brightness reduction was evaluated based on the following evaluation standards.

### (Evaluation Standard)

A: 50<Relative brightness≤100
B: 40<Relative brightness≤50
C: 0≤Relative brightness≤40

### <Evaluation of Suppression Effect of External Light Reflection>

Using the reflectivity value obtained in the above simulation, the reflectivity reduction rate was calculated according to the following expression, and the suppression effect of external light reflection was evaluated based on the following evaluation standards.

$$Reflectivity reduction rate = ( {R}_{0} - {R}_{1} ) / {R}_{0} \times 100 \%$$

R₁: reflectivity in a case where a light absorption filter containing a dye is used
R₀: reflectivity in a case where a light absorption filter No. r301 containing no dye is used

### (Evaluation Standard)

A: 85%<Reduction Rate of Reflectivity
B: 70%<Reduction Rate of Reflectivity≤85%
C: 0≤Reduction Rate of Reflectivity≤70%

### (Evaluation of Reflection Tint)

Using a* and b* obtained in the above-described simulation, the reflection tint was evaluated based on the following evaluation standard.

### (Evaluation Standard)

A: both a* and b* are −5.0 or more and 5.0 or less.
B: at least one of a* or b* is less than −5.0 or more than 5.0.

The evaluation results are collectively listed in Table 3.

TABLE 3

| Light | Display performance simulation | | |
|---|---|---|---|
| absorption | Suppression effect of | Reflection | Suppression effect of |
| filter No. | external light reflection | tint | brightness reduction |
| 101 | A | A | A |
| 102 | A | A | A |
| c201 | C | B | A |
| c202 | B | B | C |
| c203 | C | B | A |
| c204 | B | B | C |

As shown in Table 3, in the light absorption filters Nos. c201, c202, and c204 of Comparative Examples in which the dye was contained only in the wavelength-selective absorption layer, both the suppression of external light reflection and the suppression of brightness reduction could not be achieved. As can be seen from the comparison between the light absorption filter No. c201 and the light absorption filters Nos. c202 and c204, it can be seen that in a case where the dye is contained only in the wavelength-selective absorption layer, the suppression effect of brightness reduction is deteriorated by increasing the content of the dye or increasing the thickness of the layer to improve the suppression effect of external light reflection.

In addition, in the light absorption filter No. c203 of Comparative Example in which the dye was contained only in the light absorption disappearing layer, the suppression effect of external light reflection was deteriorated, and both the suppression of external light reflection and the suppression of brightness reduction could not be achieved. In a case where the dye is contained only in the light absorption disappearing layer, the display portion is transparent, and thus in a display device in which the proportion of the area of the display portion to the area of the non-display portion is high, the suppression effect of external light reflection cannot be increased to a certain level or higher.

On the other hand, in the light absorption filters Nos. 101 and 102 according to the embodiment of the present invention in which the dye was contained in both the wavelength-selective absorption layer and the light absorption disappearing layer, both the suppression of external light reflection and the suppression of brightness reduction could be achieved at a high level, and a neutral reflection tint could also be achieved.

The present invention has been described using the embodiments. However, unless specified otherwise, any of the details of the above description is not intended to limit the present invention and can be construed in a broad sense within a range not departing from the concept and scope of the present invention disclosed in the accompanying claims.
1: upper polarizing plate
2: direction of absorption axis of upper polarizing plate
3: liquid crystal cell upper electrode substrate
4: alignment control direction of upper substrate
5: liquid crystal layer
6: liquid crystal cell lower electrode substrate
7: alignment control direction of lower substrate
8: lower polarizing plate
9: direction of absorption axis of lower polarizing plate
B: backlight unit
10: liquid crystal display device

What is claimed is:

1. Alight absorption filter comprising: alight absorption disappearing layer containing a resin, a dye having a main absorption wavelength band in a wavelength range of 400 to 700 nm, and a compound that generates a radical upon ultraviolet irradiation; and
a wavelength-selective absorption layer containing a resin and a dye having a main absorption wavelength band in a wavelength range of 400 to 700 nm, and containing no compound that generates a radical upon ultraviolet irradiation.

2. The light absorption filter according to claim 1, wherein the compound, contained in the light absorption disappearing layer and that generates a radical upon ultraviolet irradiation, includes a combination of a compound A having an acid group and a compound B having a structure capable of forming a hydrogen bond with the acid group contained in the compound A.

3. The light absorption filter according to claim 2, wherein the compound A is chemically bonded to a polymer constituting the resin contained in the light absorption disappearing layer.

4. The light absorption filter according to claim 1, wherein the dye contained in the light absorption disappearing layer is chemically changed and decolorized upon ultraviolet irradiation.

5. An optical filter that is obtained by subjecting the light absorption filter according to claim 1 to mask exposure by ultraviolet irradiation.

6. A display element intermediate comprising the light absorption filter according to claim 1.

7. A display element obtained by subjecting the display element intermediate according to claim 6 to mask exposure by ultraviolet irradiation.

8. An organic electroluminescent display device, an inorganic electroluminescent display device, or a liquid crystal display device, comprising: the optical filter according to claim 5.

9. An organic electroluminescent display device, an inorganic electroluminescent display device, or a liquid crystal display device, comprising the display element according to claim 7.

10. The organic electroluminescent display device, the inorganic electroluminescent display device, or the liquid crystal display device according to claim 8, wherein a layer which inhibits light absorption of the compound which generates a radical upon ultraviolet irradiation is provided on a viewer side with respect to the optical filter.

11. The organic electroluminescent display device, the inorganic electroluminescent display device, or the liquid crystal display device according to claim 9, wherein a layer which inhibits light absorption of the compound which generates a radical upon ultraviolet irradiation is provided on a viewer side with respect to the display element.

12. A manufacturing method for an optical filter, comprising: irradiating the light absorption filter according to claim 1 with ultraviolet rays to carry out mask exposure.
